(19) United States
(12) Patent Application Publication
(10) Pub. No.: US 2026/0259493 A1
(43) Pub. Date: Sep. 3, 2026

(54) COMPOSITION, RESIN COMPOSITION, COMPOSITION FOR FILM FORMATION, PATTERN FORMATION METHOD, AND COMPOUND

(71) Applicant: Mitsubishi Gas Chemical Company, Inc., Tokyo (JP)

(72) Inventors: Tadashi OMATSU, Hiratsuka-shi, Kanagawa (JP); Kentaro KATAOKA, Niigata-shi, Niigata (JP); Masahiro MATSUMOTO, Niigata-shi, Niigata (JP); Yushi NIIMI, Niigata-shi, Niigata (JP); Takeru KOGUMA, Hiratsuka-shi, Kanagawa (JP); Junya HORIUCHI, Kurashiki-shi, Okayama (JP); Hiroaki YAMAMOTO, Hiratsuka-shi, Kanagawa (JP); Masataka IINUMA, Niigata-shi, Niigata (JP); Kodai MATSUURA, Kurashiki-shi, Okayama (JP); Takashi SATO, Hiratsuka-shi, Kanagawa (JP); Yu OKADA, Chiyoda-ku, Tokyo (JP); Takashi MAKINOSHIMA, Hiratsuka-shi, Kanagawa (JP); Masatoshi ECHIGO, Chiyoda-ku, Tokyo (JP)

(21) Appl. No.: 18/879,499

(22) PCT Filed: Jun. 28, 2023
(86) PCT No.: PCT/JP2023/023917

§ 371 Date: Dec. 27, 2024

(30) Foreign Application Priority Data
Jun. 28, 2022 (JP) 2022-103630

(51) Int. Cl. G03F 7/038; C08F 212/14; C08F 220/18; C08F 220/26; G03F 7/039; G03F 7/20

(52) U.S. Cl. CPC G03F 7/0382; C08F 212/22; C08F 220/18; C08F 220/26; G03F 7/0392; G03F 7/2002

(57) ABSTRACT

A composition comprising a compound (A) represented by the following formula (1) and a compound (B) represented by the following formula (2):

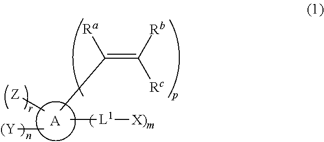

wherein each definition is as shown in the specification; and

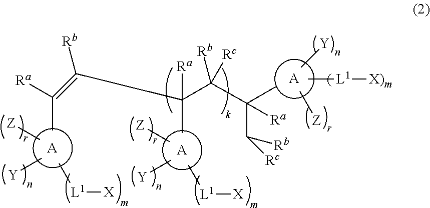

wherein
X, L¹, Y, R^{a}, R^{b}, R^{c}, A, Z, p, m, n, and r are the same as those described in the formula (1), and k represents an integer of 0 or more and 2 or less.

### TECHNICAL FIELD

The present invention relates to a composition, a resin composition, a composition for film formation, a pattern formation method, and a compound.

### BACKGROUND ART

In recent years, in the production of semiconductor elements and liquid crystal display elements, semiconductors (patterns) and pixels have been rapidly miniaturized due to the advance in lithography technology. For pixel miniaturization, the exposure light source has been shifted to have a shorter wavelength, in general. Specifically, ultraviolet rays typified by g-ray and i-ray have been used conventionally, but nowadays, an exposure method for using far ultraviolet such as KrF excimer laser (248 nm) and ArF excimer laser (193 nm) is being the center of mass production. Furthermore, the introduction of extreme ultraviolet (EUV) lithography (13.5 nm) is progressing. In addition, electron beam (EB) is also used for forming a fine pattern.

Up to now, typical resist materials are polymer based resist materials capable of forming an amorphous film. Examples include polymer based resist compositions such as polymethyl methacrylate, polyhydroxy styrene with an acid dissociation group, and polyalkyl methacrylate (e.g., see Non Patent Literature 1). Conventionally, a line pattern of about 10 to 100 nm is formed by irradiating a resist thin film made by coating a substrate with a solution of these resist compositions with ultraviolet, far ultraviolet, electron beam, extreme ultraviolet or the like.

In addition, lithography using electron beam or extreme ultraviolet has a reaction mechanism different from that of normal photolithography (see Non Patent Literature 2, Non Patent Literature 3). Furthermore, lithography with electron beam or extreme ultraviolet aims at forming fine patterns of several nm to ten-odd nm. Accordingly, there is a demand for a resist composition having higher sensitivity to an exposure light source when the dimension of the resist pattern is reduced. In particular, lithography with extreme ultraviolet is required to further increase sensitivity in terms of throughput.

As a resist material that solves the problems as mentioned above, a resist composition having a metallic complex such as titanium, tin, hafnium and zirconium has been proposed (e.g., see Patent Literature 1).

There is a demand for a resist composition having higher sensitivity to an exposure light source when the dimension of the resist pattern is reduced, and a resist composition using 4-hydroxystyrene containing iodine is proposed as a raw material monomer of the resist composition (e.g., see Patent Literatures 2 to 3). In addition, the present inventors propose a resist composition excellent in the exposure sensitivity (e.g., Patent Literature 4).

### CITATION LIST

### Patent Literature

Patent Literature 1: Japanese Patent Laid-Open No. 2015-108781
Patent Literature 2: US2019/0, 187, 342
Patent Literature 3: International Publication No. WO 2019/187881
Patent Literature 4: International Publication No. WO 2021/029395

### Non Patent Literature

Non Patent Literature 1: Shinji Okazaki et al., and eight others “Development of Lithography Technology in These 40 Years”, S&T Publishing Inc., Dec. 9, 2016
Non Patent Literature 2: H. Yamamoto, et al., Jpn. J. Appl. Phys. 46, L142 (2007)
Non Patent Literature 3: H. Yamamoto, et al., J. Vac. Sci. Technol. b 23, 2728 (2005)

### SUMMARY OF INVENTION

### Technical Problem

However, while conventionally developed compositions for film formation have good sensitivity to the exposure light source, they have such a problem of defects being found on a film to be obtained and a pattern after exposure due to aging accompanying the storage and the like of the composition.

To solve the problem, an object of the present invention is to provide a composition, a resist composition, a pattern formation method, and a compound, by which a resist having suppressed defects caused by a prepared film and a pattern after exposure due to aging accompanying the storage and the like can be obtained.

### Solution to Problem

The inventors have, as a result of devoted examinations to solve the aforementioned problem, found out that a compound having a specific structure, or a polymer including the compound as a structural unit can suppress defects that may be caused on a film of a resist composition and a pattern after exposure due to aging accompanying the storage and the like, and reached the present invention.

More specifically, the present invention is as follows.

[1]

A composition comprising a compound (A) represented by the following formula (1) and a compound (B) represented by the following formula (2):

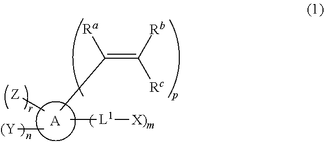

wherein
each X is independently I, F, Cl, Br, or an organic group having 1 to 30 carbon atoms and having 1 or more and 5 or less substituents selected from the group consisting of I, F, Cl, and Br;
each L1 is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of L¹ optionally has a substituent;
each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, I, F, Cl, Br, or an organic group having 1 to 8 carbon atoms and optionally having a substituent;
A is an organic group having 6 to 30 carbon atoms;
each Z is independently an alkoxy group, an ester group, an acetal group, a carboxyalkoxy group, or a carbonate ester group, and the alkoxy group, the ester group, the acetal group, the carboxyalkoxy group, or the carbonate ester group of Z optionally has a substituent; and
p is an integer of 1 or more, m is an integer of 1 or more, n is an integer of 0 or more, and r is an integer of 0 or more; and

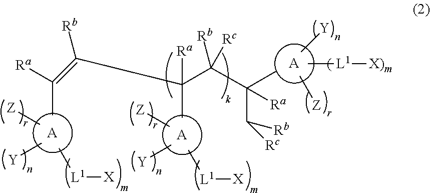

wherein
X, L¹, Y, R^{a}, R^{b}, R^{c}, A, Z, p, m, n, and r are the same as those described in the formula (1), and k represents an integer of 0 or more and 2 or less.
   [2]

The composition according to the above [1], wherein the formula (1) is represented by the following formula (Ia):

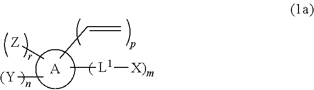

wherein
X, L¹, Y, A, Z, p, m, n, and r are as defined in the formula (1).
   [3]

The composition according to the above [1] or [2], wherein the formula (1) is represented by the following formula (Ib):

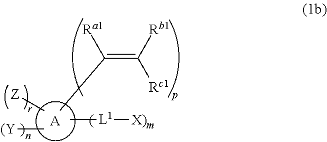

wherein
X, L¹, Y, A, Z, p, m, n, and r are as defined in the formula (1);
each of R^{a1}, R^{b1}, and R^{e1} is independently H, I, F, Cl, Br, or an organic group having 1 to 8 carbon atoms and optionally having a substituent; and at least one of R^{a1}, R^{b1}, and R^{e1} is I, F, Cl, Br, or an organic group having 1 to 8 carbon atoms and optionally having a substituent.
   [4]

The composition according to any one of the above [1] to [3], wherein n+r in the formula (1) is an integer of 1 or more.

[5]

The composition according to any one of the above [1] to [4], wherein each Y in the formula (1) is independently a group represented by the following formula (Y-1):

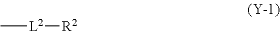

wherein
L² is a group which is cleaved by an action of an acid or a base; and
R² is a linear, branched, or cyclic aliphatic group having 1 to 30 carbon atoms, an aromatic group having 6 to 30 carbon atoms, a linear, branched, or cyclic aliphatic group containing a heteroatom and having 1 to 30 carbon atoms, or an aromatic group containing a heteroatom and having 1 to 30 carbon atoms, and the aliphatic group, the aromatic group, the aliphatic group containing a heteroatom, and the aromatic group containing a heteroatom of R² optionally further have a substituent.
   [6]

The composition according to any one of the above [1] to [5], wherein A in the formula (1) is an aromatic ring.

[7]

The composition according to any one of the above [1] to [6], wherein A in the formula (1) is an alicyclic structure.

[8]

The composition according to any one of the above [1] to [7], wherein A in the formula (1) is a heterocyclic structure.

[9]

The composition according to any one of the above [1] to [8], wherein n in the formula (1) is 2 or more.

[10]

The composition according to any one of the above [1] to [9], wherein the compound represented by the formula (1) comprises a functional group for improving solubility in an alkaline developing solution by the action of an acid or a base.

[11]

The composition according to any one of the above [1] to [10], wherein X in the formula (1) is I, and L¹ is a single bond.

[12]

The composition according to any one of the above [1] to [11], wherein X in the formula (1) is an aromatic group into which one or more F, Cl, Br, or I are introduced.

[13]

The composition according to any one of the above [1] to [12], wherein X in the formula (1) is an alicyclic group into which one or more F, Cl, Br, or I are introduced.

[14]

The composition according to any one of the above [1] to [13], wherein A in the formula (2) is an aromatic ring.

[15]

The composition according to any one of the above [1] to [14], wherein A in the formula (2) is a benzene ring or a naphthalene ring.

[16]

The composition according to any one of the above [1] to [15], wherein X in the formula (2) is iodine or fluorine.

[17]

The composition according to any one of the above [1] to [16], wherein L¹ in the formula (2) is a single bond.

[18]

The composition according to any one of the above [1] to [17], wherein Y in the formula (2) is a hydroxy group, an alkoxy group, a carbonate ester group, or an acetal group.

[19]

The composition according to any one of the above [1] to [18], wherein a mass ratio of a content of the compound represented by the formula (2) based on a content of the compound represented by the formula (1) is 1 ppm or more and 5% by mass or less.

[20]

The composition according to any one of the above [1] to [19], wherein the composition comprises a compound represented by the formula (2a), and a content of the compound represented by the formula (2a) is 18 by mass or less based on the compound of the formula (1):

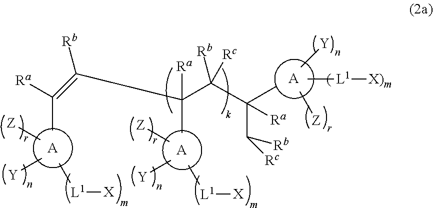

wherein
X, L¹, Y, R^{a}, R^{b}, R^{c}, A, Z, p, m, n, and r are the same as those described in the formula (1), and k represents an integer of 3 or more.
   [21]

The composition according to any one of the above [1] to [20], wherein peroxide is 10 ppm by mass or less based on the compound of the formula (1).

[22]

The composition according to any one of the above [1] to [21], wherein impurities containing one or more elements selected from the group consisting of Mn, Al, Si, and Li are 1 ppm by mass or less, in terms of element, based on the compound of the formula (1).

[23]

The composition according to the above [22], wherein a phosphorus-containing compound is 10 ppm by mass or less based on the compound of the formula (1).

[24]

The composition according to the above [23], wherein maleic acid is 10 ppm by mass or less based on the compound of the formula (1).

[25]

The composition according to any one of the above [1] to [24], wherein in the formula (1) and the formula (2), all r are 0, and at least one n is 1 or more.

[26]

A resin composition comprising:
a polymer comprising at least a constitutional unit represented by the following formula (4) and having 5 or more constitutional units;
a compound (B) represented by the following formula (2) in a content of 1% by mass or less based on the polymer; and
a compound (A) represented by the following formula (1):

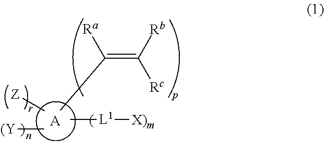

wherein
each X is independently I, F, Cl, Br, or an organic group having 1 to 30 carbon atoms and having 1 or more and 5 or less substituents selected from the group consisting of I, F, Cl, and Br;
each L¹ is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of Li optionally has a substituent;
each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, I, F, Cl, Br, or an organic group having 1 to 8 carbon atoms and optionally having a substituent;
A is an organic group having 6 to 30 carbon atoms; each Z is independently an alkoxy group, an ester group, an acetal group, a carboxyalkoxy group, or a carbonate ester group, and the alkoxy group, the ester group, the acetal group, the carboxyalkoxy group, or the carbonate ester group of Z optionally has a substituent; and
p is an integer of 1 or more, m is an integer of 1 or more, n is an integer of 0 or more, and r is an integer of 0 or more;

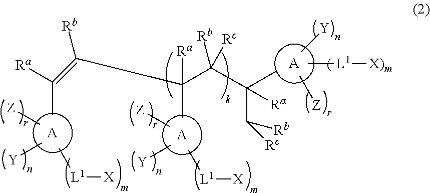

wherein
X, L¹, Y, R^{a}, R^{b}, R^{c}, A, Z, p, m, n, and r are the same as those described in the formula (1), and k represents an integer of 0 or more and 2 or less; and

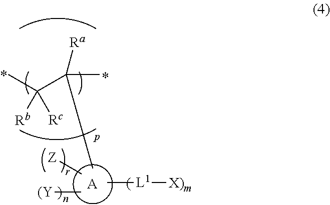

wherein X, L¹, Y, R^{a}, R^{b}, R^{c}, A, Z, p, m, n, and r are as defined in the formula (1); and
* is a site for binding with an adjacent constitutional unit.
   [27]

The resin composition according to the above [26], wherein the polymer further comprises a constitutional unit represented by the following formula (C6):

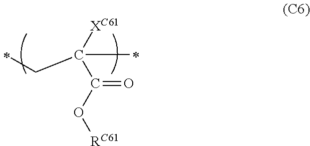

wherein
X^{C61} is a hydroxyl group or a halogen group;
each R^{C61} is independently an alkyl group having 1 to 20 carbon atoms; and
* is a site for binding with an adjacent constitutional unit.
   [28]

The resin composition according to the above or [27], wherein in the formula (1), the formula (2), and the formula (4), all r are 0, and at least one n is 1 or more.

[29]

A composition for film formation comprising the composition according to any one of the above [1] to [25], or the resin composition according to any one of the above to.

[30]

The composition for film formation according to any one of the above to [29], further comprising an acid generating agent, a base generating agent, or a base compound.

[31]

A resist pattern formation method comprising:
a step of forming a resist film on a substrate by using a composition for film formation containing the composition according to any one of the above [1] to or the resin composition according to any one of the above to;
a step of exposing a pattern on the resist film; and
a step of subjecting the resist film to a development treatment after exposure.
   [32]

A compound represented by the following formula (2):

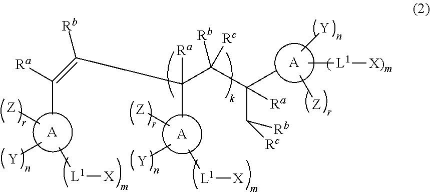

wherein
each X is independently I, F, Cl, Br, or an organic group having 1 to 30 carbon atoms and having 1 or more and 5 or less substituents selected from the group consisting of I, F, Cl, and Br;
each L¹ is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of L¹ optionally has a substituent;
each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, I, F, Cl, Br, or an organic group having 1 to 8 carbon atoms and optionally having a substituent;
A is an organic group having 6 to 30 carbon atoms; each Z is independently an alkoxy group, an ester group, an acetal group, a carboxyalkoxy group, or a carbonate ester group, and the alkoxy group, the ester group, the acetal group, the carboxyalkoxy group, or the carbonate ester group of Z optionally has a substituent;
p is an integer of 1 or more, m is an integer of 1 or more, n is an integer of 0 or more, and r is an integer of 0 or more; and
k represents an integer of 0 or more and 2 or less.

The compound according to the above [32], wherein in the formula (2), all r are 0, and at least one n is 1 or more.

### Advantageous Effects of Invention

The present invention can provide a composition, a resist composition, a pattern formation method, and a compound, by which a resist having suppressed defects that may be caused by a prepared film and a pattern after exposure due to aging accompanying the storage and the like can be obtained.

### DESCRIPTION OF EMBODIMENTS

Hereinafter, the embodiment of the present invention will be described (hereinafter, may be referred to as the “present embodiment”). The present embodiment is given in order to illustrate the present invention. The present invention is not limited to only the present embodiment.

As used herein, the meaning of each term is as follows.

The term “(meth)acrylate” means at least one selected from acrylate, haloacrylate, and methacrylate. The term haloacrylate means an acrylate in which the position of the methyl group in methacrylate is substituted with a halogen. Other terms having the expression (meth) should be similarly interpreted as (meth)acrylate.

The term “(co) polymer” means at least one selected from a homopolymer and a copolymer.

### [Composition]

The composition according to the present embodiment is a composition containing a compound (A) and a compound (B). The composition contains the compound (A) represented by the formula (1) described later and the compound (B) represented by the formula (2) described later.

### [Compound (A)]

The compound according to the present embodiment (A) is preferably represented by the following formula (1). The compound (A) preferably comprises a functional group for improving solubility in an alkaline developing solution by the action of an acid or a base. The functional group for improving solubility in an alkaline developing solution by the action of an acid or a base is preferably contained in any of Z, Y, and X described below.

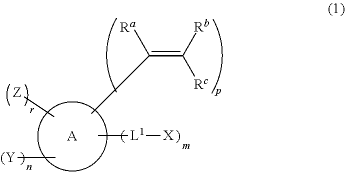

In the formula (1),
each X is independently I, F, Cl, Br, or an organic group having 1 to 30 carbon atoms and having 1 or more and 5 or less substituents selected from the group consisting of I, F, Cl, and Br. Among them, each X is preferably independently, I, F, Cl, or Br, more preferably independently, I, F, or Br, more preferably independently, I or F, and further preferably independently I.

In the present embodiment, unless otherwise defined, the term “substituted” means that one or more hydrogen atoms in a functional group are substituted with a substituent. Examples of the “substituent” include, but are not particularly limited to, a halogen atom, a hydroxyl group, a carboxyl group, a cyano group, a nitro group, a thiol group, a heterocyclic ring group, an alkyl group having 1 to 30 carbon atoms, an aryl group having 6 to 30 carbon atoms, an alkoxyl group having 1 to 30 carbon atoms, an alkenyl group having 2 to 30 carbon atoms, an alkynyl group having 2 to 30 carbon atoms, an acyl group having 1 to 30 carbon atoms, and an amino group having 0 to 30 carbon atoms.

The alkyl group may be any of a linear aliphatic hydrocarbon group, a branched aliphatic hydrocarbon group, and a cyclic aliphatic hydrocarbon group.

Examples of the alkyl group having 1 to 30 carbon atoms include, but are not limited to, a methyl group, an ethyl group, an n-propyl group, an i-propyl group, an n-butyl group, an i-butyl group, a t-butyl group, an n-pentyl group, an n-hexyl group, an n-dodecyl group, and a valeryl group.

Examples of the aryl group having 6 to 30 carbon atoms include, but are not limited to, a phenyl group, a naphthalene group, a biphenyl group, an anthracyl group, a pyrenyl group, and a perylene group.

Examples of the alkenyl group having 2 to 30 carbon atoms include, but are not limited to, an ethynyl group, a propenyl group, a butynyl group, and a pentynyl group.

Examples of the alkynyl group having 2 to 30 carbon atoms include, but are not limited to, an acetylene group and an ethynyl group.

Examples of an alkoxy group having 1 to 30 carbon atoms include, but are not limited to, a methoxy group, an ethoxy group, a propoxy group, a butoxy group, and pentoxy.

Examples of “the organic group having 1 to 30 carbon atoms and having 1 or more and 5 or less substituents selected from the group consisting of I, F, Cl, and Br” include, but are not particularly limited to, a monoiodophenyl group, a diiodophenyl group, a triiodophenyl group, a tetraiodophenyl group, a pentaiodophenyl group, a monoiodohydroxyphenyl group, a diiodohydroxyphenyl group, a triiodohydroxyphenyl group, a monoiodoacetoxyphenyl group, a diiodoacetoxyphenyl group, a triiodoacetoxyphenyl group, a monoiodo-t-butoxycarbonylphenyl group, a diiodo-t-butoxycarbonylphenyl group, a triiodo-t-butoxycarbonylphenyl group, a monoiododihydroxyphenyl group, a diiododihydroxyphenyl group, a triiododihydroxyphenyl group, a monoiododiacetoxyphenyl group, a diiododiacetoxyphenyl group, a triiododiacetoxyphenyl group, a monoiodo-di-t-butoxycarbonylphenyl group, a diiodo-di-t-butoxycarbonylphenyl group, a triiodo-di-t-butoxycarbonylphenyl group, a monoiodotrihydroxyphenyl group, a diiodotrihydroxyphenyl group, a monoiodotriacetoxyphenyl group, a diiodotriacetoxyphenyl group, a monoiodo-tri-t-butoxycarbonylphenyl group, a diiodo-tri-t-butoxycarbonylphenyl group, a monoiodonaphthyl group, a diiodonaphthyl group, a triiodonaphthyl group, a tetraiodonaphthyl group, a pentaiodonaphthyl group, a monoiodohydroxynaphthyl group, a diiodohydroxynaphthyl group, a triiodohydroxynaphthyl group, a monoiodoacetoxynaphthyl group, a diiodoacetoxynaphthyl group, a triiodoacetoxynaphthyl group, a monoiodo-t-butoxycarbonylnaphthyl group, a diiodo-t-butoxycarbonylnaphthyl group, a triiodo-t-butoxycarbonylnaphthyl group, a monoiododihydroxynaphthyl group, a diiododihydroxynaphthyl group, a triiododihydroxynaphthyl group, a monoiododiacetoxynaphthyl group, a diiododiacetoxynaphthyl group, a triiododiacetoxynaphthyl group, a monoiodo-di-t-butoxycarbonylnaphthyl group, a diiodo-di-t-butoxycarbonylnaphthyl group, a triiodo-di-t-butoxycarbonylnaphthyl group,
a monoiodotrihydroxynaphthyl group, a diiodotrihydroxynaphthyl group, a monoiodotriacetoxynaphthyl group, a diiodotriacetoxynaphthyl group, a monoiodo-tri-t-butoxycarbonylnaphthyl group, a diiodo-tri-t-butoxycarbonylnaphthyl group, a monoiodoadamantyl group, a diiodoadamantyl group, a triiodoadamantyl group, a monoiodohydroxyadamantyl group, a diiodohydroxynaphthyl group, a monoiodoacetoxynaphthyl group, a diiodoacetoxyadamantyl group, a monoiodo-t-butoxycarbonyladamantyl group, a diiodo-t-butoxycarbonyladamantyl group, a triiodo-t-butoxycarbonyladamantyl group, a monoiododihydroxyadamantyl group, a monoiododiacetoxyadamantyl group, a monoiodo-di-t-butoxycarbonyladamantyl group, a monoiodocyclohexyl group, a diiodocyclohexyl group, a triiodocyclohexyl group, a monoiodohydroxycyclohexyl group, a diiodohydroxynaphthyl group, a monoiodoacetoxynaphthyl group, a diiodoacetoxycyclohexyl group, a monoiodo-t-butoxycarbonylcyclohexyl group, a diiodo-t-butoxycarbonylcyclohexyl group, a triiodo-t-butoxycarbonylcyclohexyl group, a monoiododihydroxycyclohexyl group, a monoiododiacetoxycyclohexyl group, a monoiodo-di-t-butoxycarbonylcyclohexyl group,
a monobromophenyl group, a dibromophenyl group, a tribromophenyl group, a tetrabromophenyl group, a pentabromophenyl group, a monobromohydroxyphenyl group, a dibromohydroxyphenyl group, a tribromohydroxyphenyl group, a monobromoacetoxyphenyl group, a dibromoacetoxyphenyl group, a tribromoacetoxyphenyl group, a monobromo t-butoxycarbonylphenyl group, a dibromo t-butoxycarbonylphenyl group, a tribromo t-butoxycarbonylphenyl group, a monobromodihydroxyphenyl group, a dibromodihydroxyphenyl group, a tribromodihydroxyphenyl group, a monobromodiacetoxyphenyl group, a dibromodiacetoxyphenyl group, a tribromodiacetoxyphenyl group, a monobromo di-t-butoxycarbonylphenyl group, a dibromo di-t-butoxycarbonylphenyl group, a tribromo di-t-butoxycarbonylphenyl group,
a monobromotrihydroxyphenyl group, a dibromotrihydroxyphenyl group, a monobromotriacetoxyphenyl group, a dibromotriacetoxyphenyl group, a monobromotri-t-butoxycarbonylphenyl group, a dibromotri-t-butoxycarbonylphenyl group, a monobromoadamantyl group, a dibromoadamantyl group, a tribromoadamantyl group, a monobromohydroxyadamantyl group, a dibromohydroxynaphthyl group, a monobromoacetoxynaphthyl group, a dibromoacetoxyadamantyl group, a monobromo t-butoxycarbonyladamantyl group, a dibromo t-butoxycarbonyladamantyl group, a tribromo t-butoxycarbonyladamantyl group, a monobromodihydroxyadamantyl group, a monobromodiacetoxyadamantyl group, a monobromo-di-t-butoxycarbonyladamantyl group,
a monofluorophenyl group, a difluorophenyl group, a trifluorophenyl group, a tetrafluorophenyl group, a pentafluorophenyl group, a monofluorohydroxyphenyl group, a difluorohydroxyphenyl group, a trifluorohydroxyphenyl group, a monofluoroacetoxyphenyl group, a difluoroacetoxyphenyl group, a trifluoroacetoxyphenyl group, a monofluoro t-butoxycarbonylphenyl group, a difluoro t-butoxycarbonylphenyl group, a trifluoro t-butoxycarbonylphenyl group, a monofluorodihydroxyphenyl group, a difluorodihydroxyphenyl group, a trifluorodihydroxyphenyl group, a monofluorodiacetoxyphenyl group, a difluorodiacetoxyphenyl group, a trifluorodiacetoxyphenyl group, a monofluorodi-t-butoxycarbonylphenyl group, a difluorodi-t-butoxycarbonylphenyl group, a trifluorodi-t-butoxycarbonylphenyl group, a monofluorotrihydroxyphenyl group, a difluorotrihydroxyphenyl group, a monofluorotriacetoxyphenyl group, a difluorotriacetoxyphenyl group, a monofluorotri-t-butoxycarbonylphenyl group, a difluorotri-t-butoxycarbonylphenyl group, a monofluoroadamantyl group, a difluoroadamantyl group, a trifluoroadamantyl group, a monofluorohydroxyadamantyl group, a difluorohydroxynaphthyl group, a monofluoroacetoxynaphthyl group, a difluoroacetoxyadamantyl group, a monofluoro t-butoxycarbonyladamantyl group, a difluoro t-butoxycarbonyladamantyl group, a trifluoro t-butoxycarbonyladamantyl group, a monofluorodihydroxyadamantyl group, a monofluorodiacetoxyadamantyl group, a monofluoro-di-t-butoxycarbonyladamantyl group,
a monochlorophenyl group, a dichlorophenyl group, a trichlorophenyl group, a tetrachlorophenyl group, a pentachlorophenyl group, a monochlorohydroxyphenyl group, a dichlorohydroxyphenyl group, a trichlorohydroxyphenyl group, a monochloroacetoxyphenyl group, a dichloroacetoxyphenyl group, a trichloroacetoxyphenyl group, a monochloro t-butoxycarbonylphenyl group, a dichloro t-butoxycarbonylphenyl group, a trichloro t-butoxycarbonylphenyl group, a monochlorodihydroxyphenyl group, a dichlorodihydroxyphenyl group, a trichlorodihydroxyphenyl group, a monochlorodiacetoxyphenyl group, a dichlorodiacetoxyphenyl group, a trichlorodiacetoxyphenyl group, a monochlorodi-t-butoxycarbonylphenyl group, a dichlorodi-t-butoxycarbonylphenyl group, a trichlorodi-t-butoxycarbonylphenyl group,
a monochlorotrihydroxyphenyl group, a dichlorotrihydroxyphenyl group, a monochlorotriacetoxyphenyl group, a dichlorotriacetoxyphenyl group, a monochlorotri-t-butoxycarbonylphenyl group, a dichlorotri-t-butoxycarbonylphenyl group, a monochloroadamantyl group, a dichloroadamantyl group, a trichloroadamantyl group, a monochlorohydroxyadamantyl group, a dichlorohydroxynaphthyl group, a monochloroacetoxynaphthyl group, a dichloroacetoxyadamantyl group, a monochloro t-butoxycarbonyladamantyl group, a dichloro t-butoxycarbonyladamantyl group, a trichloro t-butoxycarbonyladamantyl group, a monochlorodihydroxyadamantyl group, a monochlorodiacetoxyadamantyl group, and a monochlorodi-t-butoxycarbonyladamantyl group.

For example, X may be an aromatic group into which one or more F, Cl, Br, or I are introduced. Examples of such an aromatic group include a group having a benzene ring such as a phenyl group and having 1 to 5 halogens, and a group having a heteroaromatic ring such as furan, thiophene, and pyridine and having 1 to 5 halogens. Examples thereof include a phenyl group having 1 to 5 I, a phenyl group having 1 to 5 F, a phenyl group having 1 to 5 Cl, a phenyl group having 1 to 5 Br, a naphthyl group having 1 to 5 F, a naphthyl group having 1 to 5 Cl, a naphthyl group having 1 to 5 Br, a naphthyl group having 1 to 5 I, a phenol group having 1 to 4 F, a phenol group having 1 to 4 Cl, a phenol group having 1 to 4 Br, a phenol group having 1 to 4 I, a furan group having 1 to 3 F, a furan group having 1 to 3 Cl, a furan group having 1 to 3 Br, a furan group having 1 to 3 I, a thiophene group having 1 to 3 F, a thiophene group having 1 to 3 Cl, a thiophene group having 1 to 3 Br, a thiophene group having 1 to 3 I, a pyridine group having 1 to 4 F, a pyridine group having 1 to 4 Cl, a pyridine group having 1 to 4 Br, a pyridine group having 1 to 4 I, a benzodiazole group having 1 to 5 F, a benzodiazole group having 1 to 5 Cl, a benzodiazole group having 1 to 5 Br, a benzodiazole group having 1 to 5 I, a benzimidazole group having 1 to 4 F, a benzimidazole group having 1 to 4 Cl, a benzimidazole group having 1 to 4 Br, a benzimidazole group having 1 to 4 I, a benzoxazole group having 1 to 4 F, a benzoxazole group having 1 to 4 Cl, a benzoxazole group having 1 to 4 Br, a benzoxazole group having 1 to 4 I, a benzothiophene group having 1 to 4 F, a benzothiophene group having 1 to 4 Cl, a benzothiophene group having 1 to 4 Br, and a benzothiophene group having 1 to 4 I.

X may be an alicyclic group into which one or more F, Cl, Br, or I are introduced. Examples of such an alicyclic group include an adamantyl group having 1 to 3 halogens, an adamantyl group having 1 to 3 F, an adamantyl group having 1 to 3 Cl, an adamantyl group having 1 to 3 Br, an adamantyl group having 1 to 3 I, a cyclopentyl group having 1 to 3 F, a cyclopentyl group having 1 to 3 Cl, a cyclopentyl group having 1 to 3 Br, a cyclopentyl group having 1 to 3 I, a bicycloundecyl group having 1 to 3 F, a bicycloundecyl group having 1 to 3 Cl, a bicycloundecyl group having 1 to 3 Br, a bicycloundecyl group having 1 to 3 I, a norbornyl group having 1 to 3 F, a norbornyl group having 1 to 3 Cl, a norbornyl group having 1 to 3 Br, and a norbornyl group having 1 to 3 I.

L¹ is a single bond, an ether group, an ester group, a thioether group, an amino group, a thioester group, an acetal group, a phosphine group, a phosphone group, a urethane group, a urea group, an amide group, an imide group, or a phosphate group. Among them, L¹ is preferably a single bond. The ether group, the ester group, the thioether group, the amino group, the thioester group, the acetal group, the phosphine group, the phosphone group, the urethane group, the urea group, the amide group, the imide group, or the phosphate group of L¹ optionally has a substituent. Examples of such a substituent are as described above.

From the viewpoint of improving the exposure sensitivity, it is preferable that X in the formula (1) be I and L¹ be a single bond.

m is an integer of 1 or more, preferably an integer of 1 or more and 5 or less, more preferably an integer of 1 or more and 4 or less, further preferably 1 or more and 3 or less, and still more preferably 1 or 2.

Each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent.

Examples of Y include at least one group selected from the group consisting of a hydroxyl group, an alkoxy group [*³—O—R²], an ester group [*³—O—(C═O)—R² or 3—(C═O)—O—R²], an acetal group [*³—O—(C(R²¹)₂)—O—R² (wherein each R²¹ is independently H or a hydrocarbon group having 1 to 10 carbon atoms)], a carboxyalkoxy group [*³—O—R²²—(C═O)—O—R² (wherein R²² is a divalent hydrocarbon group having 1 to 10 carbon atoms)], and a carbonate ester group [*³—O—(C═O)—O—R²]. The ester group is preferably a tertiary ester group, from the viewpoint of achieving high sensitivity. In the formula, *³ is a site for binding with A.

Among them, it is preferable to contain any one of a hydroxyl group, a tertiary ester group, an acetal group, a carbonate ester group, or a carboxyalkoxy group as Y, above all, more preferable to contain any one of a hydroxyl group, an acetal group, a carbonate ester group, or a carboxyalkoxy group, and further preferable to contain any one of a hydroxyl group, an acetal group, or a carboxyalkoxy group, from the viewpoint of high sensitivity. From the viewpoint of producing a polymer having a stable quality by radical polymerization, it is preferable to contain any one of an ester group, a carboxyalkoxy group, and a carbonate ester group as Y.

Each Y may preferably independently contain a group represented by the following formula (Y-1).

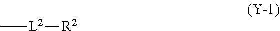

In the formula (Y-1),
L² is a group which is cleaved by the action of an acid or a base. Examples of the group which is cleaved by the action of an acid or a base include at least one divalent linking group selected from the group consisting of an ester group [*]—O—(C═O)—*² or *¹—(C═O)—O—*²], an acetal group [*¹—O—(C(R²¹)₂)—O—*² (each R²¹ is independently H or a hydrocarbon group having 1 to 10 carbon atoms)], a carboxyalkoxy group [*¹—O—R²²—(C═O)—O—*² (R²² is a divalent hydrocarbon group having 1 to 10 carbon atoms)], and a carbonate ester group [*¹—O—(C═O)—O—*²]. The ester group is preferably a tertiary ester group, from the viewpoint of achieving high sensitivity. In the formula, *¹ is a site for binding with A, and *² is a site for binding with R². Among them, L² is preferably a tertiary ester group, an acetal group, a carbonate ester group, or a carboxyalkoxy group, more preferably an acetal group, a carbonate ester group, or a carboxyalkoxy group, and further preferably an acetal group or a carboxyalkoxy group, from the viewpoint of high sensitivity. From the viewpoint of producing a polymer having a stable quality by radical polymerization, an ester group, a carboxyalkoxy group, and a carbonate ester group are preferable.

As another effect, Y is preferably a group represented by the formula (Y-1) to control the polymerization properties of resin and the degree of polymerization in a desired range, when the compound (A) of the present embodiment is used as a polymerization unit of a copolymer. Since the compound A has a large influence on activity species in the polymer formation reaction due to having an X group and thus the desired control is difficult, variation of copolymer formation derived from the hydrophilic group and polymerization inhibition can be suppressed by having a group represented by the formula (Y-1) in the hydrophilic group in the compound A as a protecting group.

R² is a linear, branched, or cyclic aliphatic group having 1 to 30 carbon atoms, an aromatic group having 6 to 30 carbon atoms, a linear, branched, or cyclic aliphatic group containing a heteroatom and having 1 to 30 carbon atoms, or a linear, branched, or cyclic aromatic group containing a heteroatom and having 1 to 30 carbon atoms, and the aliphatic group, the aromatic group, the aliphatic group containing a heteroatom, and the aromatic group containing a heteroatom of R² optionally further have a substituent. As the substituent here, the aforementioned substituents are used, but a linear, branched, or cyclic aliphatic group having 1 to 20 carbon atoms or an aromatic group having 6 to 20 carbon atoms are preferable. Among them, R² is preferably an aliphatic group. The aliphatic group in R² is preferably a branched or cyclic aliphatic group. The number of carbon atoms of the aliphatic group is preferably 1 or more and 20 or less, more preferably 3 or more and 10 or less, and further preferably 4 or more and 8 or less. Examples of the aliphatic group include, but are not particularly limited to, a methyl group, an isopropyl group, a sec-butyl group, a tert-butyl group, an isobutyl group, a cyclohexyl group, a methylcyclohexyl group, and an adamantyl group. Among them, a tert-butyl group, a cyclohexyl group, or an adamantyl group is preferable.

L² is preferably *¹-(C═O)—O—*² or a carboxyalkoxy group, because, when L1 is cleaved by the action of an acid or a base, a carboxylic acid group is formed and the difference in the solubility and the difference in the dissolution rate between a cleaved portion and an uncleaved portion are increased in the development treatment, so that the resolution is improved and, in particular, residues at the pattern bottom in thin line patterns are suppressed.

Specific examples of Y also include the followings.

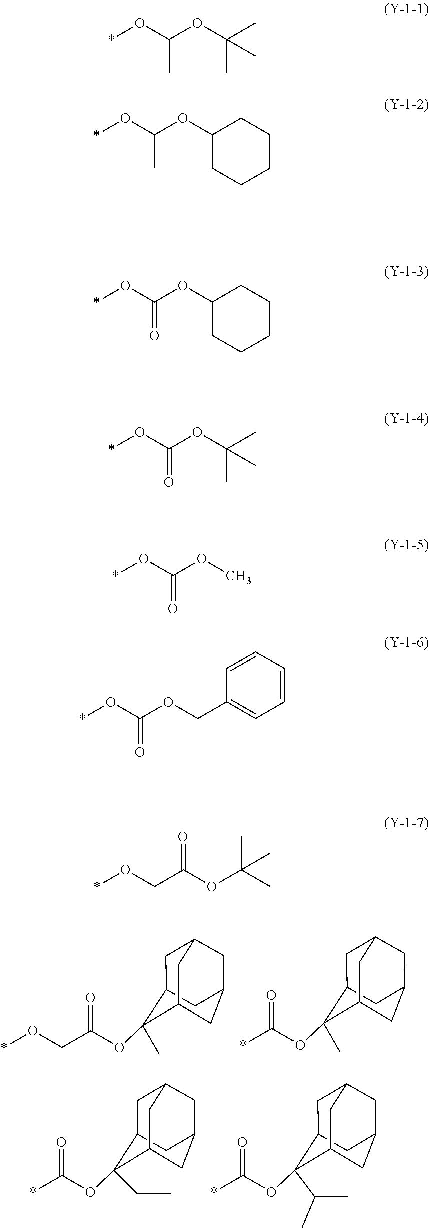

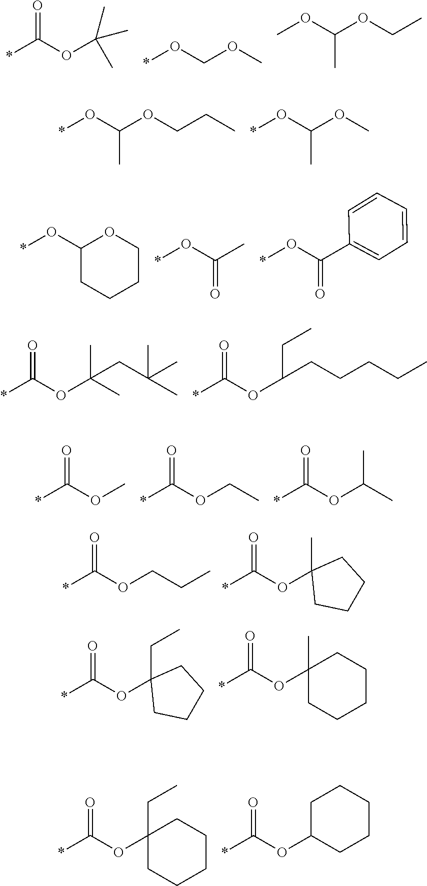

Examples of the alkoxy group that can be used as Y include an alkoxy group having 1 or more carbon atoms, and from the viewpoint of the solubility of a resin after the compound is combined with other monomers to form the resin, an alkoxy group having 2 or more carbon atoms is preferable, and an alkoxy group having 3 or more carbon atoms or having a cyclic structure is preferable.

Specific examples of the alkoxy group that can be used as Y include, but are not limited to, the followings.

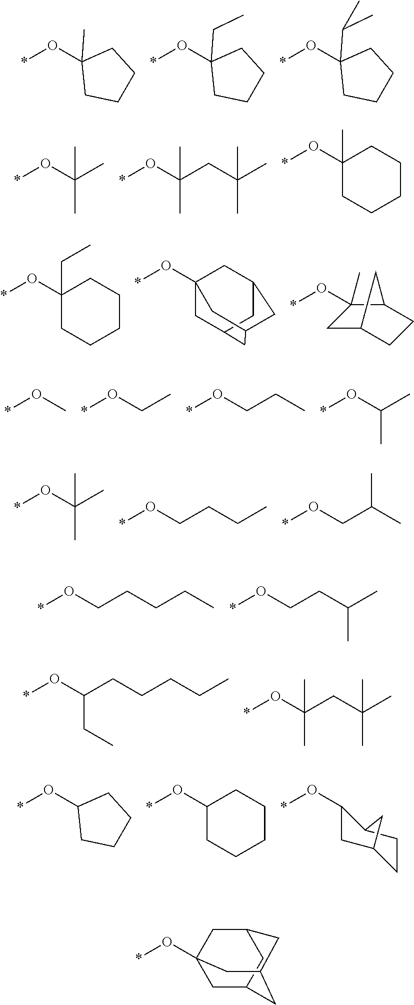

As the amino group and amide group that can be used as Y, a primary amino group, a secondary amino group, a tertiary amino group, a group having a quaternary ammonium salt structure, an amide having a substituent, or the like can be arbitrarily used. Specific examples of the amino group or amide group that can be used include, but are not limited to, the followings.

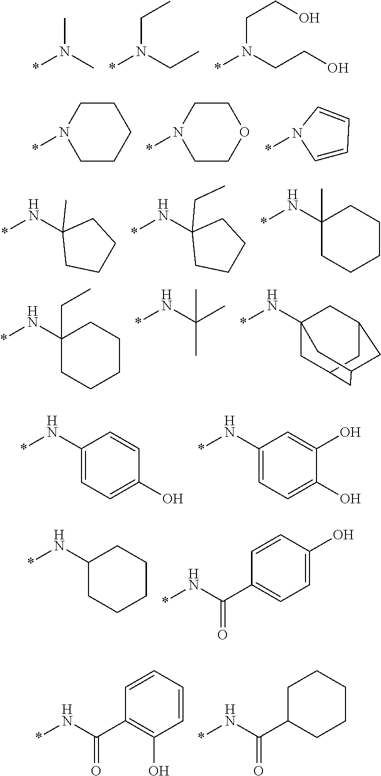

n is an integer of 0 or more, preferably an integer of 1 or more, more preferably an integer of 1 or more and 5 or less, further preferably an integer of 1 or more and 3 or less, still more preferably 1 or 2, and particularly preferably 2.

Each of R^{a}, R^{b}, and R^{c} is independently H, I, F, Cl, Br, or an organic group having 1 to 8 carbon atoms and optionally having a substituent. The combination of R^{a}, R^{b}, and R^{c} is preferably such that all of R^{a}, R^{b}, and R^{c} are H (hydrogen atoms). Examples of the substituent of the organic group having 1 to 8 carbon atoms include, but are not particularly limited to, I, F, Cl, Br, or other substituents. Examples of other substituents include, but are not particularly limited to, a hydroxyl group, an alkoxy group, an ester group, an acetal group, a carbonate ester group, a nitro group, an amino group, a carboxyl group, a thiol group, an ether group, a thioether group, a phosphine group, a phosphone group, a urethane group, a urea group, an amide group, an imide group, and a phosphate group. Among them, the alkoxy group, the ester group, the carbonate ester group, the amino group, the ether group, the thioether group, the phosphine group, the phosphone group, the urethane group, the urea group, the amide group, the imide group, and the phosphate group optionally further have a substituent. Examples of the substituent here include a linear, branched, or cyclic aliphatic group having 1 to 7 carbon atoms.

The number of carbon atoms of the organic group optionally having a substituent in R^{a}, R^{b}, and R^{c} is preferably 1 to 6.

Examples of the organic group having 1 to 8 carbon atoms and optionally having a substituent include, but are not particularly limited to, a linear or branched aliphatic hydrocarbon group having 1 to 8 carbon atoms, a cycloaliphatic hydrocarbon group having 4 to 8 carbon atoms, and an aromatic group having 6 to 8 carbon atoms and optionally having a heteroatom.

Examples of the linear or branched aliphatic hydrocarbon group having 1 to 8 carbon atoms include, but are not particularly limited to, a methyl group, an ethyl group, an n-propyl group, an isopropyl group, an n-butyl group, an isobutyl group, a tert-butyl group, an n-pentyl group, an n-hexyl group, an n-heptyl group, an n-octyl group, and a 2-ethylhexyl group.

Examples of the cycloaliphatic hydrocarbon group include, but are not particularly limited to, a cyclohexyl group, a cycloheptyl group, a cyclooctyl group, and a dicyclopentyl group. Further, an aromatic group optionally having a heteroatom such as a benzodiazole group, a benzotriazole group, and a benzothiazole group can be arbitrarily selected. A combination of these organic groups can also be selected.

Examples of the aromatic group having 6 to 8 carbon atoms and optionally having a heteroatom include, but are not particularly limited to, a phenyl group, a benzodiazole group, a benzotriazole group, and a benzothiazole group.

Among the organic group having 1 to 8 carbon atoms and optionally having a substituent, a methyl group is preferable, from the viewpoint of producing a polymer having a stable quality.

When R^{a} is an organic group having 1 or more and 8 or less carbon atoms, or a group selected from F, Cl, and I, it is preferable that the sum of n and r be 0 or more, r be 0, and n be 1 or more.

A is an organic group having 6 to 30 carbon atoms. A may be a monocyclic organic group or a polycyclic organic group, or optionally has a substituent. A is preferably an aromatic ring optionally having a substituent. The number of carbon atoms of A is preferably 6 to 14, and more preferably 6 to 10.

A is preferably a group represented by any of the following formulas (A-1) to (A-4), more preferably a group represented by any of the following formulas (A-1) to (A-2) (that is, a benzene ring or a naphthalene ring), and further preferably a group represented by the following formula (A-1).

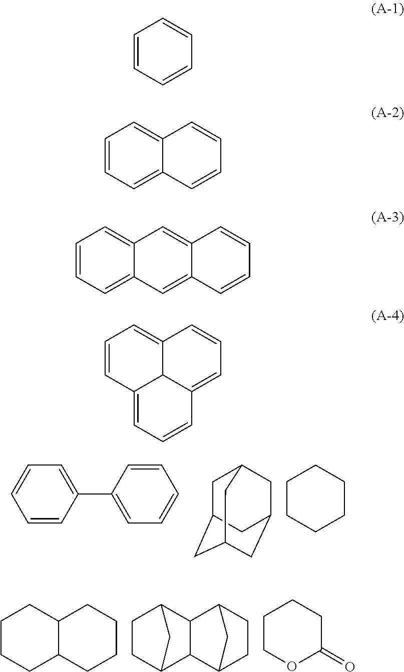

A may be an alicyclic structure optionally having a substituent. Here, the “alicyclic structure” refers to a saturated or unsaturated carbocycle having no aromatic properties. Examples of the alicyclic structure include a saturated or unsaturated carbocycle having 3 to 30 carbon atoms, and a saturated or unsaturated carbocycle having 3 to 20 carbon atoms is preferable. Examples of the alicyclic structure include a group having cyclopropyl, cyclobutyl, cyclopentyl, cyclohexyl, cycloheptyl, cyclooctyl, cyclononyl, cyclodecyl, cycloicosyl, cyclopropenyl, cyclobutenyl, cyclopentenyl, cyclohexenyl, cycloheptenyl, cyclooctenyl, cyclopentadienyl, cyclooctadienyl, adamantyl, bicycloundecyl, decahydronaphthyl, norbornyl, norbornadienyl, cubane, basketane, or housane.

A may also be a heterocyclic structure optionally having a substituent. Examples of the heterocyclic structure include, but are not particularly limited to, a nitrogen-containing cyclic structure such as pyridine, piperidine, piperidone, benzodiazole, and benzotriazole; a cyclic ether such as triazine, a cyclic urethane structure, cyclic urea, cyclic amide, cyclic imide, furan, pyran, and dioxolane; an alicyclic group having a lactone structure such as caprolactone, butyrolactone, nonalactone, decalactone, undecalactone, bicycloundecalactone, and phthalide.

p is an integer of 1 or more, preferably an integer of 1 or more and 3 or less, more preferably an integer of 1 or more and 2 or less, and further preferably 1.

Each Z is independently an alkoxy group, an ester group, an acetal group, a carboxyalkoxy group, or a carbonate ester group. These groups optionally have a substituent, and examples of the substituent include a hydrocarbon group having 1 to 60 carbon atoms and optionally further having a substituent. r is an integer of 0 or more, preferably an integer of 0 or more and 2 or less, more preferably an integer of 0 or more and 1 or less, and further preferably 0. That is, in the formula (1) and in each formula such as the formulas (2) and (4), which will be mentioned later, it is preferable that all r be 0 and at least one n be 1 or more.

Examples of Z include at least one group selected from the group consisting of an alkoxy group [*³—O—R²], an ester group [*³—O—(C═O)—R² or *³-(C═O)—O—R²], an acetal group [*³—O—(C(R²¹)₂)—O—R² (wherein each R²¹ is independently H or a hydrocarbon group having 1 to 10 carbon atoms)], a carboxyalkoxy group [*³—O—R²²—(C═O)—O—R² (wherein R²² is a divalent hydrocarbon group having 1 to 10 carbon atoms)], and a carbonate ester group [*³—O—(C═O)—O—R²]. The ester group is preferably a tertiary ester group, from the viewpoint of achieving high sensitivity. In the formula, *³ is a site for binding with A.

Among them, Z is preferably a tertiary ester group, an acetal group, a carbonate ester group, or a carboxyalkoxy group, more preferably an acetal group, a carbonate ester group, or a carboxyalkoxy group, and further preferably an acetal group or a carboxyalkoxy group, from the viewpoint of high sensitivity. From the viewpoint of producing a polymer having a stable quality by radical polymerization, an ester group, a carboxyalkoxy group, and a carbonate ester group are preferable.

As described above, n is an integer of 0 or more, r is an integer of 0 or more, but at least one of n or r may be an integer of 1 or more. That is, n+r in the formula (1) may be an integer of 1 or more.

From the viewpoint of suppressing the etching defect, n in the formula (1) is preferably an integer of 2 or more.

Among the compounds (A) described above, a compound represented by the following formula (Ia) is preferable.

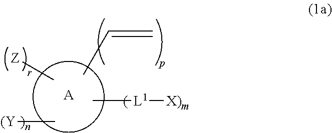

(In the formula (Ia),
X, L¹, Y, A, Z, p, m, n, and r are as defined in the formula (1).)

Examples of the compound (A) according to the present embodiment (above all, the compound represented by the formula (Ia)) include compounds having the structures given below.

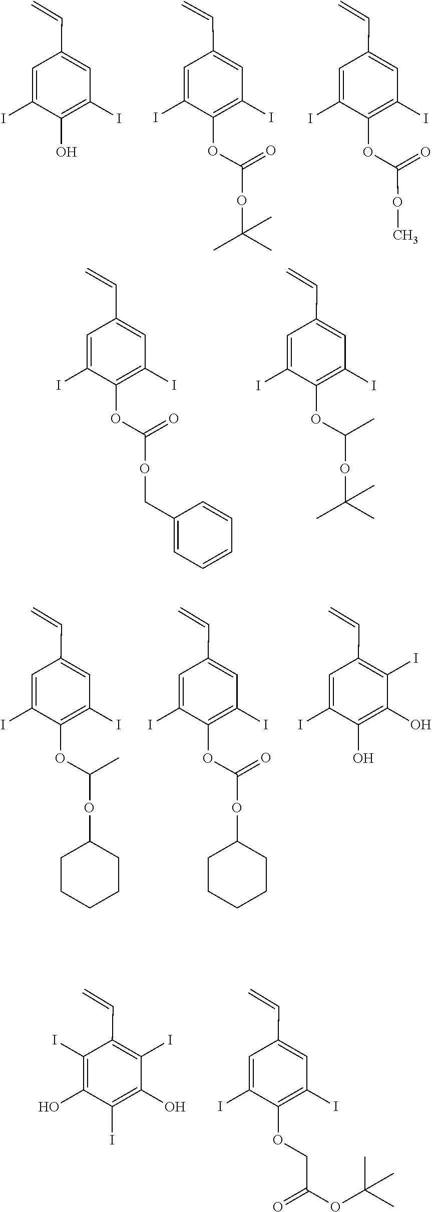

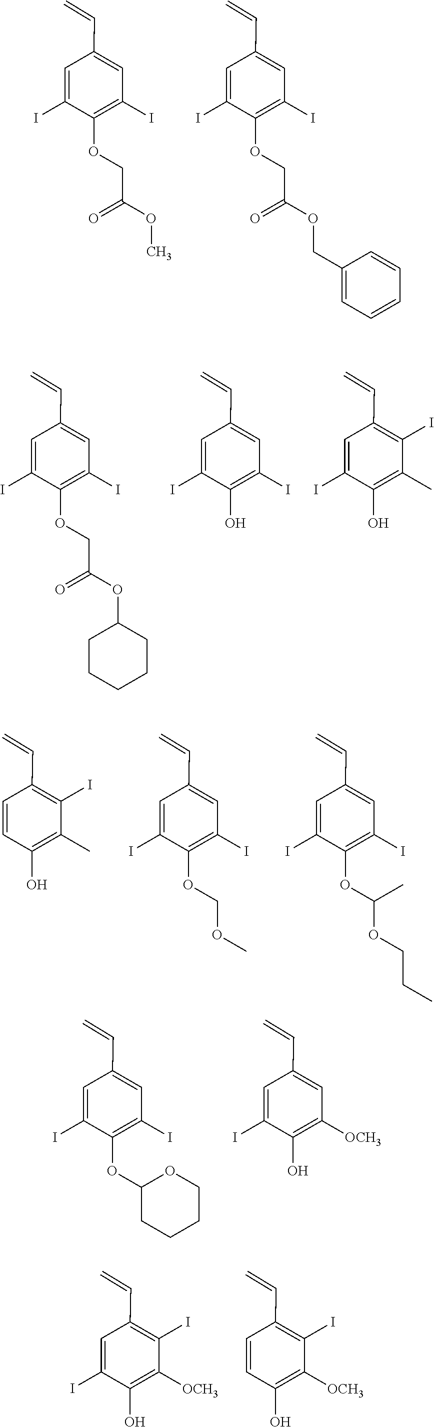

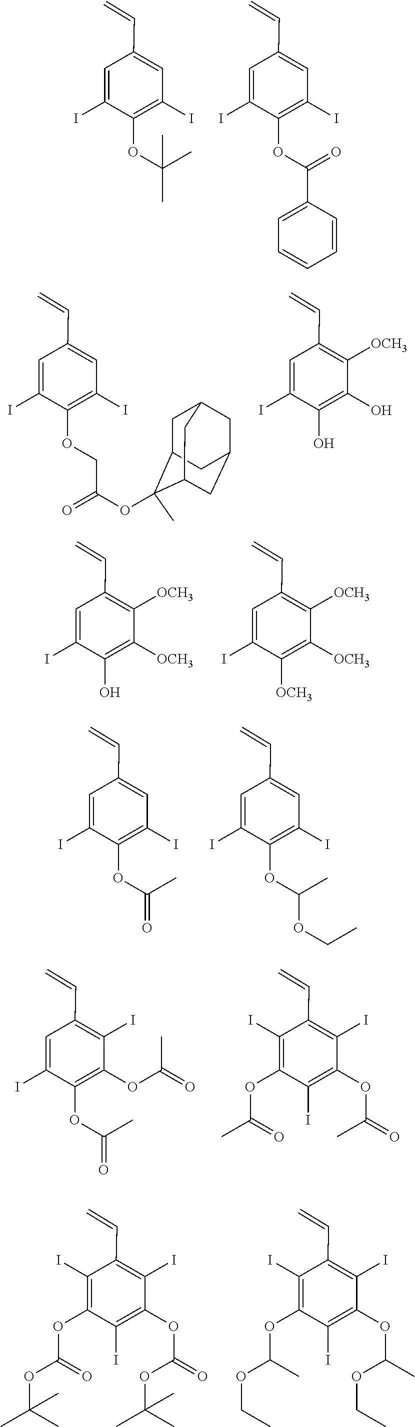

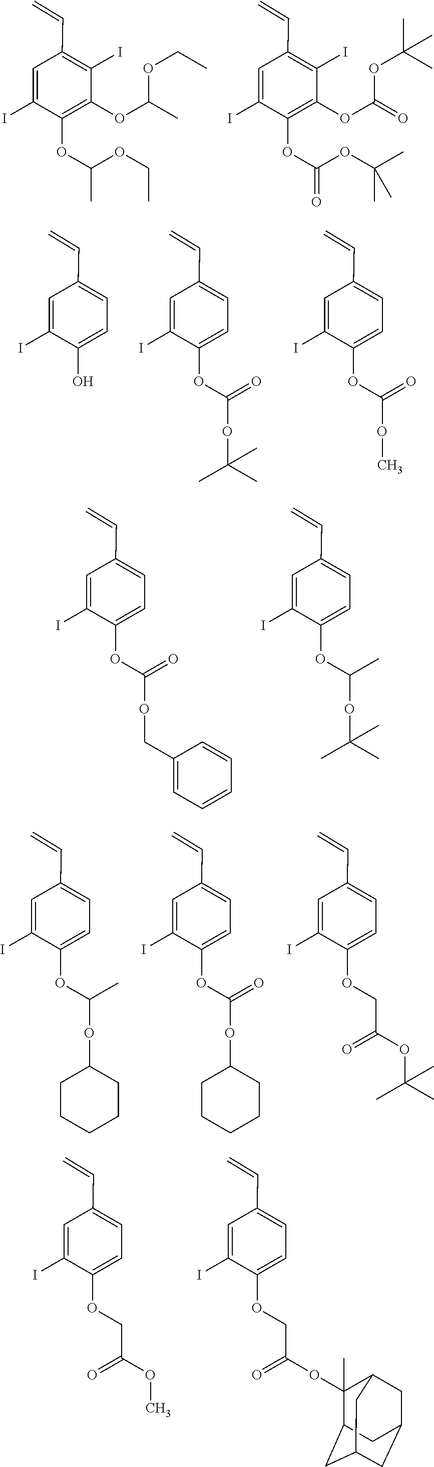

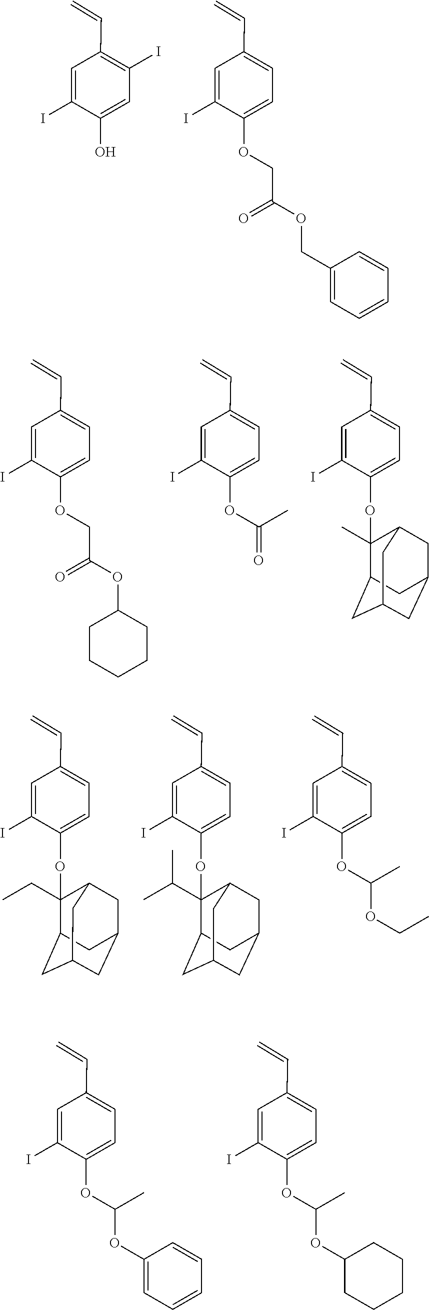

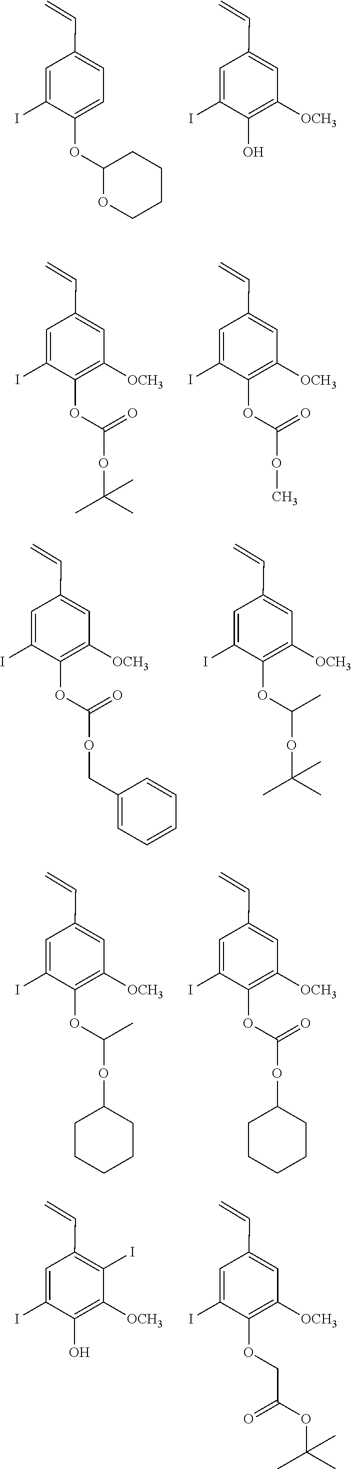

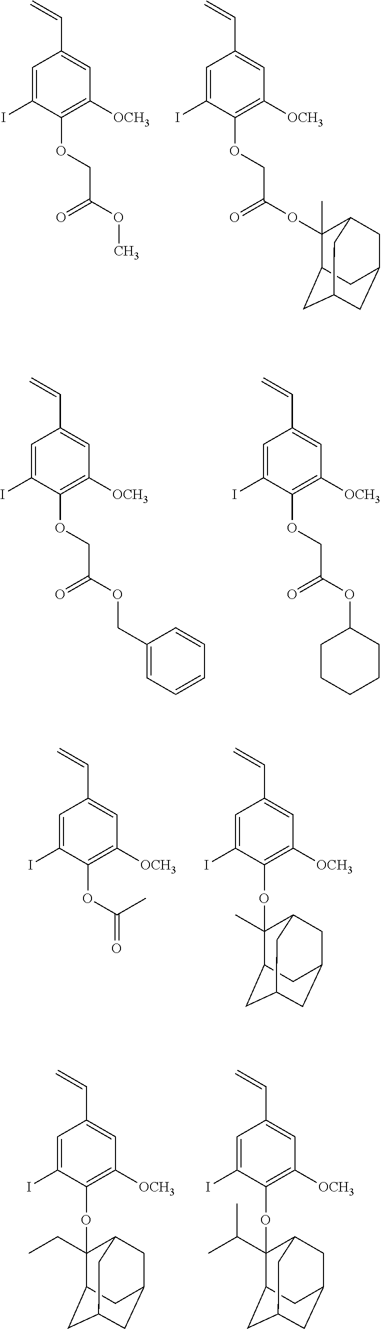

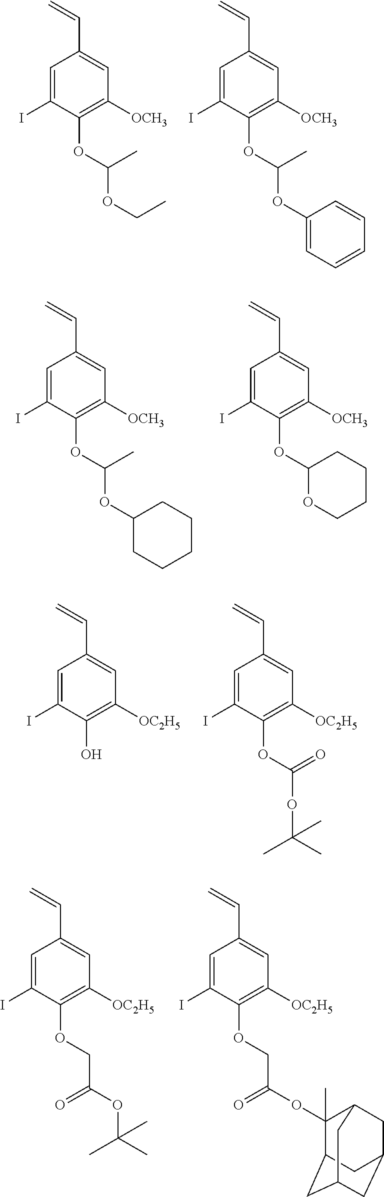

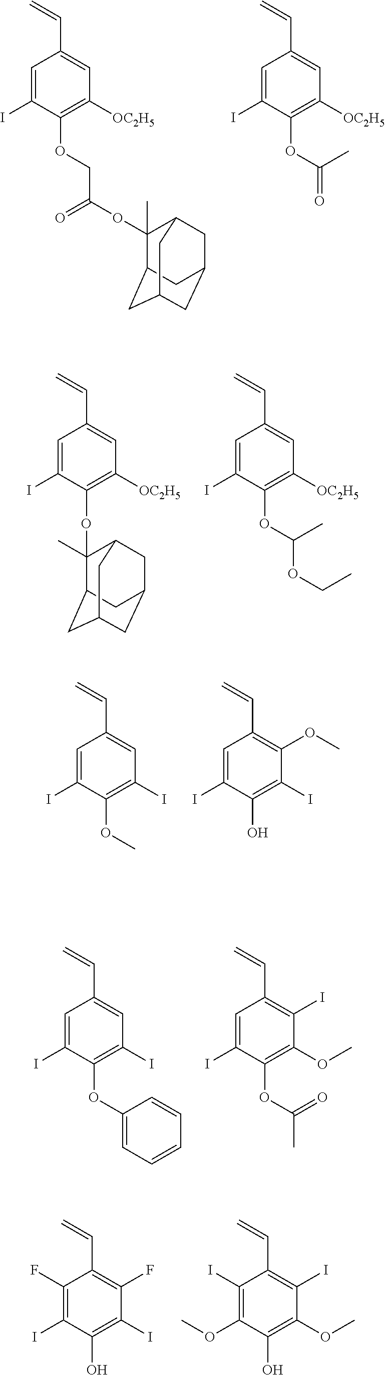

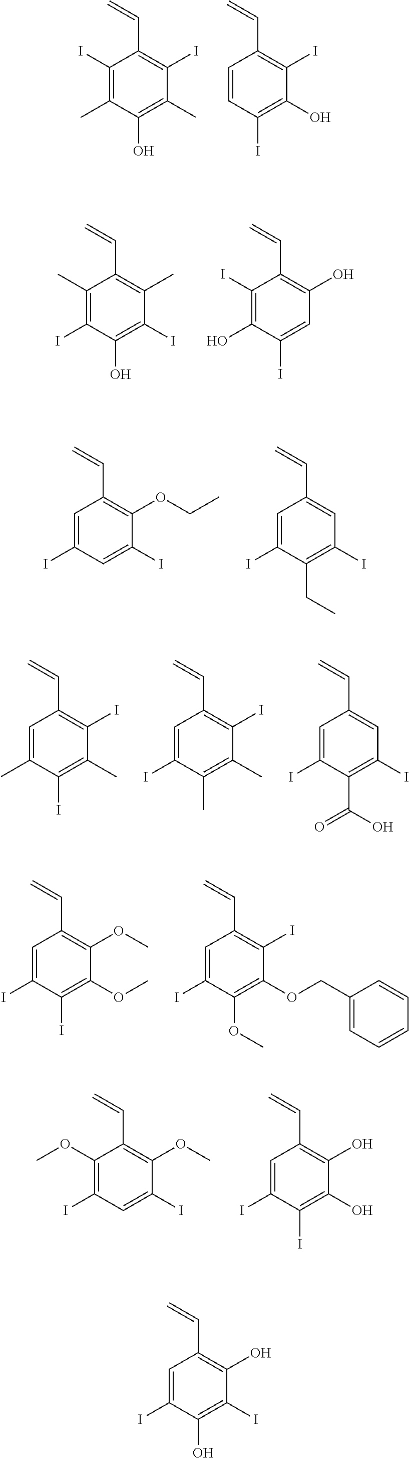

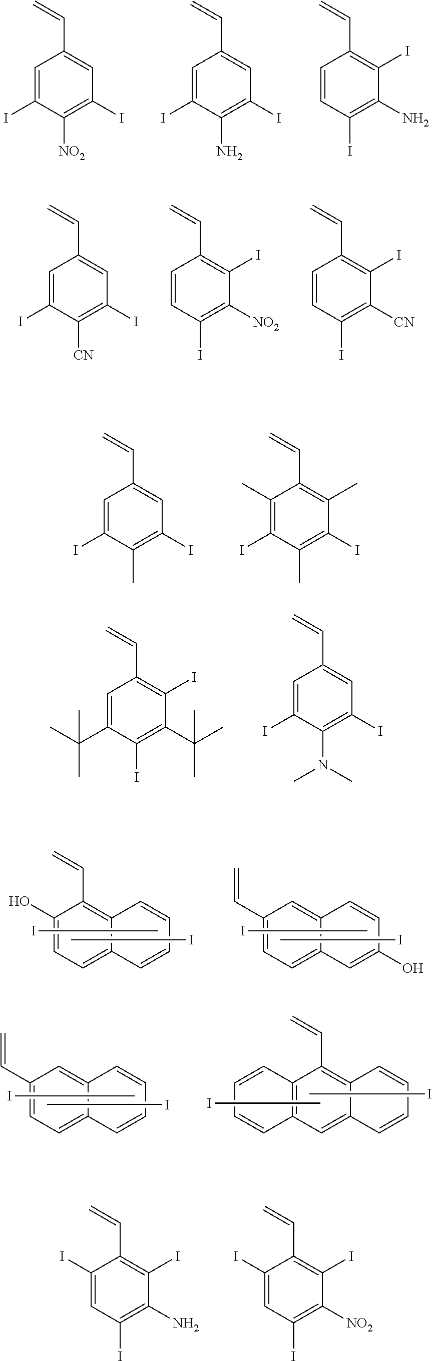

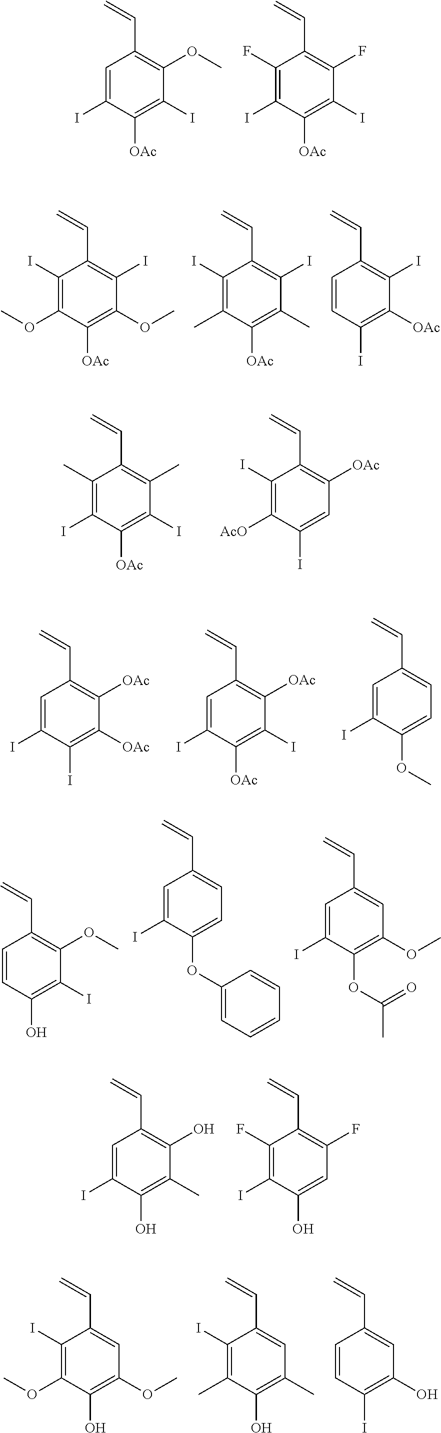

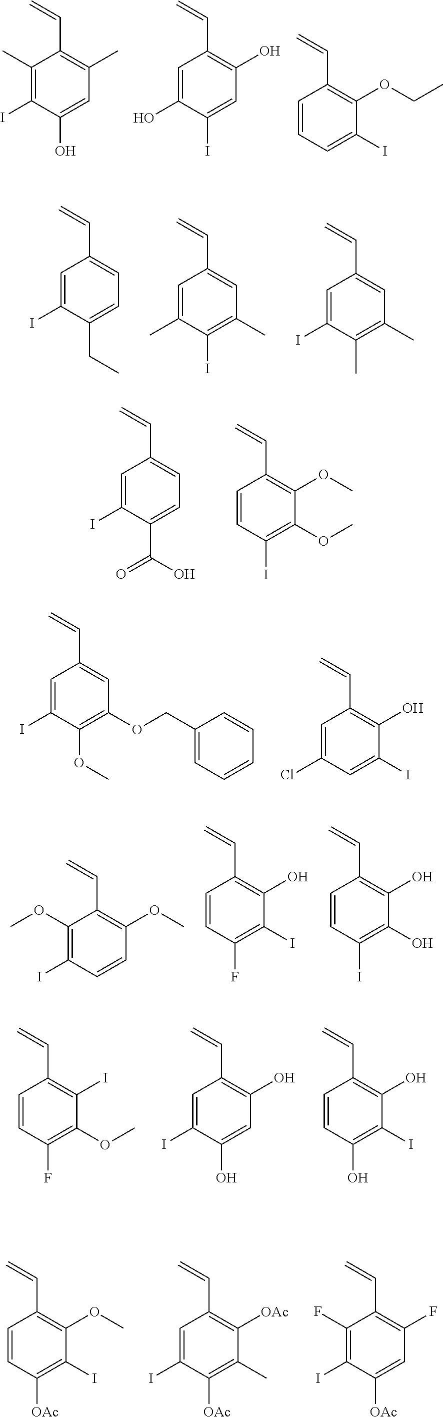

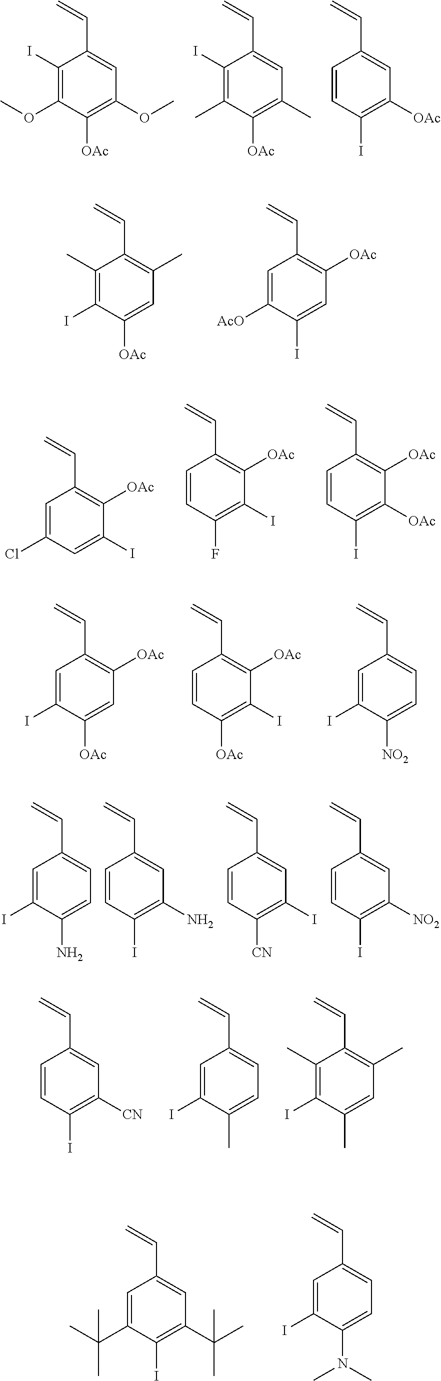

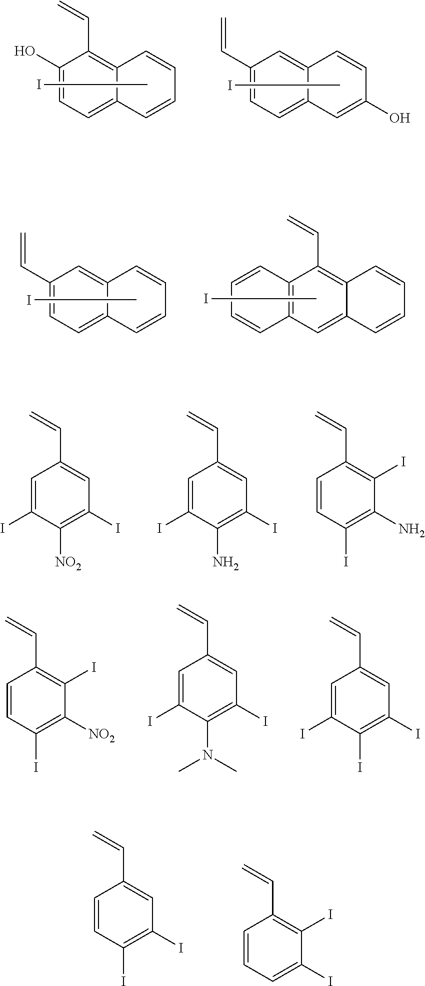

Among the compounds (A) described above, a compound represented by the following formula (Ib) is preferable, from the viewpoint of improving the sensitivity.

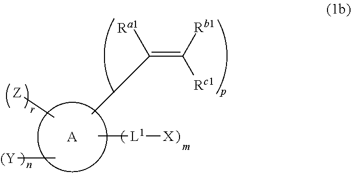

(In the formula (Ib),
X, L¹, Y, A, Z, p, m, n, and r have the same definitions, specific examples, and preferred ranges as those in the formula (1);
each of R^{a1}, R^{b1}, and R^{e1} is independently H, I, F, Cl, Br, or an organic group having 1 to 8 carbon atoms and optionally having a substituent; and
at least one of R^{a1}, R^{b1}, and R^{e1} is I, F, Cl, Br, or an organic group having 1 to 8 carbon atoms and optionally having a substituent.

The organic group having 1 to 8 carbon atoms and optionally having a substituent in R^{a1}, R^{b1}, and R^{e1} has the same meaning as the aforementioned organic group having 1 to 8 carbon atoms and optionally having a substituent in R^{a}, R^{b}, and R^{c}. R^{a1} is preferably an organic group having 1 to 8 carbon atoms and optionally having a substituent or I, and more preferably a methyl group or I. R^{b1} and R^{e1} are preferably H.

Examples of the compound (A) according to the present embodiment (above all, the compound represented by the formula (Ib)) include compounds having the structures given below.

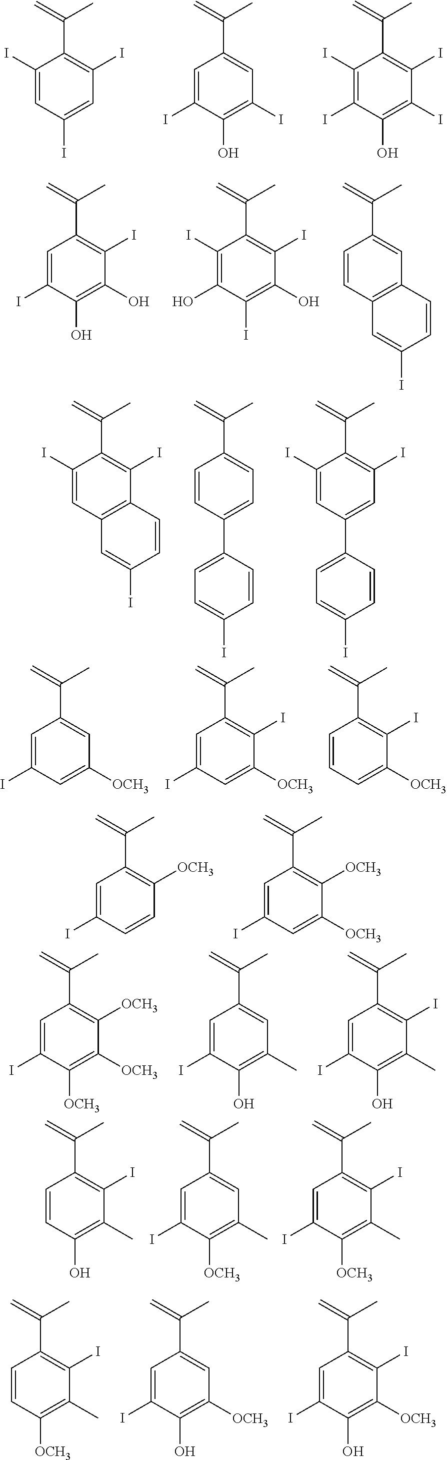

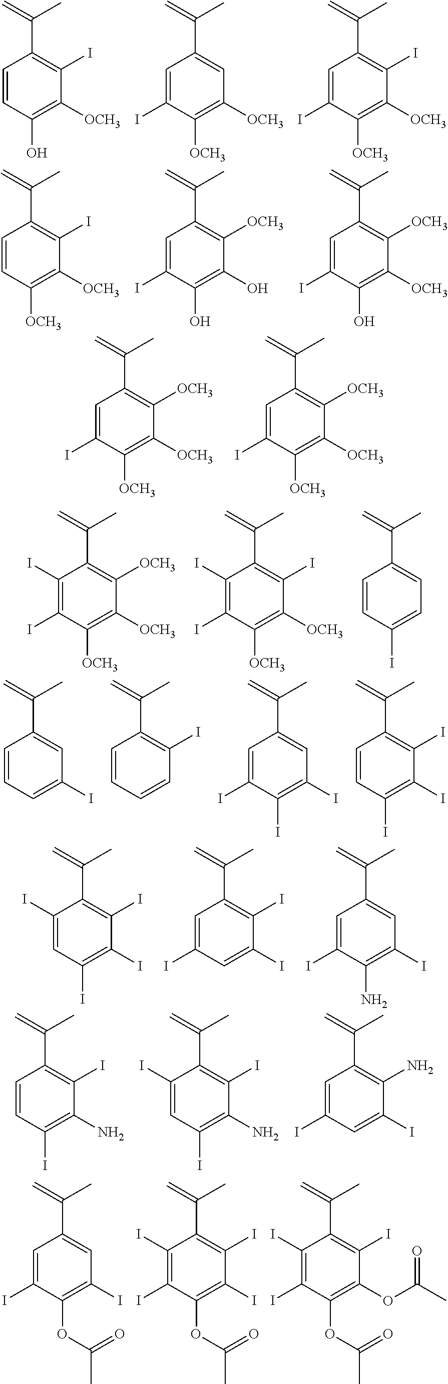

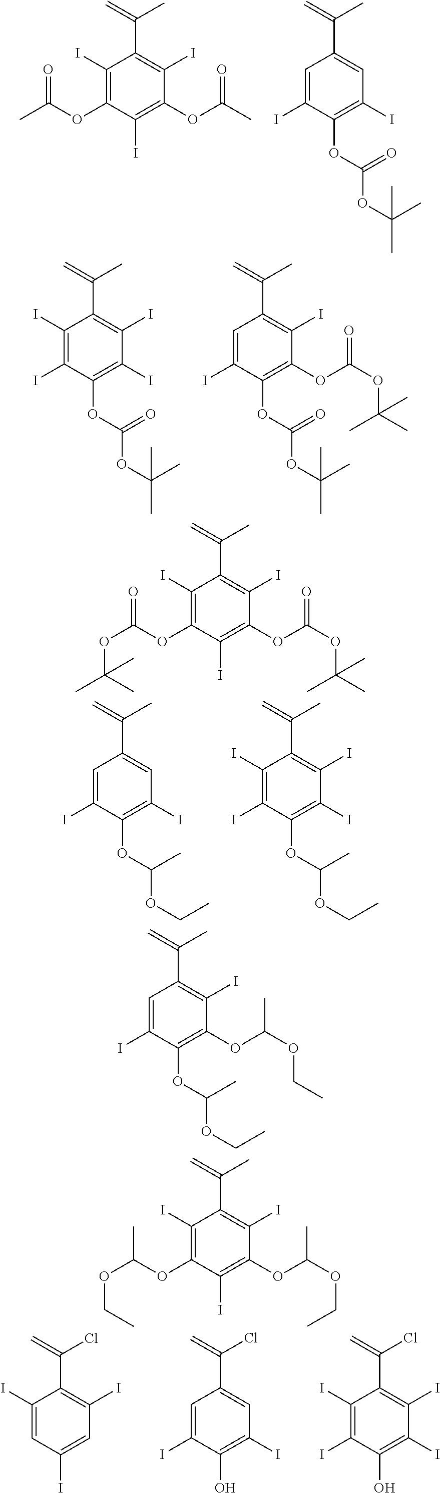

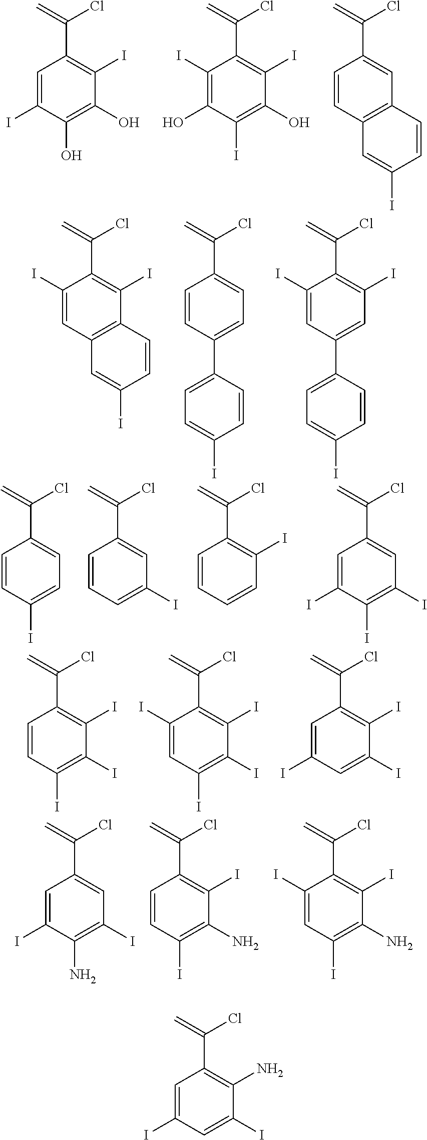

The compound (A) described above may be, for example, a compound represented by the following formula (1C). Although it is not particularly limited, the compound represented by the following formula (1C) is preferably used in combination with another compound (A) other than the compound represented by the formula (1C), as described below.

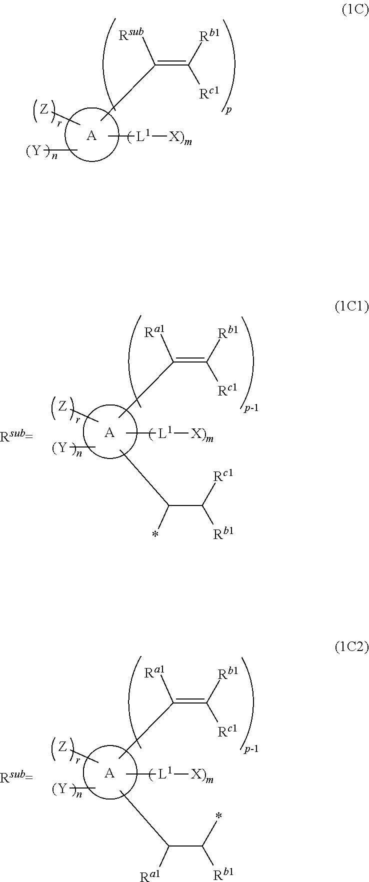

(In the formula (1C), the formula (1C1), and the formula (1C2),
X, L¹, Y, A, Z, p, m, n, and r are as defined in the formula (1);
R^{sub} represents the formula (1C1) or the formula (1C2);
each of R^{a1}, R^{b1}, and R^{e1} is independently H, I, F, Cl, Br, or an organic group having 1 to 8 carbon atoms and optionally having a substituent;
at least one of R^{a1}, R^{b1}, and R^{e1} is I, F, Cl, Br, or an organic group having 1 to 8 carbon atoms and optionally having a substituent;
p-1 is an integer of 0 or more; and
* is a site for binding with each formula.)

When the compound represented by the formula (1C) is used in a composition containing the compound (A) according to the present embodiment, the composition may contain the compound represented by the following formula (1C) in combination with another compound (A) other than the compound represented by the formula (1C). In this case, the composition is preferably prepared such that the compound represented by the formula (1C) is within a range of 1 ppm by mass or more and 10% by mass or less, more preferably within a range of 1 ppm by mass or more and 5% by mass or less, further preferably within a range of 1 ppm by mass or more and 38 by mass or less, and particularly preferably within a range of 1 ppm by mass or more and 18 by mass or less, based on the total compound (A). In the resin form after the formation of a resin made of starting materials including the composition thus prepared, the presence of a moiety containing X and a moiety consisting of Y or Z at a high density in the proximity area becomes the starting point for improving the sensitivity. Further, a local increase in the solubility of the resin leads to a reduction in the residue defect after development in a lithography process.

Examples of the compound (A) according to the present embodiment (above all, the compound represented by the formula (1C)) include compounds having the structures given below.

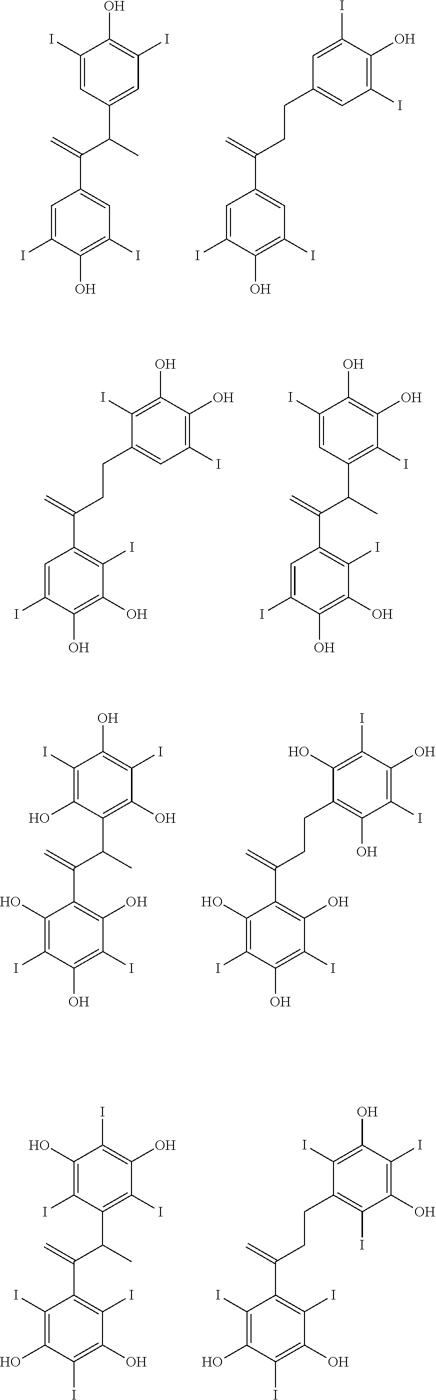

The compound (A) of the present embodiment may be used, for example, in combination with a compound represented by the following formula (1D).

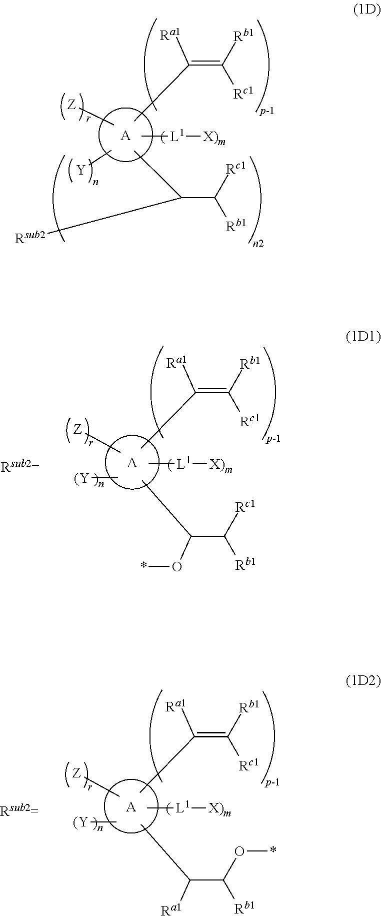

(In the formula (1D), the formula (1D1), or the formula (1D2),
X, L¹, Y, A, Z, p, m, n, and r are as defined in the formula (1);
R^{sub2} represents the formula (1D1) or the formula (1D2);
each of R^{a1}, R^{b1}, and R^{e1} is independently H, I, F, Cl, Br, or an organic group having 1 to 8 carbon atoms and optionally having a substituent;
at least one of R^{a1}, R^{b1}, and R^{e1} is I, F, Cl, Br, or an organic group having 1 to 8 carbon atoms and optionally having a substituent;
n2 represents an integer of 0 or more and 4 or less;
p-1 is an integer of 0 or more; and
* is a site for binding with an adjacent constitutional unit.

When the compound represented by the formula (1D) is used in a composition containing the compound (A) of the present embodiment, the composition may contain the compound represented by the following formula (1D) in combination with another compound (A) other than the compound represented by the formula (1D). In this case, the composition is preferably prepared such that the compound represented by the formula (1D) is in a range of 1 ppm by mass or more and 10% by mass or less, more preferably in a range of 1 ppm by mass or more and 5% by mass or less, further preferably in a range of 1 ppm by mass or more and 3% by mass or less, and particularly preferably in a range of 1 ppm by mass or more and 1% by mass or less, based on the total compound (A). In the resin form in the case of forming a resin made of starting materials including the composition thus prepared, the coexistence of a moiety containing X and a moiety consisting of Y or Z at a high density in the proximity area becomes the starting point for improving the sensitivity. Further, a local increase in the solubility of the resin can lead to a reduction in the residue defect after development in a lithography process.

Examples of the compound (A) according to the present embodiment (above all, the compound represented by the formula (1D)) include compounds having the structures given below.

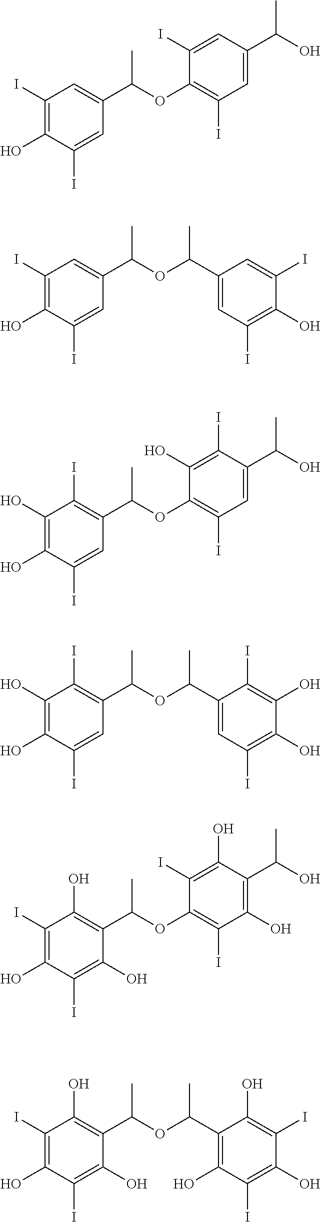 [SMILES: CC(O)c1cc(I)c(OC(C)c2cc(I)c(O)c(I)c2)c(I)c1 ; CC(OC(C)c1cc(I)c(O)c(I)c1)c1cc(I)c(O)c(I)c1 ; CC(O)c1cc(I)c(OC(C)c2cc(I)c(O)c(O)c2I)c(O)c1I ; CC(OC(C)c1cc(I)c(O)c(O)c1I)c1cc(I)c(O)c(O)c1I ; CC(O)c1c(O)c(I)c(OC(C)c2c(O)c(I)c(O)c(I)c2O)c(I)c1O ; CC(OC(C)c1c(O)c(I)c(O)c(I)c1O)c1c(O)c(I)c(O)c(I)c1O]

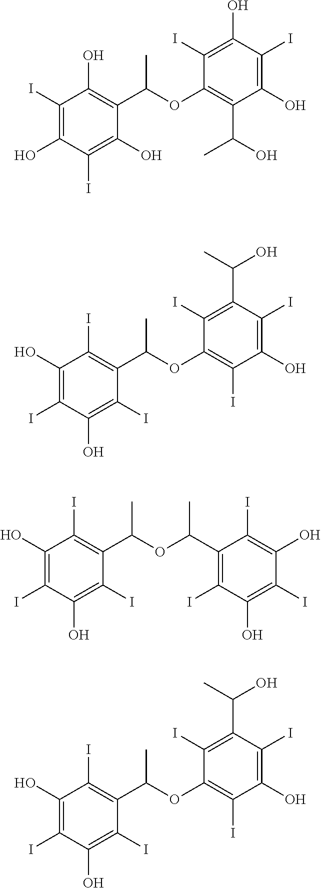 [SMILES: CC(O)c1c(O)c(I)c(O)c(I)c1OC(C)c1c(O)c(I)c(O)c(I)c1O ; CC(O)c1c(I)c(O)c(I)c(OC(C)c2c(I)c(O)c(I)c(O)c2I)c1I ; CC(OC(C)c1c(I)c(O)c(I)c(O)c1I)c1c(I)c(O)c(I)c(O)c1I ; CC(O)c1c(I)c(O)c(I)c(OC(C)c2c(I)c(O)c(I)c(O)c2I)c1I]

A compound represented by the following formula (1E) can be contained in the composition containing the compound (A) of the present embodiment. When the compound is used, the composition containing the compound (A) of the present embodiment preferably contains the compound represented by the formula (1E) in a range of 1 ppm by mass or more and 10% by mass or less, more preferably in a range of 1 ppm by mass or more and 5% by mass or less, further preferably in a range of 1 ppm by mass or more and 3% by mass or less, and particularly preferably in a range of 1 ppm by mass or more and 18 by mass or less, based on the total compound (A).

In the composition thus prepared, its stability tends to increase. The reason is not clear, but can be presumed that the equilibrium reaction of iodine atoms occurs between the compound (A) containing iodine and the compound (1E) containing no iodine and thus the composition is stabilized.

In this case, the composition preferably contains, as the compound (1E), a compound having a structure in which iodine atoms are eliminated from a compound exemplified as the compound (A) mentioned above, in combination.

In the composition thus prepared, its stability increases, leading to not only an increase in the storage stability, but also formation of a resin having stable properties, providing stable resist performance, and further, a reduction in the residue defect after development in a lithography process.

Examples of the method for using the compound represented by the formula (1E) in a range of 1 ppm by mass or more and 10% by mass or less based on the compound (A) in the composition containing the compound (A) include, but are not particularly limited to, a method for adding the compound (1E) to the compound (A).

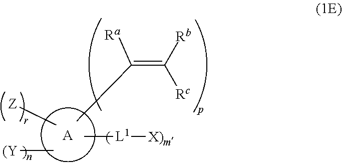

(In the formula (1E),
each X is independently F, Cl, Br, or an organic group having 1 to 30 carbon atoms and having 1 or more and 5 or less substituents selected from the group consisting of F, Cl, and Br;
each L¹ is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of L¹ optionally has a substituent;
each Y is independently a hydroxyl group, an alkoxy group, an ester group, an acetal group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, F, Cl, Br, or an organic group having 1 to 8 carbon atoms and optionally having a substituent;
A is an organic group having 6 to 30 carbon atoms; each Z is independently an alkoxy group, an ester group, an acetal group, or a carbonate ester group, provided that none of X, L¹, Y, R^{a}, R^{b}, R^{c}, A, and Z contains I; and
p is an integer of 1 or more, m′ is an integer of 0 or more, n is an integer of 0 or more, and r is an integer of 0 or more, provided that m′ is m′≤m-1 (m represents m in the formula (1)) in the relationship with the compound (A) represented by the formula (1) that is used in combination).

If the compound represented by the formula (1E) is contained in an amount more than 10% by mass based on the compound (A), the effect of improving the sensitivity may be reduced when a polymer containing the compound (A) is formed and used for lithography applications. On the other hand, when contained in an amount less than 1 ppm, the effect of improving aging stability may not be sufficiently exhibited.

m′ of the compound represented by the formula (1E) is preferably 0 to further increase the effect of aging stability.

Examples of the compound (1E) according to the present embodiment include compounds having the structures given below.

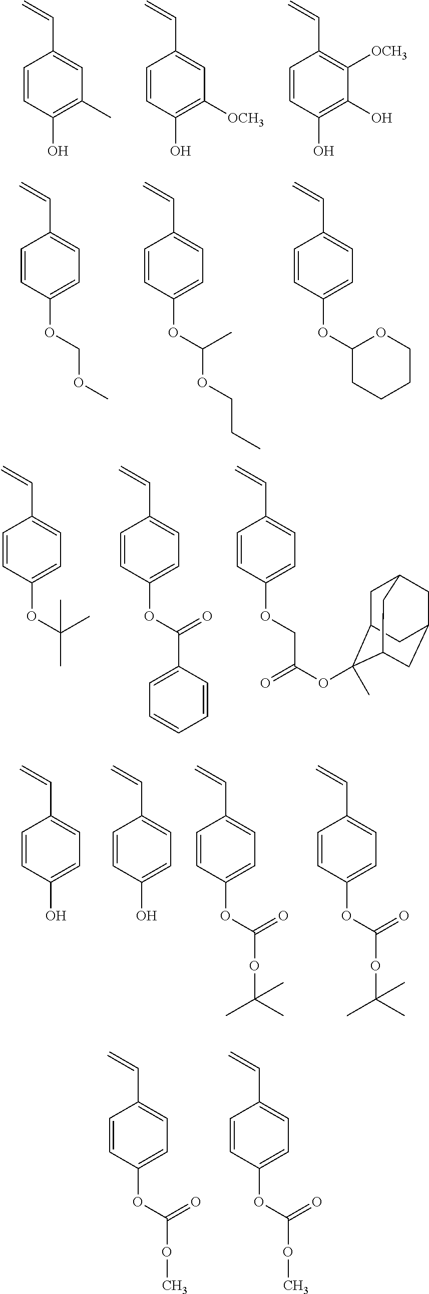

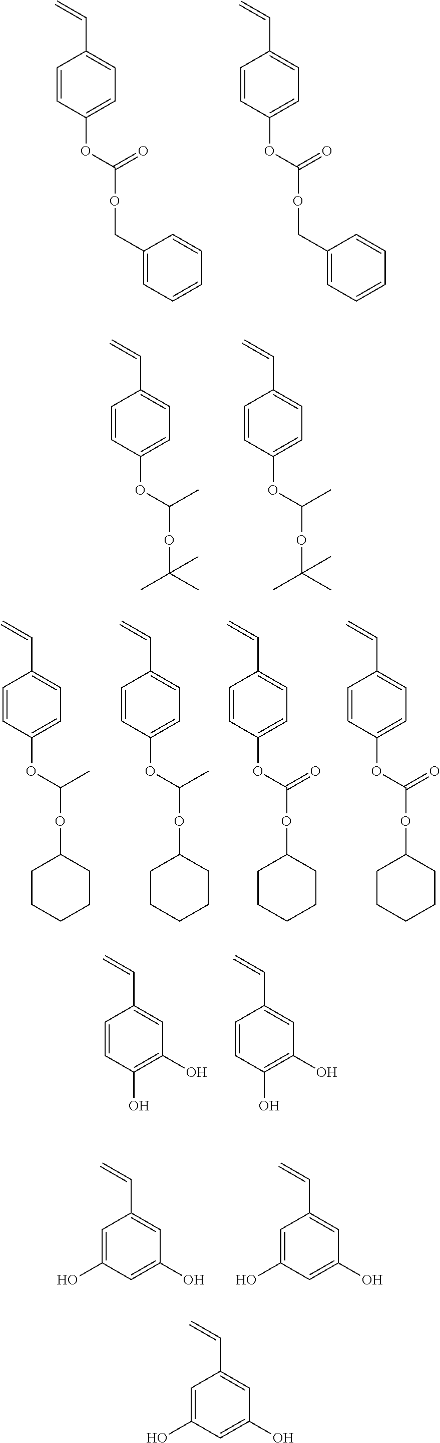

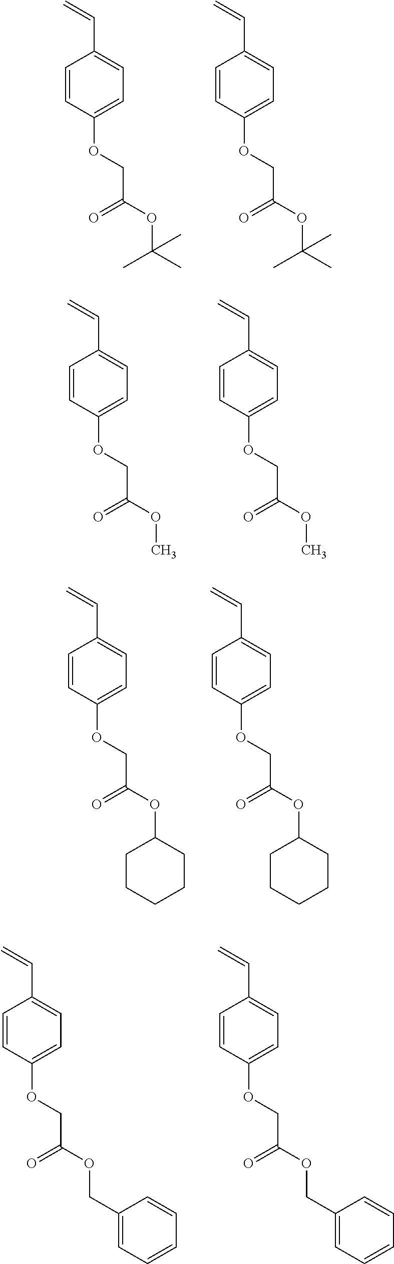

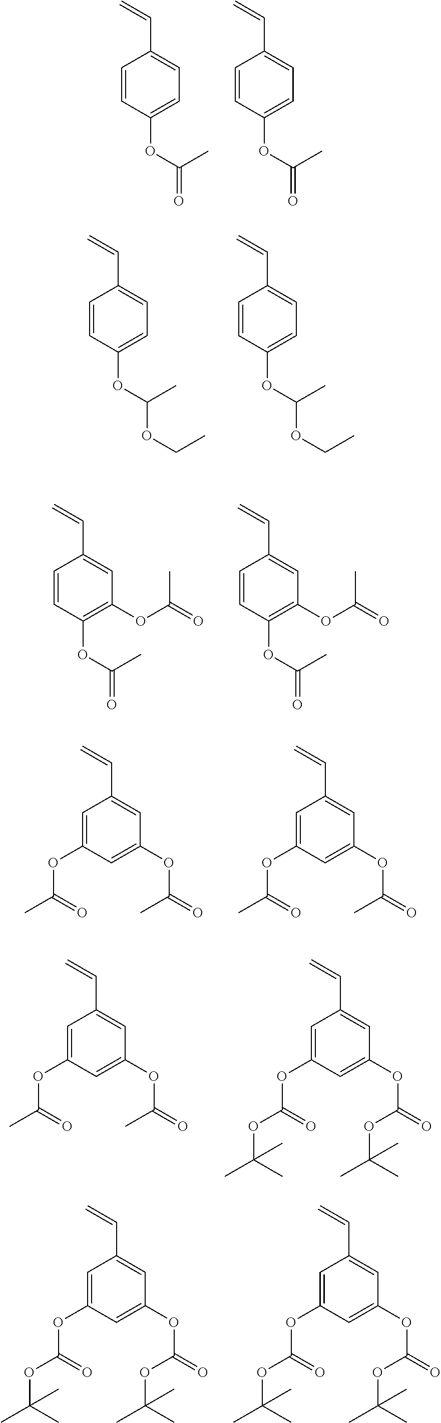

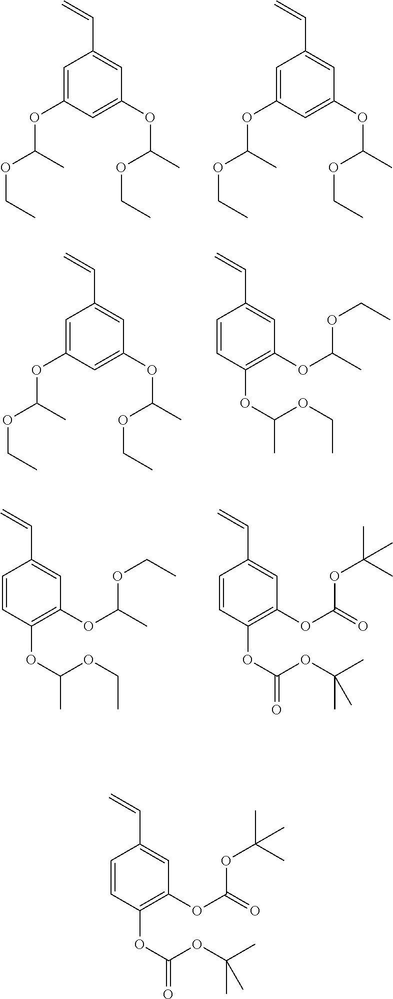

### [Method for Producing Compound (A)]

The compound represented by the formula (1) can be produced by various known synthetic methods. As an example of the synthetic method, for example, the method described in International Publication No. WO 2021/029395 can be used without particular limitation. As the raw material used in the synthesis of the compound (A), for example, the followings can be used.

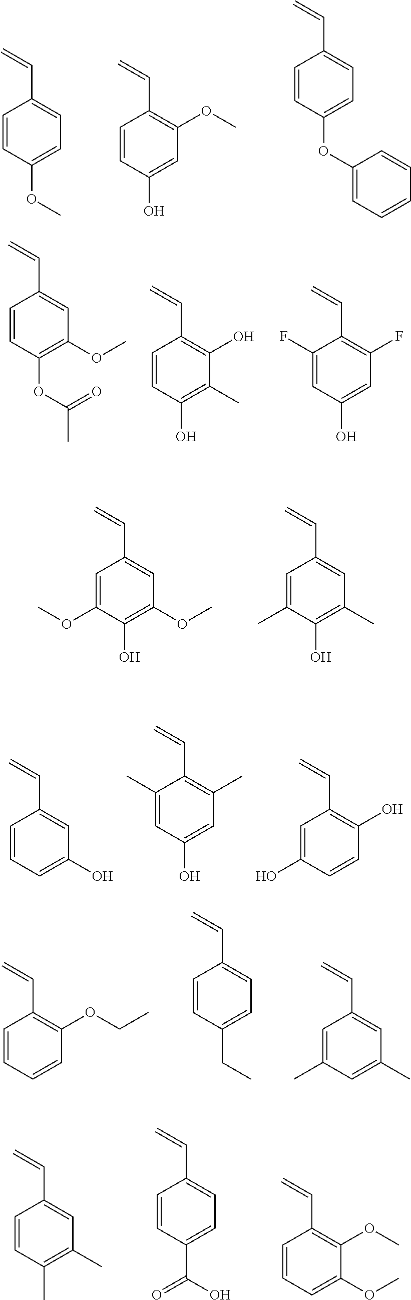

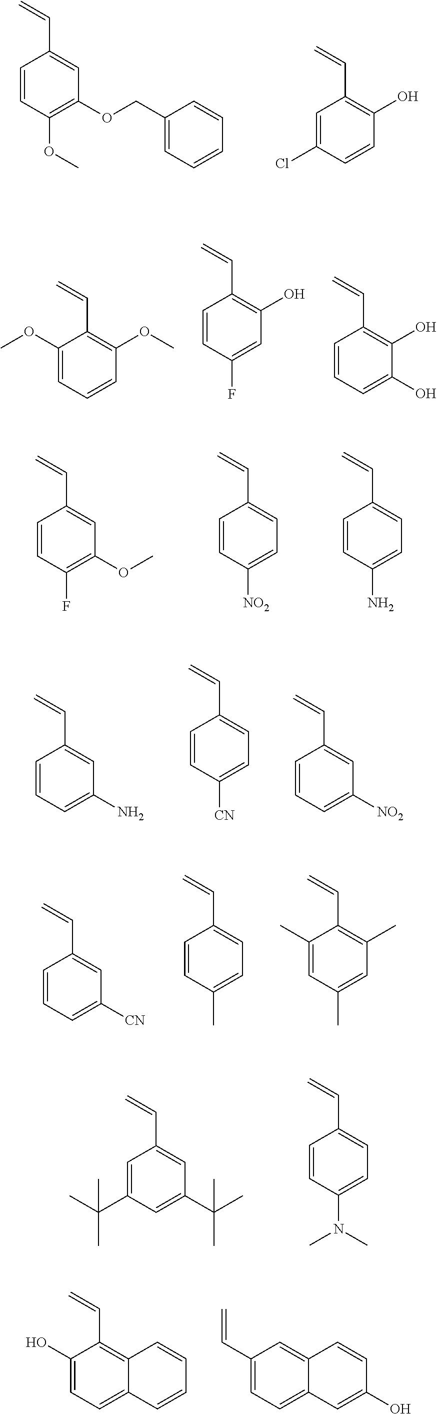

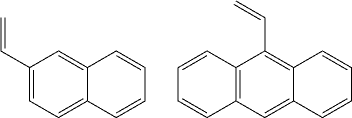

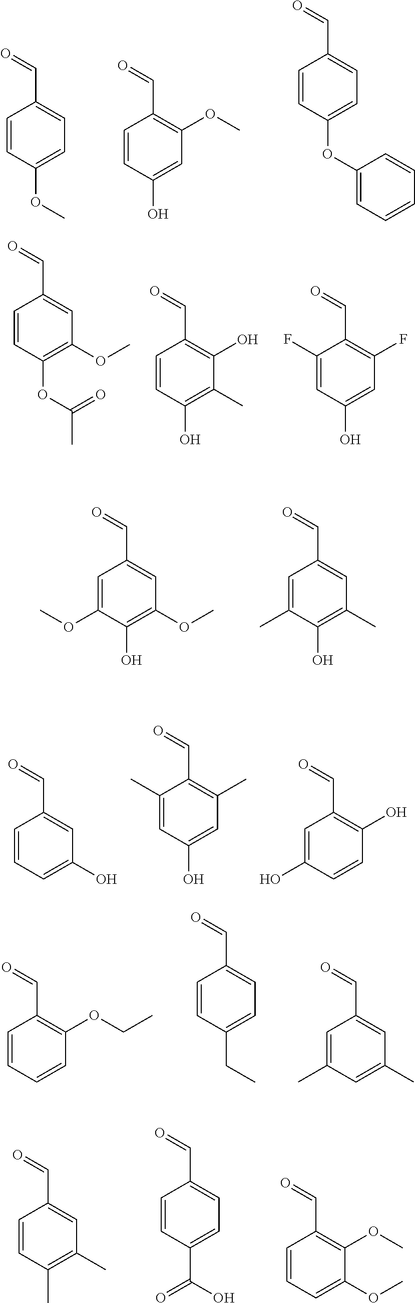

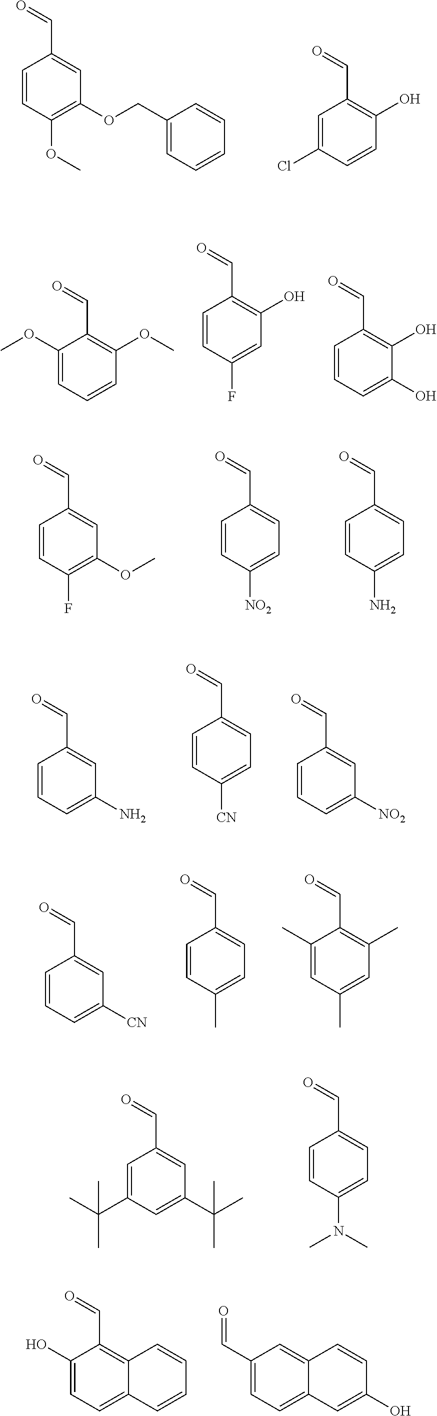

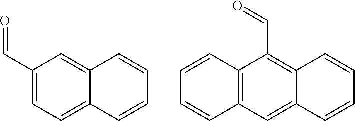

It is preferable that the compound in the present embodiment be obtained as a crude by the reaction described above and be then further subjected to purification, thereby removing the residual metal impurities. That is, it is preferable to avoid residual metal impurities derived from contamination by metal components which are used as a reaction aid during the production process of the compound or contaminated from a reaction vessel for production or other production equipment, from the viewpoint of preventing the deterioration of the resin with time, storage stability, and further, production yield due to processability, defects, and the like when the composition is formed into a resin and applied to a semiconductor production process.

The residual amounts of respective metal impurities are preferably less than 1 ppm, more preferably less than 100 ppb, further preferably less than 50 ppb, still more preferably less than 10 ppb, and most preferably less than 1 ppb, based on the resin. In particular, with respect to various metal species such as Fe, Ni, Mn, W, and Al which are classified as transition metals, alkali metals such as Li, Na, and K, and other metals such as Si, Sn, Sb, and Pb, there is concern that the amount of residual metals of 1 ppm or more may cause the denaturation and deterioration of materials with time due to the interaction with the compound in the present embodiment. Further, there is also concern that the metal balance cannot be sufficiently reduced with the amount of residual metals of 1 ppm or more when a resin for semiconductor process is prepared using the compound prepared, which results in defects derived from residual metals in a semiconductor production process and reduction in yield due to performance deterioration.

The purification method is not particularly limited, and, for example, the purification method described in International Publication No. WO 2021/029395 can be used.

### [Applications of Compound (A)]

The compound (A) according to the present embodiment can increase the sensitivity to an exposure light source by being added to a composition for film formation as it is or as the polymer described below. The compound (A) or a polymer thereof is preferably used for photoresists.

### [Compound (B)]

The compound (B) according to the present embodiment is a compound different from the compound (A) and represented by the following formula (2), and has two or more halogens, and an unsaturated double bond in the molecule other than the terminal. The compound (B) represented by the formula (2) may be either a cis isomer or a trans isomer. The composition of the present embodiment may contain only either one of the cis-isomer and the trans-isomer of the compound represented by the formula (2) as the compound (B), or may contain both the cis-isomer and the trans-isomer.

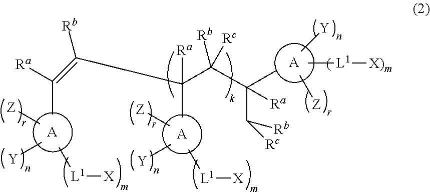

(In the formula (2),
X, L¹, Y, R^{a}, R^{b}, R^{c}, A, Z, p, m, n, and r are the same as those described in the formula (1), and k represents an integer of 0 or more and 2 or less.)

In the formula (2), X, L¹, Y, R^{a}, R^{b}, R^{c}, A, Z, p, m, n, and r have the same definitions, specific examples, and preferred ranges as those in the formula (1). In the formula (2), X, L¹, Y, R^{a}, R^{b}, R^{c}, A, Z, p, m, n, and r may be, in the definitions thereof, the same groups as X, L¹, Y, R^{a}, R^{b}, R^{c}, A, Z, p, m, n, and r in the compound represented by the formula (1) which is used in combination, or may be different groups. Similarly, in the formula (2), X, L¹, Y, R^{a}, R^{b}, R^{c}, A, Z, p, m, n, and r may be, in the definitions thereof, bonded to the same positions as X, L¹, Y, R^{a}, R^{b}, R^{c}, A, Z, p, m, n, and r in the compound represented by the formula (1) which is used in combination, or may be bonded to different positions.

The compound (B) optionally further has one or more hydrophilic groups or one decomposable group as Y. From the viewpoint of the roughness of a pattern, the compound (B) preferably has one or more hydrophilic groups or one decomposable group as Y. That is, the compound (B) according to the present embodiment preferably has two or more halogens, one or more hydrophilic groups or one decomposable group, and an unsaturated double bond in the molecule other than the terminal. In addition, the compound (B) optionally further has one or more hydrophilic groups or one decomposable group.

Preferable examples of the halogen represented by X include I, F, Cl, and Br. Among them, I, F, or Br is preferable, I or F is more preferable, and I is further preferable, from the viewpoint of the sensitizing effect of EUV and reducing the roughness of a pattern. The number of halogen is preferably an integer of 2 or more and 10 or less, more preferably an integer of 2 or more and 8 or less, and further preferably 2 or more and 6 or less.

The term “hydrophilic group” means a group that binds to an organic compound, thereby improving the affinity between the organic compound and water. Examples of the hydrophilic group include a hydroxyl group, a nitro group, an amino group, a carboxyl group, a thiol group, a phosphine group, a phosphone group, a phosphate group, an ether group, a thioether group, a urethane group, a urea group, an amide group, and an imide group in Y. Among them, a hydroxyl group is preferable, from the viewpoint of the sensitizing effect of EUV and reducing the roughness of a pattern. The number of hydrophilic group is preferably an integer of 1 or more and 10 or less, more preferably an integer of 1 or more and 6 or less, further preferably 1 or more and 4 or less, and particularly preferably 2 or more and 4 or less.

The term “decomposable group” means a group that is decomposed in the presence of an acid or a base, or by an action of irradiation from a light source such as radiation, electron beam, extreme ultraviolet (EUV), ArF, or KrF. The decomposable group is not particularly limited, and for example, an acid dissociable functional group described in International Publication No. WO 2013/024778 can be used. Among the decomposable groups, a hydrolyzable group is preferable. The term “hydrolyzable group” means a group that is hydrolyzed in the presence of an acid or a base. Examples of the hydrolyzable group include an alkoxy group, an ester group, an acetal group, and a carbonate ester group in Y. The number of decomposable group is preferably an integer of 1 or more and 10 or less, more preferably an integer of 1 or more and 6 or less, further preferably 1 or more and 4 or less, and particularly preferably 2 or more and 4 or less.

The unsaturated double bond in the formula (2) is preferably a polymerizable unsaturated double bond. In the formula (2), examples of the group having an unsaturated double bond that is formed together with R^{a} and R^{b} include, but are not particularly limited to, a vinyl group, an isopropenyl group, a (meth)acryloyl group, and a haloacryloyl group. Examples of the haloacryloyl group include an α-fluoroacryloyl group, an α-chloroacryloyl group, an α-bromoacryloyl group, an a-iodoacryloyl group, an α,β-dichloroacryloyl group, and an α,β-diiodoacryloyl group. Among these unsaturated double bonds, an isopropenyl group or a vinyl group is preferable. The number of unsaturated double bond is preferably an integer of 1 or more and 6 or less, more preferably an integer of 1 or more and 4 or less, and further preferably 1 or more and 2 or less.

From the viewpoint of suppressing etching residues, the compound (B) preferably contains a functional group for improving solubility in an alkaline developing solution by the action of an acid or a base, and the functional group for improving solubility in an alkaline developing solution by the action of an acid or a base is preferably contained in either Y or X. Examples of the functional group include a carbonyloxy group (e.g., an ester group such as an acetyl group), an acetal group, a carbonate ester group, and a tertiary alkoxy group.

When the compound (B) represented by the formula (2) is used in a composition containing the compound (A) according to the present embodiment, the composition may contain the compound (B) represented by the formula (2) in combination with the compound (A) other than the compound (B). In this case, the composition is preferably prepared such that the compound (B) represented by the formula (2) is in a range of 1 ppm by mass or more and 10% by mass or less, more preferably in a range of 1 ppm by mass or more and 10% by mass or less, further preferably in a range of 1 ppm by mass or more and 3% by mass or less, and particularly preferably in a range of 1 ppm by mass or more and 18 by mass or less, based on the total compound (A). In the resin form after the formation of a resin made of starting materials including the composition thus prepared, the presence of a moiety containing X and a moiety consisting of Y or Z at a high density in the proximity area becomes the starting point for improving the sensitivity. Further, a local increase in the solubility of the resin leads to a reduction in the residue defect after development in a lithography process.

As another effect, the coexistence of the compound (A) and the compound (B) can improve the aging stability of the compound (A). The mechanism of the effect of improving the aging stability of the compound (A) is not certain. However, it is considered that the formation of polymers by thermal radical polymerization and the like in the compound (A) in a stored state is suppressed, and when a resin that contains, as the starting material, a composition containing the compound (A) is applied to a lithography process, the increase with time of defects starting from polymer impurities due to the compound (A) is largely suppressed, and as a result, the performance in a lithography process can be maintained.

Examples of the method for using the compound (B) in a range of 1 ppm by mass or more and 10% by mass or less based on the compound (A) in the composition containing the compound (A) include, but are not particularly limited to, a method for adding the compound (B) to the compound (A). For example, it is preferable that the compound (A) and the compound (B) have the same type (such as Y and X) and binding portion of substituents that are common in each formula.

Examples of the compound (B) according to the present embodiment or a mixture of the compound (B) include compounds having the structures given below. The structures given below may be either a cis-isomer or a trans-isomer, and a trans-isomer is preferable.

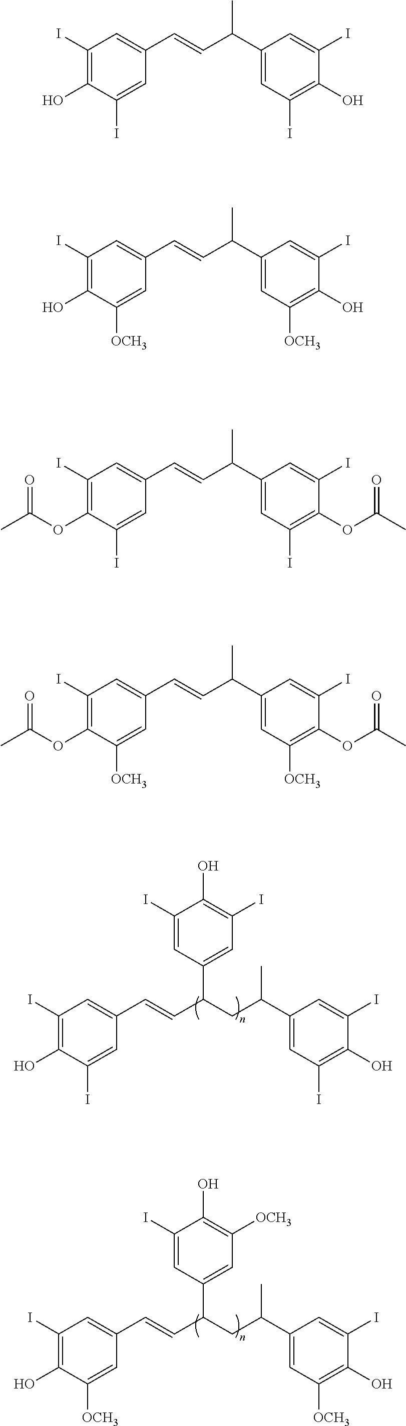

(In the formula, the compound denoted by n means a mixture in which n=1 to 4.)

A in the formula (2) is more preferably a benzene ring or a naphthalene ring, from the viewpoint of solubility.

X in the formula (2) is preferably iodine or fluorine, from the viewpoint of exposure sensitivity.

L¹ in the formula (2) is preferably a single bond, from the viewpoint of the stability of the compound.

Y in the formula (2) is preferably a hydroxyl group, an alkoxy group, an ester group, a carbonate ester group, or an acetal group, from the viewpoint of suppressing the pattern defect.

The composition of the present embodiment may contain a compound (Ba) represented by the following formula (2a), in addition to the compound (A) and the compound (B). The compound represented by the formula (2a) may be either a cis isomer or a trans isomer. The composition of the present embodiment may contain only either one of the cis-isomer and the trans-isomer of the compound represented by the formula (2a) as the compound (Ba), or may contain both the cis-isomer and the trans-isomer.

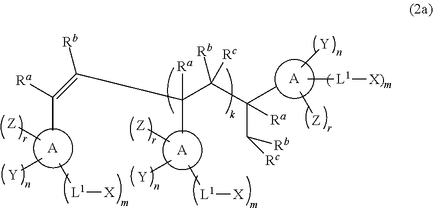

(In the formula (2a),
X, L¹, Y, R^{a}, R^{b}, R^{c}, A, Z, p, m, n, and r are the same as those described in the formula (1), and k represents an integer of 3 or more.)

In the formula (2a), X, L¹, Y, R^{a}, R^{b}, R^{c}, A, Z, p, m, n, and r have the same definitions, specific examples, and preferred ranges as those in the formula (1). k in the formula (2a) is preferably 3 or more and 5 or less, and more preferably 3, from the viewpoint of solubility.

### [Method for Producing Compound (B)]

The compound (B) represented by the formula (2) can be produced by various synthetic methods. As an example of the preferred synthetic method of the compound (B), for example, the compound (B) can be produced by a method in which the reaction temperature in the synthetic method of the compound (A) represented by the formula (1) is regulated, without particular limitation. The larger the reaction temperature is, the more the selectivity of the compound (B) represented by the formula (2) improves as compared with that of the compound (A) represented by the formula (1). Although it is not particularly limited, for example, the reaction is carried out at 50° C. or more and the boiling point of the solvent to be used or less, and the reaction is preferably carried out at 60° C. or more and the boiling point of the solvent or less, from the viewpoint of the selectivity of the compound (B). From the viewpoint of controlling the reaction temperature, the reaction is more preferably carried out at the boiling point of the solvent.

It is preferable that the compound produced in the present embodiment be obtained as a crude by the reaction described above and be then further subjected to purification, thereby removing the residual metal impurities. As an example of the purification method, for example, purification can be carried out by the same method as the aforementioned purification method of the compound (A) represented by the formula (1), without particular limitation.

The residual amounts of respective metal impurities are preferably less than 1 ppm, more preferably less than 100 ppb, further preferably less than 50 ppb, still more preferably less than 10 ppb, and most preferably less than 1 ppb, based on the resin. In particular, with respect to various metal species such as Fe, Ni, Mn, W, and Al which are classified as transition metals, alkali metals such as Li, Na, and K, and other metals such as Si, Sn, Sb, and Pb, there is concern that the amount of residual metals of 1 ppm or more may cause the denaturation and deterioration of materials with time due to the interaction with the compound in the present embodiment. Further, there is also concern that the metal balance cannot be sufficiently reduced with the amount of residual metals of 1 ppm or more when a resin for semiconductor process is prepared using the compound prepared, which results in defects derived from residual metals in a semiconductor production process and reduction in yield due to performance deterioration.

### [Applications of Compound (B)]

The compound (B) according to the present embodiment can increase the sensitivity to an exposure light source by being added to a composition for film formation as it is or as the polymer described below. The compound (B) or a polymer thereof is preferably used for photoresists.

### [Method for Producing Compound (Ba)]

The compound (Ba) represented by the formula (2a) can be produced by various synthetic methods. As an example of the preferred synthetic method of the compound, for example, the compound can be produced by a method in which the reaction temperature in the synthetic method of the compound (A) represented by the formula (1) is regulated, without particular limitation. The higher the reaction temperature is, the more the selectivity of the compound (Ba) improves. Although it is not particularly limited, for example, it is preferable that the raw material be dissolved in a solvent having a high boiling point and the reaction be carried out at the reaction temperature which is the boiling point, from the viewpoint of improving the selectivity of the compound (Ba). To increase the reaction temperature, a solvent having a high boiling point may be used under reflux.

### [Applications of Compound (Ba)]

The compound (Ba) represented by the formula (2a) according to the present embodiment can increase the sensitivity to an exposure light source by being added to a composition for film formation as it is or as the polymer described below. The compound (Ba) or a polymer thereof is preferably used for photoresists.

### [Composition]

The composition of the present embodiment contains the compound (A) and the compound (B). The content of the compound (A) in the present embodiment is preferably 90% by mass or more, more preferably 958 by mass or more, and further preferably 998 by mass or more.

As other preferred form of the composition of the present embodiment, the content of the compound (B) represented by the formula (2) contained is preferably as little as 1 ppm by mass or more and 108 by mass or less, more preferably 1 ppm by mass or more and 5% by mass or less, further preferably 20 ppm by mass or more and 2% by mass or less, and particularly preferably 50 ppm by mass or more and 1% by mass or less, based on the content of the compound (A) represented by the formula (1).

By setting the content of the compound (B) represented by the formula (2) to the above range, the interaction between resins when being formed into a resin can be reduced, and the crystalline due to the interaction between the resins after a film is formed using the resin can be suppressed. As a result, the locality in the solubility in the developing solution upon developing can be reduced at a molecular level from several to several tens of nanometers, the reduction in pattern quality, such as the line edge roughness and the residue defect, of a pattern which is formed in the pattern formation process in a series of lithography processes of exposure, post exposure bake, and development can be suppressed, and the resolution can be further improved. Furthermore, although the mechanism is not certain, the compound (B) represented by the formula (2) effectively and actively captures radicals generated by heat and the like, suppresses the deterioration in quality of the compound (A) represented by the formula (1) in the composition, suppresses generation of a trace amount of particulate foreign matter, and suppresses defects on a film to be obtained or a pattern after development due to aging.

With respect to these effects for lithography performance, the effect for improving the resolution due to suppression of the crystalline due to the interaction between the resins is increased by the compound represented by the formula (2), as a result that, in the compound represented by the formula (2) having the core A into which a halogen element, in particular, iodine, fluorine, or the like is introduced, the affinity with the compound represented by the formula (1) is further increased relative to a compound having a hydroxystyrene backbone in which no iodine and the like are introduced, and the polarization at the polar moieties is increased.

The composition of the present embodiment may contain a compound (Ba) represented by the formula (2a), in addition to the compound (A) and the compound (B), as mentioned above. From the viewpoint of suppressing the etching defect, the content of the compound (Ba) in the composition of the present embodiment is preferably 1% by mass or less, more preferably 0.1% by mass or less, and further preferably 0.01% by mass or more and 0.1% by mass or less, based on the content of the compound (A).

In the composition of the present embodiment, impurities containing K (potassium) are preferably 1 ppm by mass or less, more preferably 0.5 ppm by mass or less, further preferably 0.1 ppm by mass or less, and still more preferably 0.005 ppm by mass or less, in terms of element, based on the total amount of the compound (A) and the compound (B).

In the composition of the present embodiment, the content of one or more elemental impurities selected from the group consisting of Fe (iron), Ni (nickel), Mn (manganese), W (tungsten), Al (aluminum), Li (lithium), Na (sodium), K (potassium), Si (silicon), Sn (tin), Sb (antimony), Zn (zinc), Co (cobalt), Cr (chrome), Zr (zirconium), Mo (molybdenum), and Pb (lead) (preferably, one or more elemental impurities selected from the group consisting of Mn and A1) is preferably 1 ppm by mass or less, more preferably 0.5 ppm by mass or less, and further preferably 0.1 ppm by mass or less, in terms of element, based on the compound (A) (or based on the compound (A) and the compound (B)), from the viewpoint of suppressing the pattern defect.

The amount of K, Mn, Al, and the like can be measured by inorganic elemental analysis (IPC-AES/IPC-MS). Examples of the inorganic element analyzer include “AG8900” manufactured by Agilent Technologies, Inc.

In the composition of the present embodiment, a phosphorus-containing compound is preferably 10 ppm by mass or less, more preferably 8 ppm by mass or less, and further preferably 5 ppm by mass or less, based on the compound (A) (or based on the compound (A) and the compound (B)), from the viewpoint of the pattern shape.

In the composition of the present embodiment, maleic acid is preferably 10 ppm by mass or less, more preferably 8 ppm by mass or less, and further preferably 5 ppm by mass or less, based on the compound (A) (or based on the compound (A) and the compound (B)), from the viewpoint of the pattern shape.

The amount of the phosphorus-containing compound and maleic acid is calculated from the area fraction of the GC chart and the peak intensity ratio between the target peak and the reference peak by gas chromatography mass spectrometry (GC-MS).

In the composition of the present embodiment, peroxide is preferably 10 ppm by mass or less, more preferably 1 ppm by mass or less, and further preferably 0.1 ppm by mass or less, based on the compound (A) (or based on the compound (A) and the compound (B)), from the viewpoint of the reactivity.

The amount of peroxide is quantified by an ammonium ferrothiocyanate acid method (hereinafter, AFTA method) by adding trichloroacetic acid in a sample, then adding ammonium iron (II) sulfate and potassium thiocyanate, determining a calibration curve of peroxide which is known as a standard, and measuring the absorbance at a wavelength of 480 μm.

In the composition of the present embodiment, the moisture content is preferably 100,000 ppm by mass or less, more preferably 20,000 ppm by mass or less, further preferably 1,000 ppm by mass or less, still more preferably 500 ppm by mass or less, and still more preferably 100 ppm by mass or less, based on the compound (A) and the compound (B). The moisture content can be measured by a Karl Fischer method (Karl Fischer moisture content measuring apparatus).

### [Polymer (A)]

The polymer (A) of the present embodiment contains a constitutional unit derived from the aforementioned compound (A). By containing the constitutional unit derived from the compound (A), the polymer (A) can increase the sensitivity to an exposure light source when being blended in a resist composition. In particular, the polymer (A) can exhibit sufficient sensitivity and can form good thin line patterns having a narrow line width even in the case of using an extreme ultraviolet ray as the exposure light source.

The conventional resist compositions were difficult to expand for actual semiconductor production, since their sensitivity to an exposure light source may be reduced over time due to storage or the like. However, according to the polymer (A) of the present embodiment, the stability of the resist composition is improved, and the reduction in the sensitivity to an exposure light source is suppressed even in the case of long-term storage.

The polymer (A) of the present embodiment contains the constitutional unit derived from the compound (A).

The constitutional unit derived from the compound (A) is the constitutional unit represented by the following formula (4).

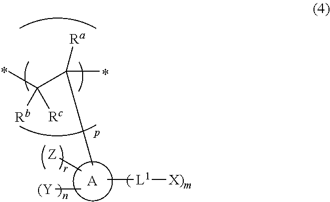

In the formula (4), X, L¹, Y, R^{a}, R^{b}, R^{c}, A, Z, p, m, n, and r have the same definitions, specific examples, and preferred ranges as those in the formula (1).

The polymer (A) can be obtained by polymerizing the compound (A) of the present embodiment, or by copolymerizing the compound (A) and other monomers. For example, the polymer (A) can be used as a material for forming a film for lithography.

The constitutional unit derived from the compound (A) is preferably the constitutional unit represented by the following formula (5).

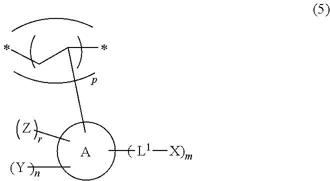

In the formula (5), X, L¹, Y, A, p, m, and n have the same definitions, specific examples, and preferred ranges as those in the formula (1).

The constitutional unit derived from the compound (A) is more preferably the constitutional unit represented by the following formula (6).

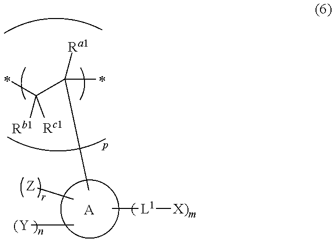

In the formula (6), X, L¹, Y, R^{a1}, R^{b1}, R^{c1}, A, Z, p, m, n, and r have the same definitions, specific examples, and preferred ranges as those in the formula (Ib).

The amount of the constitutional unit derived from the compound (A) is preferably 5 mol % or more, more preferably 8 mol % or more, and further preferably 10 mol % or more, based on the total amount of the monomer components of the polymer (A). The amount of the constitutional unit derived from the compound (A) is 100 mol % or less, preferably 80 mol % or less, more preferably 70 mol % or less, and further preferably 30 mol % or less, based on the total amount of the monomer components of the polymer (A).

As a preferred form of the polymer of the present embodiment, it is preferable that, as the constitutional unit of the polymer (A), the monomer represented by the compound (A) at least include a compound represented by the formula (1) other than the formula (1C) and a compound represented by the formula (1C). The proportion of the monomer represented by the formula (1C) contained is preferably as little as 10 ppm by mass or more and 10% by mass or less, more preferably 20 ppm or more and 2% by mass or less, and 50 ppm or more and 1% by mass or less, based on the monomer represented by the formula (1).

By setting the content of the compound represented by the formula (1C) to the described range, the interaction between resins when being formed into a resin can be reduced, and by suppressing the crystalline due to the interaction between the resins after a film is formed using the resin, the locality in the solubility in the developing solution upon developing can be reduced at a molecular level from several to several tens of nanometers, the reduction in pattern quality, such as the line edge roughness and the residue defect, of a pattern which is formed in the pattern formation process in a series of lithography processes of exposure, post exposure bake, and development can be suppressed, and the resolution can be further improved.

The influence of these effects for lithography performance increases in the monomer represented by the formula (1C), as a result that the hydrophilicity/hydrophobicity of the compound represented by the formula (1) and the compound represented by the formula (1C) each having the core A into which a halogen element, in particular, iodine, fluorine, or the like is introduced, is shifted to a compound having a hydroxystyrene backbone in which no iodine and the like are introduced, and the polarization at the polar moieties is thus increased.

As the other monomers to be copolymerized with the compound (A), it is preferable to contain a polymerization unit that has an aromatic compound having an unsaturated double bond as a substituent, as a polymerization unit, and has a functional group for improving solubility in an alkaline developing solution by the action of an acid or a base.

Examples of other monomers include, but are not particularly limited to, those described in International Publication No. WO 2016/125782, International Publication No. WO 2015/115613, Japanese Patent Laid-Open No. 2015/117305, International Publication No. WO 2014/175275, Japanese Patent Laid-Open No. 2012/162498, those described in paragraphs 0015 to 0131 in Japanese Patent Laid-Open No. 2015-161823, those described in paragraphs 0050 to 0059 in Japanese Patent No. 7044011, and those described in paragraphs 0096 to 0125 in Japanese Patent Laid-Open No. 2022-123839, or a compound represented by the following formula (C1) or formula (C2). Among them, the compound represented by the following formula (C1) or formula (C2) is preferable.

From the viewpoint of the quality of the pattern shape after exposure and development in a lithography process, in particular, suppressing the roughness and the pattern collapse, it is preferable that the difference between the dissolution rate Rₘᵢₙ of the resin that becomes protrusions of a pattern during alkali development on unexposed portions during exposure in the alkaline developing solution and the dissolution rate Rₘₐₓ of the resin that becomes recesses of the pattern during alkali development on exposed portions during exposure in the alkaline developing solution be 3 or more orders of magnitude larger, and it is preferable that the difference in the dissolution rate due to the presence or absence of a protective group be large and the elimination rate of the protective group in post-exposure bake (PEB) and development be large. From these viewpoints, other monomers to be copolymerized with the compound (A) in the polymer (A) preferably have a constitutional unit represented by the following formula (C1).

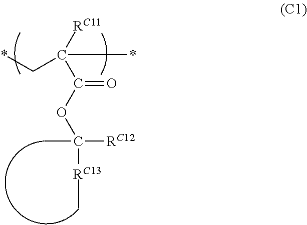

In the formula (C1),
R^{C11} is H or a methyl group;
R^{C12} is H or an alkyl group having 1 to 4 carbon atoms;
R^{c13} is taken together with a carbon atom to which R^{C13} is bonded to be a cycloalkyl group or heterocycloalkyl group having 4 to 20 carbon atoms; and
* is a site for binding with an adjacent constitutional unit.

R^{C12} is preferably H or an alkyl group having 1 to 3 carbon atoms, R^{c13} is preferably taken together with a carbon atom to which R^{c13} is bonded to be a cycloalkyl group or heterocycloalkyl group having 4 to 10 carbon atoms. The cycloalkyl group or heterocycloalkyl group of R^{C13} may have a substituent (e.g., an oxo group).

The amount of the constitutional unit represented by the formula (C1) is preferably 5 mol % or more, more preferably 10 mol % or more, and further preferably 20 molo or more, based on the total amount of the monomer components of the polymer (A). The amount of the constitutional unit represented by the formula (C1) is preferably 90 mol % or less, more preferably 80 mol % or less, further preferably 70 mol % or less, based on the total amount of the monomer components of the polymer (A).

Other monomers to be copolymerized with the compound (A) in the polymer (A) are preferably the constitutional unit represented by the following formula (C2), from the viewpoint of the quality of the pattern shape after exposure and development in a lithography process, in particular, suppressing the roughness and the pattern collapse.

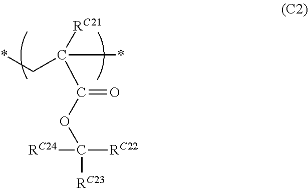

In the formula (C2),
R^{C21} is H or a methyl group;
each of R^{C22} and R^{C23} is independently an alkyl group having 1 to 4 carbon atoms;
R^{C24} is an alkyl group having 1 to 4 carbon atoms or a cycloalkyl group having 5 to 20 carbon atoms;
two or three of R^{C22}, R^{C23}, and R^{c24} are taken together with a carbon atom to which they are bonded to form an alicyclic structure having 3 to 20 carbon atoms; and
* is a site for binding with an adjacent constitutional unit.

R^{C22} is preferably an alkyl group having 1 to 3 carbon atoms, and R^{C24} is a cycloalkyl group having 5 to 10 carbon atoms. The above alicyclic structure formed by R^{C22}, R^{C23}, and R^{C24} may contain a plurality of rings such as an adamantyl group. The above alicyclic structure may have a substituent (e.g., a hydroxyl group and an alkyl group).

The amount of the constitutional unit represented by the formula (C2) is preferably 5 mol % or more, more preferably 10 mol % or more, and further preferably 20 molo or more, based on the total amount of the monomer components of the polymer (A). The amount of the constitutional unit represented by the formula (C2) is preferably 80 mol % or less, more preferably 60 mol % or less, further preferably 40 mol % or less, based on the total amount of the monomer components of the polymer (A).

Examples of the monomer raw material of the constitutional unit represented by the formula (C2) include, but are not limited to, 2-methyl-2-(meth)acryloyloxyadamantane, 2-ethyl-2-(meth)acryloyloxyadamantane, 2-isopropyl-2-(meth)acryloyloxyadamantane, 2-n-propyl-2-(meth)acryloyloxyadamantane, 2-n-butyl-2-(meth)acryloyloxyadamantane, 1-methyl-1-(meth)acryloyloxycyclopentane, 1-ethyl-1-(meth)acryloyloxycyclopentane, 1-methyl-1-(meth)acryloyloxycyclohexane, 1-ethyl-1-(meth)acryloyloxycyclohexane, 1-methyl-1-(meth)acryloyloxycycloheptane, 1-ethyl-1-(meth)acryloyloxycycloheptane, 1-methyl-1-(meth)acryloyloxycyclooctane, 1-ethyl-1-(meth)acryloyloxycyclooctane, 2-ethyl-2-(meth)acryloyloxydecahydro-1, 4:5,8-dimethanonaphtalene, and 2-ethyl-2-(meth)acryloyloxynorbornane. Commercial products may be used as these monomer.

Other monomers to be copolymerized with the compound (A) in the polymer (A) preferably have a constitutional unit represented by the following formula (C3).

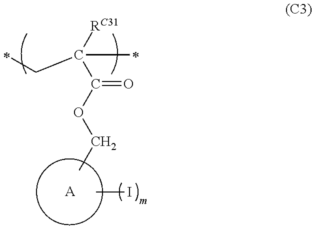

In the formula (C3), R^{C31} is H or a methyl group, and m, A, and * are as defined in the above formula (4). Other monomers to be copolymerized with the compound (A) in the polymer (A) preferably have a constitutional unit represented by the following formula (C4).

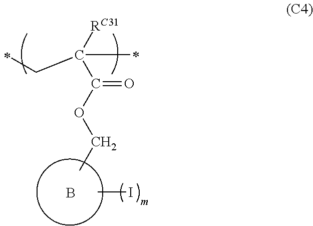

In the formula (C4), B represents an organic group containing an aromatic ring and having 5 to 30 carbon atoms, and R^{C31}, m, and * are as defined in the above formula (C3).

Other monomers to be copolymerized with the compound (A) in the polymer (A) preferably have a constitutional unit represented by the following formula (C5).

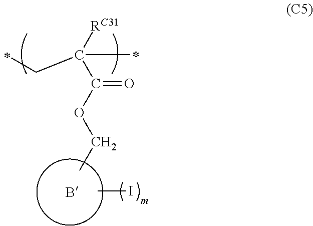

In the formula (C5), B′ represents an organic group containing an aromatic ring and having 5 to 30 carbon atoms, and R^{C31}, m, and * are as defined in the above formula (C3).

Other monomers to be copolymerized with the compound (A) in the polymer (A) are preferably the constitutional unit represented by the following formula (C6), from the viewpoint of the exposure sensitivity in pattern formation and the quality of the pattern shape after exposure and development in a lithography process, in particular, suppressing the roughness and the pattern collapse.

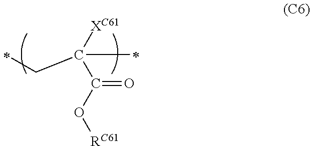

In the formula (C6),
X^{C61} is a hydroxyl group or a halogen group;
each R^{C61} is independently an alkyl group having 1 to 20 carbon atoms; and
* is a site for binding with an adjacent constitutional unit.

X^{C61} is preferably F, Cl, Br, or I, further preferably Cl or I, and still more preferably I. R^{C61} is preferably an alkyl group having 1 to 4 carbon atoms, and more preferably a methyl group.

The amount of the constitutional unit represented by the formula (C6) is preferably 20 mol % or more, more preferably 30 mol % or more, and further preferably 40 mol % or more, based on the total amount of the monomer components of the polymer (A). The amount of the constitutional unit represented by the formula (C6) is preferably 80 mol % or less, more preferably 70 mol % or less, further preferably 60 mol % or less, based on the total amount of the monomer components of the polymer (A).

Examples of the monomer raw material of the constitutional unit represented by the formula (C6) include, but are not limited to, methyl 2-chloroacrylate, ethyl 2-chloroacrylate, butyl 2-chloroacrylate, methyl 2-bromoacrylate, ethyl 2-bromoacrylate, butyl 2-bromoacrylate, methyl 2-iodoacrylate, ethyl 2-iodoacrylate, and butyl 2-iodoacrylate. Commercial products may be used as these monomer.

Next, the method for producing the polymer (A) will be described. The polymerization reaction is carried out by dissolving a monomer as a constitutional unit in a solvent and adding a polymerization initiator while heating or cooling. The reaction conditions can be inadvertently set depending on the kind of polymerization initiator, the initiation method such as heat and light, the temperature, the pressure, the concentration, the solvent, the additive, and the like. Examples of the polymerization initiator include a radical polymerization initiator such as azoisobutyronitrile and peroxide, and an anion polymerization initiator such as alkyllithium and a Grignard reagent.

As the solvent used in the polymerization reaction, a commonly available product can be used. For example, a wide variety of solvents such as alcohols, ethers, hydrocarbons, and halogenated solvents can be arbitrarily used within a range not inhibiting the reaction. Within the above range not inhibiting the reaction, a plurality of solvents can be used as a mixture.

The polymer (A) obtained in the polymerization reaction can be purified by a publicly known method. Specifically, ultrafiltration, crystallization, microfiltration, acid washing, water washing at an electrical conductivity of 10 mS/m or less, and extraction can be used in combination.

### [Resin Composition]

The resin composition of the present embodiment may contain, for example, at least a polymer containing a constitutional unit represented by the formula (4), the compound (B) represented by the formula (2), and the compound (A) represented by the formula (1). The number of constitutional units (number of monomer units) contained in the above polymer is preferably 5 or more. The content of the compound (B) contained in the above resin composition is preferably 18 by mass or less, more preferably 0.1% by mass or less, and further preferably 0.05% by mass or less, based on the above polymer. The above polymer may be the above polymer (A).

The above polymer (polymer (A)) contained in the resin composition of the present embodiment may be obtained by copolymerizing the compound (A) and other monomers. Examples of other monomers include, but are not particularly limited to, monomers described in International Publication No. WO 2016/125782, International Publication No. WO 2015/115613, Japanese Patent Laid-Open No. 2015/117305, International Publication No. WO 2014/175275, Japanese Patent Laid-Open No. 2012/162498, those described in paragraphs 0015 to 0131 in Japanese Patent Laid-Open No. 2015-161823, those described in paragraphs 0050 to 0059 in Japanese Patent No. 7044011, and at least some monomers described in paragraphs 0096 to 0125 in Japanese Patent Laid-Open No. 2022-123839. Other monomers are not particularly limited, but may be, for example, a compound having a constitutional unit represented by the formula (C1), the formula (C2), the formula (C3), the formula (C4), the formula (C5), or the formula (C6).

The above polymer contained in the resin composition of the present embodiment is preferably obtained by copolymerizing the compound (A) and a compound having a constitutional unit represented by the formula (C6), from the viewpoint of the pattern shape. That is, the above polymer contained in the resin composition of the present embodiment may further contain a constitutional unit represented by the formula (C6).

### [Composition for Film Formation]

The composition for film formation of the present embodiment may contain the compound (A) or the polymer (A) and the compound (B), and is particularly suitable for lithography technology. Also, the composition for film formation of the present embodiment may contain the above composition of the present embodiment or the above resin composition of the present embodiment. The composition can be used for, without particular limitation, film formation purposes for lithography, for example, resist film formation purposes (that is, a “resist composition”). Furthermore, the composition can be used for upper layer film formation purposes (that is, a “composition for upper layer film formation”), intermediate layer formation purposes (that is, a “composition for intermediate layer formation”), underlayer film formation purposes (that is, a “composition for underlayer film formation”), and the like. According to the composition of the present embodiment, not only a film having high sensitivity can be formed, but also a good resist pattern shape can be imparted.

The composition for film formation of the present embodiment can also be used as an optical component forming composition applying lithography technology. The optical component is used in the form of a film or a sheet and is also useful as a plastic lens (a prism lens, a lenticular lens, a microlens, a Fresnel lens, a viewing angle control lens, a contrast improving lens, etc.), a phase difference film, a film for electromagnetic wave shielding, a prism, an optical fiber, a solder resist for flexible printed wiring, a plating resist, an interlayer insulating film for multilayer printed circuit boards, a photosensitive optical waveguide, a liquid crystal display, an organic electroluminescent (EL) display, an optical semiconductor (LED) element, a solid state image sensing element, an organic thin film solar cell, a dye sensitized solar cell, and an organic thin film transistor (TFT). The composition can be suitably utilized as an embedded film and a smoothed film on a photodiode, a smoothed film in front of or behind a color filter, a microlens, and a smoothed film and a conformal film on a microlens, all of which are components of a solid state image sensing element, to which high refractive index is particularly demanded.

As other preferred form of the composition of the present embodiment, the compound (B) contained is preferably as little as 1 ppm by mass or more and 10% by mass or less, more preferably 20 ppm by mass or more to 2% by mass or less, and 50 ppm by mass or more and 1% by mass or less, based on the compound (A) or the polymer (A).

By setting the content of the compound (B) to the above range, although the mechanism is not certain, the compound (B) effectively and actively captures radicals generated by heat and the like, suppresses the deterioration in quality of the compound (A) or the compound represented by the polymer (A) in the composition, suppresses generation of a trace amount of particulate foreign matter, and suppresses defects on a film to be obtained or a pattern after development due to aging.

The composition for film formation of the present embodiment may further contain an acid generating agent (C), a base generating agent (G), or a base compound (H). The composition for film formation of the present embodiment may contain the compound (A) or the polymer (A) and the compound (B), and may contain other components such as a base material (D), a solvent(S), or an acid diffusion controlling agent (E), if required. Hereinafter, each of these components will be described.

### [Base Material (D)]

The “base material (D)” in the present embodiment is a compound (including a resin) other than the compound (A) or the polymer (A) and means a base material applied as a resist for g-ray, i-ray, KrF excimer laser (248 nm), ArF excimer laser (193 nm), extreme ultraviolet (EUV) lithography (13.5 nm) or electron beam (EB) (for example, a base material for lithography or a base material for resist). These base materials can be used as the base material (D) in the present embodiment without particular limitation. Examples of the base material (D) include a phenol novolac resin, a cresol novolac resin, a hydroxystyrene resin, a (meth)acrylic resin, and a hydroxystyrene-(meth)acrylic copolymer, a cycloolefin-maleic anhydride copolymer, a cycloolefin, a vinyl ether-maleic anhydride copolymer, and an inorganic resist material having a metallic element such as titanium, tin, hafnium, and zirconium, and derivatives thereof. Among them, from the viewpoint of the shape of a resist pattern to be obtained, preferable are a phenol novolac resin, a cresol novolac resin, a hydroxystyrene resin, a (meth)acrylic resin, a hydroxystyrene-(meth)acrylic copolymer, and an inorganic resist material having a metallic element such as titanium, tin, hafnium, and zirconium, and derivatives thereof.

Examples of the derivative include, but are not particularly limited to, those to which a dissociation group is introduced and those to which a crosslinkable group is introduced. The above derivative to which a dissociation group or a crosslinkable group is introduced can exhibit dissociation reaction or crosslinking reaction through the effect of light, acid or the like.

The “dissociation group” refers to a characteristic group that is cleaved to generate a functional group that alters solubility, such as an alkali soluble group. Examples of the alkali soluble group include, but are not particularly limited to, a phenolic hydroxy group, a carboxyl group, a sulfonic acid group, and a hexafluoroisopropanol group, and a phenolic hydroxy group and a carboxyl group are preferable, and a phenolic hydroxy group is particularly preferable.

The “crosslinking group” refers to a group that crosslinks in the presence of a catalyst or without a catalyst. Examples of the crosslinking group include, but are not particularly limited to, an alkoxy group having 1 to 20 carbon atoms, a group having an allyl group, a group having a (meth)acryloyl group, a group having an epoxy (meth)acryloyl group, a group having a hydroxy group, a group having a urethane (meth)acryloyl group, a group having a glycidyl group, and a group having a vinyl-containing phenylmethyl group.

### [Solvent(S)]

As the solvent in the present embodiment, a known solvent can be arbitrarily used as long as it can at least dissolve the compound (A) or the polymer (A) mentioned above. Examples of the solvent include, but are not particularly limited to, ethylene glycol monoalkyl ether acetates such as ethylene glycol monomethyl ether acetate, ethylene glycol monoethyl ether acetate, ethylene glycol mono-n-propyl ether acetate, and ethylene glycol mono-n-butyl ether acetate; ethylene glycol monoalkyl ethers such as ethylene glycol monomethyl ether and ethylene glycol monoethyl ether; propylene glycol monoalkyl ether acetates such as propylene glycol monomethyl ether acetate (PGMEA), propylene glycol monoethyl ether acetate, propylene glycol mono-n-propyl ether acetate, and propylene glycol mono-n-butyl ether acetate; propylene glycol monoalkyl ethers such as propylene glycol monomethyl ether (PGME) and propylene glycol monoethyl ether; lactate esters such as methyl lactate, ethyl lactate, n-propyl lactate, n-butyl lactate, and n-amyl lactate; aliphatic carboxylic acid esters such as methyl acetate, ethyl acetate, n-propyl acetate, n-butyl acetate, n-amyl acetate, n-hexyl acetate, methyl propionate, and ethyl propionate; other esters such as methyl 3-methoxypropionate, ethyl 3-methoxypropionate, methyl 3-ethoxypropionate, ethyl 3-ethoxypropionate, methyl 3-methoxy-2-methylpropionate, 3-methoxybutylacetate, 3-methyl-3-methoxybutylacetate, butyl 3-methoxy-3-methylpropionate, butyl 3-methoxy-3-methylbutyrate, methyl acetoacetate, methyl pyruvate, and ethyl pyruvate; aromatic hydrocarbons such as toluene and xylene; ketones such as acetone, 2-butanone, 2-heptanone, ³-heptanone, 4-heptanone, cyclopentanone (CPN), and cyclohexanone (CHN); amides such as N, N-dimethylformamide, N-methylacetamide, N, N-dimethylacetamide, and N-methylpyrrolidone; and lactones such as y-lactone. The solvent used in the present embodiment is preferably a safe solvent, more preferably at least one selected from PGMEA, PGME, CHN, CPN, 2-heptanone, anisole, butyl acetate and ethyl lactate, and further preferably at least one selected from PGMEA, PGME, CHN, CPN and ethyl lactate.

In the composition for film formation of the present embodiment, the solid component concentration is not particularly limited, but is preferably 1 to 80% by mass, more preferably 1 to 50% by mass, further preferably 2 to 40% by mass, and still more preferably 2 to 10% by mass, based on the total mass of the composition for film formation.

### [Acid Generating Agent (C)]

It is preferable that the composition for film formation of the present embodiment contain one or more acid generating agents (C) that directly or indirectly generates an acid by radiation irradiation. Radiation is at least one selected from the group consisting of visible light, ultraviolet, excimer laser, electron beam, extreme ultraviolet (EUV), X-ray, and ion beam. The acid generating agent (C) is not particularly limited, and, for example, an acid generating agent described in International Publication No. WO 2013/024778 can be used. The acid generating agent (C) can be used alone or in combination of two or more kinds.

The amount of the acid generating agent (C) blended is preferably 0.001 to 49% by mass, more preferably 1 to 40% by mass, further preferably 3 to 30% by mass, and still more preferably 10 to 25% by mass, based on the total mass of the solid components. By using the acid generating agent (C) within the above range, a pattern profile with high sensitivity and low edge roughness tends to be obtained. In the present embodiment, the acid generation method is not particularly limited, as long as an acid is generated in the system. By using excimer laser instead of ultraviolet such as g-ray and i-ray, finer processing is possible, and also by using electron beam, extreme ultraviolet, X-ray, or ion beam as a high energy ray, further finer processing is possible.

### [Acid Diffusion Controlling Agent (E)]

The composition for film formation of the present embodiment may contain the acid diffusion controlling agent (E). The acid diffusion controlling agent (E) controls diffusion of an acid generated from an acid generating agent by radiation irradiation in a resist film to inhibit any unpreferable chemical reaction in an unexposed region or the like. By using the acid diffusion controlling agent (E), there is a tendency that the storage stability of the composition of the present embodiment can be improved. Also, by using the acid diffusion controlling agent (E), there is a tendency that not only the resolution of a film formed by using the composition of the present embodiment can be improved, but also the line width change of a resist pattern due to variation in the post exposure delay time before radiation irradiation and the post exposure delay time after radiation irradiation can also be suppressed, making the composition excellent in process stability. Examples of the acid diffusion controlling agent (E) include, but are not particularly limited to, a radiation degradable basic compound such as a nitrogen atom containing basic compound, a basic sulfonium compound, and a basic iodonium compound.

The acid diffusion controlling agent (E) is not particularly limited, and, for example, an acid diffusion controlling agent described in International Publication No. WO 2013/024778 can be used. The acid diffusion controlling agent (E) can be used alone or in combination of two or more kinds.

The amount of the acid diffusion controlling agent (E) blended is preferably 0.001 to 49% by mass, more preferably 0.01 to 10% by mass, further preferably 0.01 to 5% by mass, and further preferably 0.01 to 3% by mass, based on the total mass of the solid components. When the amount of the acid diffusion controlling agent (E) blended is within the above range, there is a tendency that a decrease in resolution, and deterioration of the pattern shape and the dimension fidelity or the like can be prevented. Moreover, even though the post exposure delay time from electron beam irradiation to heating after radiation irradiation becomes longer, deterioration of the shape of the pattern upper layer portion can be suppressed. When the amount of the acid diffusion controlling agent (E) blended is 10% by mass or less, there is a tendency that a decrease in sensitivity, and developability of the unexposed portion or the like can be prevented. Also, by using such an acid diffusion controlling agent, there is a tendency that the storage stability of a resist composition is improved, also along with improvement of the resolution, the line width change of a resist pattern due to variation in the post exposure delay time before radiation irradiation and the post exposure delay time after radiation irradiation can be suppressed, making the composition excellent in process stability.

### [Base Generating Agent (G)]

The case where the base generating agent (G) is a photobase generating agent will be described.

The photobase generating agent generates a base upon exposure and does not exhibit activity under normal conditions at normal temperature and pressure, but is not particularly limited as long as the photobase generating agent generates a base (basic substance) upon irradiation with an electromagnetic wave and heating as an external stimulus.

The photobase generating agent which can be used in the present embodiment is not particularly limited, and a publicly known one can be used, and examples thereof include, for example, a carbamate derivative, an amide derivative, an imide derivative, α-cobalt complex, an imidazole derivative, a cinnamic acid amide derivative, and an oxime derivative.

The basic substance generated from the photobase generating agent is not particularly limited, and examples thereof include compounds having an amino group, particularly monoamines, polyamines such as diamines, and amidines. The basic substance to be generated is preferably a compound having an amino group with a higher basicity (a higher pka value of the conjugate acid) from the viewpoint of sensitivity and resolution.

Examples of the photobase generating agent include, for example, base generating agents having a cinnamic acid amide structure as disclosed in Japanese Patent Laid-Open No. 2009/80452 and International Publication NO. WO 2009/123122; base generating agents having a carbamate structure as disclosed in Japanese Patent Laid-Open No. 2006/189591 and Japanese Patent Laid-Open No. 2008/247747; base generating agents having an oxime structure or a carbamoyloxime structure as disclosed in Japanese Patent Laid-Open No. 2007/249013 and Japanese Patent Laid-Open No. 2008/003581; and compounds described in Japanese Patent Laid-Open No. 2010/243773, but these are not limited thereto, and other known structures of base generating agents can be used.

The photobase generating agent can be used alone or in combination of two or more kinds.

The preferred content of the photobase generating agent in actinic ray or radiation sensitive resin composition is similar to the preferred content of the aforementioned photoacid generating agent in actinic ray or radiation sensitive resin composition.

### [Base Compound (H)]

The base compound (H) is not particularly limited, and a base compound described in International Publication No. WO 2013/024778 can be used. The base compound (H) can be used as one kind or in combination of two or more kinds.

The amount of the base compound (H) blended is preferably 0.001 to 49% by mass, more preferably 0.01 to 5% by mass, and further preferably 0.01 to 3% by mass, based on the total mass of the solid components.

### [Other Component (F)]

To the composition for film formation of the present embodiment, if required, as the other component (F), one kind or two or more kinds of various additives such as a cross-linking agent, a dissolution promoting agent, a dissolution controlling agent, a sensitizing agent, a surfactant, and an organic carboxylic acid or an oxo acid of phosphorus or derivative thereof can be added.

### [Crosslinking Agent]

The composition for film formation of the present embodiment may contain the cross-linking agent. The cross-linking agent may crosslink at least one of the compound (A), the polymer (A), and the base material (D). It is preferable that the crosslinking agent be an acid crosslinking agent capable of intramolecularly or intermolecularly crosslinking the base material (D) in the presence of the acid generated from the acid generating agent (C). Examples of such an acid crosslinking agent can include a compound having one or more groups capable of crosslinking the base material (D) (hereinafter, referred to as a “crosslinkable group”).

Examples of the crosslinkable group include: (i) a hydroxyalkyl group or a group derived therefrom, such as a hydroxy group, a hydroxyalkyl group (alkyl group having 1 to 6 carbon atoms), alkoxy having 1 to 6 carbon atoms (alkyl group having 1 to 6 carbon atoms) and acetoxy (alkyl group having 1 to 6 carbon atoms); (ii) a carbonyl group or a group derived therefrom, such as a formyl group and a carboxy (alkyl group having 1 to 6 carbon atoms); (iii) a nitrogenous group containing group such as a dimethylaminomethyl group, a diethylaminomethyl group, a dimethylolaminomethyl group, a diethylolaminomethyl group and a morpholinomethyl group; (iv) a glycidyl group containing group such as a glycidyl ether group, a glycidyl ester group and a glycidylamino group; (v) a group derived from an aromatic group such as an allyloxy having 1 to 6 carbon atoms (alkyl group having 1 to 6 carbon atoms) and an aralkyloxy having 1 to 6 carbon atoms (alkyl group having 1 to 6 carbon atoms) such as a benzyloxymethyl group and a benzoyloxymethyl group; and (vi) a polymerizable multiple bond containing group such as a vinyl group and an isopropenyl group. As the crosslinkable group of the crosslinking agent in the present embodiment, a hydroxyalkyl group, an alkoxyalkyl group and the like are preferable, and an alkoxymethyl group is particularly preferable.

The crosslinking agent having the crosslinkable group is not particularly limited, and, for example, an acid crosslinking agent described in International Publication No. WO 2013/024778 can be used. The crosslinking agent can be used alone or in combination of two or more kinds.

The amount of the cross-linking agent blended in the present embodiment is preferably 50% by mass or less, more preferably 40% by mass or less, further preferably 30% by mass or less, and further preferably 20% by mass or less, based on the total mass of the solid components.

### (Dissolution Promoting Agent)

The dissolution promoting agent is a component having a function of, when the solubility of a solid component in a developing solution is too low, increasing the solubility of the solid component in a developing solution to moderately increase the dissolution rate of the compound upon developing. As the dissolution promoting agent, those having a low molecular weight are preferable, and examples thereof include a phenolic compound having a low molecular weight. Examples of the phenolic compound having a low molecular weight include a bisphenol and a tris(hydroxyphenyl) methane. These dissolution promoting agents can be used alone or in mixture of two or more kinds.

The amount of the dissolution promoting agent blended, which is arbitrarily adjusted according to the kind of the above solid component to be used, is preferably 0 to 49% by mass of the total mass of the solid component, more preferably 0 to 5% by mass, further preferably 0 to 1% by mass, and particularly preferably 0% by mass.

### (Dissolution Controlling Agent)

The dissolution controlling agent is a component having a function of, when the solubility of a solid component in a developing solution is too high, controlling the solubility of the solid component in a developing solution to moderately decrease the dissolution rate upon developing. As such a dissolution controlling agent, the one which does not chemically change in steps such as calcination of resist coating, radiation irradiation, and development is preferable.

The dissolution controlling agent is not particularly limited, and examples thereof include an aromatic hydrocarbon such as phenanthrene, anthracene and acenaphthene; a ketone such as acetophenone, benzophenone and phenyl naphthyl ketone; and a sulfone such as methyl phenyl sulfone, diphenyl sulfone and dinaphthyl sulfone. These dissolution controlling agents can be used alone or in combination of two or more kinds.

The amount of the dissolution controlling agent blended, which is arbitrarily adjusted according to the kind of the above compound to be used, is preferably 0 to 49% by mass of the total mass of the solid component, more preferably 0 to 5% by mass, further preferably 0 to 1% by mass, and particularly preferably 0% by mass.

### (Sensitizing Agent)

The sensitizing agent is a component having a function of absorbing irradiated radiation energy, transmitting the energy to the acid generating agent (C), and thereby increasing the acid production amount, and improving the apparent sensitivity of a resist. Examples of such a sensitizing agent can include, but are not particularly limited to, a benzophenone, a biacetyl, a pyrene, a phenothiazine and a fluorene. These sensitizing agents can be used alone or in combination of two or more kinds.

The amount of the sensitizing agent blended, which is arbitrarily adjusted according to the kind of the above compound to be used, is preferably 0 to 49% by mass of the total mass of the solid component, more preferably 0 to 5% by mass, further preferably 0 to 1% by mass, and particularly preferably 0% by mass.

### (Surfactant)

The surfactant is a component having a function of improving coatability and striation of the composition of the present embodiment, and developability of a resist or the like. The surfactant may be any of anionic, cationic, nonionic, and amphoteric surfactants. Preferable examples of the surfactant include a nonionic surfactant. The nonionic surfactant has a good affinity with a solvent to be used in production of the composition of the present embodiment, and can further enhance the effects of the composition of the present embodiment. Examples of the nonionic surfactant include, but are not particularly limited to, a polyoxyethylene higher alkyl ether, a polyoxyethylene higher alkyl phenyl ether, and a higher fatty acid diester of polyethylene glycol. Examples of commercially available products of these surfactants include, hereinafter by trade name, EFTOP (manufactured by Jemco Inc.), MEGAFAC (manufactured by DIC Corporation), Fluorad (manufactured by Sumitomo 3M Limited), AsahiGuard, Surflon (hereinbefore, manufactured by Asahi Glass Co., Ltd.), Pepole (manufactured by Toho Chemical Industry Co., Ltd.), KP (manufactured by Shin-Etsu Chemical Co., Ltd.), and Polyflow (manufactured by Kyoeisha Chemical Co., Ltd.).

The amount of the surfactant blended, which is arbitrarily adjusted according to the kind of the above solid component to be used, is preferably 0 to 49% by mass of the total mass of the solid component, more preferably 0 to 5% by mass, further preferably 0 to 1% by mass, and particularly preferably 0% by mass.

### (Organic Carboxylic Acid or Oxo Acid of Phosphorus or Derivative Thereof)

For the purpose of prevention of sensitivity deterioration or improvement of a resist pattern shape and post exposure delay stability or the like, and as an additional optional component, the composition of the present embodiment can contain an organic carboxylic acid or an oxo acid of phosphorus or derivative thereof. The organic carboxylic acid or the oxo acid of phosphorus or derivative thereof can be used in combination with the acid diffusion controlling agent, or may be used alone. Examples of suitable organic carboxylic acids include malonic acid, citric acid, malic acid, succinic acid, benzoic acid and salicylic acid. Examples of the oxo acid of phosphorus or derivative thereof include phosphoric acid or derivative thereof such as ester including phosphoric acid, di-n-butyl phosphate and diphenyl phosphate; phosphonic acid or derivative thereof such as ester including phosphonic acid, dimethyl phosphonate, di-n-butyl phosphonate, phenylphosphonic acid, diphenyl phosphonate and dibenzyl phosphonate; and phosphinic acid and derivative thereof such as ester including phosphinic acid and phenylphosphinic acid. Among them, phosphonic acid is particularly preferable.

The organic carboxylic acid or the oxo acid of phosphorus or derivative thereof can be used alone or in combination of two or more kinds. The amount of the organic carboxylic acid or the oxo acid of phosphorus or derivative thereof blended, which is arbitrarily adjusted according to the kind of the above compound to be used, is preferably 0 to 49% by mass of the total mass of the solid component, more preferably 0 to 5% by mass, further preferably 0 to 1% by mass, and particularly preferably 0% by mass.

### [Other Additive]

Furthermore, the composition of the present embodiment can contain one kind or two kinds or more of additives other than the components mentioned above, if required. Examples of such an additive include a dye, a pigment and an adhesion aid. For example, when the composition is blended with a dye or a pigment, a latent image of the exposed portion is visualized and influence of halation upon exposure can be alleviated, which is preferable. Also, when the composition is blended with an adhesion aid, adhesiveness to a substrate can be improved, which is preferable. Furthermore, examples of the other additive include a halation preventing agent, a storage stabilizing agent, a defoaming agent and a shape improving agent. Specific examples thereof include 4-hydroxy-4′-methylchalkone.

In the composition of the present embodiment, the total content of the optional component (F) can be 0 to 99% by mass of the total mass of the solid component, and is preferably 0 to 49% by mass, more preferably 0 to 10% by mass, further preferably 0 to 5% by mass, still more preferably 0 to 1% by mass, and particularly preferably 0% by mass.

### [Resist Pattern Formation Method]

The resist pattern formation method of the present embodiment comprises:
a step of forming a resist film on a substrate using the above composition for film formation of the present embodiment;
a step of exposing a pattern on the resist film; and
a step of subjecting the resist film to a development treatment after exposure.

The composition for film formation of the present embodiment contains, for example, the compound (A) or the polymer (A) and the compound (B), as described above.

Examples of the coating method in the step of forming a resist film include, but are not particularly limited to, spin coating, dip coating, and roll coating. Examples of the substrate include, but are not particularly limited to, a silicon wafer, metal, plastic, glass, and ceramic. After formation of the resist film, a heat treatment may be carried out at a temperature of about 50° C. to 200° C. The film thickness of the resist film is not particularly limited and is for example, 50 nm to 1 μm.

In the exposure step, exposure may be carried out via a predetermined mask pattern, or shot exposure may be carried out without masking. The thickness of the coating film is, for example, 0.1 to 20 μm, and preferably about 0.3 to 2 μm. Lights of various wavelengths such as ultraviolet ray, X-ray can be utilized for exposure, and for example, far ultraviolet ray such as F2 excimer laser (wavelength: 157 nm), ArF excimer laser (wavelength: 193 nm), and KrF excimer laser (wavelength: 248 nm), extreme ultraviolet ray (wavelength: 13 n), X-ray, and electron beam can be arbitrarily selected and used, as a light source. Among them, extreme ultraviolet ray is preferable. The exposure conditions such as the exposure amount are arbitrarily selected depending on the composition of the above resin and/or compound blended, the kind of each additive, and the like.

In the present embodiment, to stably form a fine pattern with a high degree of accuracy, the resist film is preferably subjected to a heat treatment at a temperature of 50 to 200° C. for 30 seconds or more, after exposure. In this case, variation of sensitivity depending on the kind of substrate may increase at a temperature lower than 50° C. Thereafter, development is carried out with an alkaline developing solution under the conditions of normally at 10 to 50° C. for 10 to 200 seconds, and preferably 20 to 25° C. for 15 to 90 seconds, resulting in formation of a predetermined resist pattern.

The above alkaline developing solution used is an alkaline aqueous solution in which an alkaline compound such as an alkali metal hydroxide, aqueous ammonia, an alkylamine, an alkanolamine, a heterocyclic amine, a tetraalkylammonium hydroxide, choline, 1,8-diazabicyclo-[5.4.0]-7-undecene, and 1,5-diazabicyclo-[4.3.0]-5-nonene is dissolved such that the concentration is normally 1 to 10% by mass and preferably 1 to 3% by mass. Into the above developing solution comprising the alkaline aqueous solution, a water-soluble organic solvent and a surfactant can be arbitrarily added.

The composition of the present embodiment can also be used as an optical component forming composition applying lithography technology. The optical component is used in the form of a film or a sheet and is also useful as a plastic lens (a prism lens, a lenticular lens, a microlens, a Fresnel lens, a viewing angle control lens, a contrast improving lens, etc.), a phase difference film, a film for electromagnetic wave shielding, a prism, an optical fiber, a solder resist for flexible printed wiring, a plating resist, an interlayer insulating film for multilayer printed circuit boards, a photosensitive optical waveguide, a liquid crystal display, an organic electroluminescent (EL) display, an optical semiconductor (LED) element, a solid state image sensing element, an organic thin film solar cell, a dye sensitized solar cell, and an organic thin film transistor (TFT). The composition can be suitably utilized as an embedded film and a smoothed film on a photodiode, a smoothed film in front of or behind a color filter, a microlens, and a smoothed film and a conformal film on a microlens, all of which are components of a solid state image sensing element, to which high refractive index is particularly demanded.

Also, the composition of the present embodiment can be used as a patterning material for lithography applications. For lithography process applications, the composition can be used for various applications such as a semiconductor, a liquid crystal display panel, a display panel using OLED, a power device, and CCD and other sensors. In particular, for semiconductors and integrated circuits on devices, the composition of the present embodiment can be suitably utilized in the process of forming a device element on a silicon wafer, for the purpose of constructing a semiconductor element and other devices by forming a pattern on an insulating film on the substrate side by etching based on the pattern formed on the upper surface side of the insulating layer such as a silicon oxide film and other oxide films utilizing the composition of the present embodiment, further laminating a metal film or a semiconductor material based on the formed insulating film pattern, and forming a circuit pattern.

### EXAMPLES

Hereinafter, the present invention will be described in further detail with reference to Examples and Comparative Examples, but the present invention is not limited by these Examples in any way.

### [Measurement Method]

### [Nuclear Magnetic Resonance (NMR)]

The structure of the compound was verified by carrying out NMR measurement under the following conditions using a nucleus magnetic resonance apparatus “Advance 600 II spectrometer” (product name, manufactured by Bruker).

### [¹H-NMR Measurement]

Frequency: 400 MHz
Solvent: CDCl₃, or de-DMSO
Internal standard: TMS
Measurement temperature: 23° C.

### [¹³C-NMR Measurement]

Frequency: 500 MHz
Solvent: CDCl₃, or d₆-DMSO
Internal standard: TMS
Measurement temperature: 23° C.

### [Inorganic Element Content]

The metal content contained in the compounds prepared in Examples and Comparative Examples was measured using an inorganic element analyzer (ICP-AES/ICP-MS) “AG8900” (product name, manufactured by Agilent Technologies, Inc.).

### [Organic Impurity Content]

The organic impurity content contained in the compounds prepared in Examples and Comparative Examples was calculated from the area fraction of the GC chart and the peak intensity ratio between the target peak and the reference peak by gas chromatography mass spectrometry (GC-MS).

### (Synthetic Example BP1) Synthesis of Compound BP1 Represented by Formula (BP1)

The compound BP1 (trans-isomer) represented by the formula (BP1) was synthesized by the method described below.

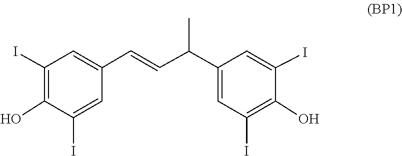 [SMILES: CC(/C=C/c1cc(I)c(O)c(I)c1)c1cc(I)c(O)c(I)c1]

The reactor was charged with 15.6 g of 1-(4-hydroxy-3,5-diiodophenyl)ethanol, 0.15 g of methanesulfonic acid, 0.04 g of 4-hydroxy-2,2,6,6-tetramethylpiperidine 1-oxyl free radical, and 60 mL of DMSO (dimethylsulfoxide), and stirring was initiated. Subsequently, reduced pressure conditions were regulated to reflux at 120° C. using a Dienstark and a condenser, and blowing of air into the reaction solution at a flow rate of 1 mL/minute was initiated. The moisture recovered in the Dienstark was arbitrarily discharged to the outside of the system. Subsequently, the reactor was immersed in a water bath at 90° C., and stirring was continued over 30 hours. Subsequently, the reactor was immersed in a water bath at 25° C. to cool the reaction solution. Subsequently, the reaction solution was gradually added to 500 g of an aqueous sodium hydrogen sulfite solution with a mass % concentration of 0.1 with vigorous stirring and mixed. Subsequently, the precipitate was filtered off with a suction filter, compressed, and washed with 200 mL of an aqueous methanol solution with a volume % concentration of 33.3. After only main components (trans-isomer) were isolated from the obtained precipitate by column purification, the solvent was distilled off by evaporation, and the obtained solid was dried in vacuo at 40° C. to obtain 8.1 g of a white solid. The yield was 26%.

As a result of the analysis by liquid chromatography-mass spectrometry (LC-MS), the molecular weight was found to be 743.9, and the white solid was confirmed to be the compound BP1 represented by the formula (BP1).

The following peaks were found by carrying out 1H-NMR measurement under the above measurement conditions, and the compound was confirmed to have the chemical structure of the compound BP1.
δ (ppm) (d₆-DMSO): 9.6 (2H, OH), 7.5 (2H, Ph), 7.8 (2H, Ph), 3.6 (1H, —CH—), 1.3 (3H, —CH3), 6.4-6.7 (2H, —CH═CH—)

### (Synthetic Example BP2) Synthesis of Compound BP2 Represented by Formula (BP2)

The compound BP2 (trans-isomer) represented by the formula (BP2) was synthesized by the method described below.

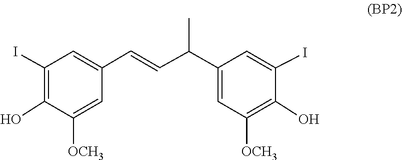 [SMILES: COc1cc(/C=C/C(C)c2cc(I)c(O)c(OC)c2)cc(I)c1O]

The reactor was charged with 11.8 g of 1-(4-hydroxy-3-methoxy-5-iodophenyl)ethanol, 0.2 g of methanesulfonic acid, 0.15 g of 4-methoxyphenol, and 60 mL of toluene, and stirring was initiated. Subsequently, blowing of air into the reaction solution at a flow rate of 1 mL/minute was initiated under reflux conditions at 113° C. using a Dienstark and a condenser. The moisture recovered in the Dienstark was arbitrarily discharged to the outside of the system. Subsequently, the reactor was immersed in a water bath at 90° C., and stirring was continued over 30 hours. Subsequently, the reactor was immersed in a water bath at 25° C. to cool the reaction solution. Subsequently, the reaction solution was gradually added to 500 g of an aqueous sodium hydrogen sulfite solution with a mass % concentration of 0.1 with vigorous stirring and mixed. Subsequently, the precipitate was filtered off with a suction filter, compressed, and washed with 200 mL of an aqueous methanol solution with a volume concentration of 33.3. After only main components (trans-isomer) were isolated from the obtained precipitate by column purification, the solvent was distilled off by evaporation, and the obtained solid was dried in vacuo at 40° C. to obtain 10.2 g of a white solid. The yield was 43%.

As a result of the analysis by liquid chromatography-mass spectrometry (LC-MS), the molecular weight was found to be 552.2, and the white solid was confirmed to be the compound BP2 represented by the formula (BP2).

The following peaks were found by carrying out 1H-NMR measurement under the above measurement conditions, and the compound was confirmed to have the chemical structure of the compound BP2.
δ (ppm) (d₆-DMSO): 9.6 (2H, OH), 7.0-7.2 (2H, Ph), 6.7 (1H, Ph), 7.5 (1H, Ph), 3.6 (1H, —CH—), 1.3 (3H, —CH3), 6.4-6.7 (2H, —CH═CH—), 3.8 (6H, —CH3)

### (Synthetic Example BP3) Synthesis of Compound BP3 Represented by Formula (BP3)

The compound BP3 represented by the formula (BP3) was synthesized by the method described below.

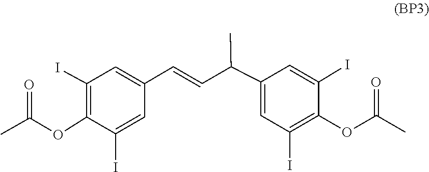 [SMILES: CC(=O)Oc1c(I)cc(/C=C/C(C)c2cc(I)c(OC(C)=O)c(I)c2)cc1I]

The following steps were conducted using the compound BP1 synthesized above.

Using a 1 L eggplant flask, 1.57 g of acetic anhydride, 1.53 g of triethylamine, 0.19 g of DMAP, and 35 mL of a solvent (dichloromethane), which were cooled to 4° C. with ice water, were put thereinto, and stirred and dissolved to prepare a reaction solution. Under cooling with ice at 4° C., 7.43 g, 10 mmol of the compound BP1 (trans-isomer) prepared in the previous step was dissolved in 10 mL of dichloromethane to prepare a solution of the compound BP1, which was added to the solution prepared in the 1 L eggplant flask over 30 minutes. Thereafter, the mixture was stirred at 4° C. for 2 hours to allow the reaction to proceed sufficiently and washed with 40 mL of ice water and 40 mL of brine sufficiently, the obtained organic phase was dried over magnesium sulfate, the filtrate after filtration was concentrated under reduced pressure to obtain a reaction product. The reaction product was further purified by column and the developing solvent was distilled off to collect 6.7 g of the target compound BP3.

The following peaks were found by carrying out 1H-NMR measurement under the above measurement conditions, and the compound was confirmed to have the chemical structure of the compound BP3.
δ (ppm) (d₆-DMSO): 2.3 (6H, —CH3), 7.7 (2H, Ph), 8.0 (2H, Ph), 1.3 (3H, —CH3), 3.6 (1H, —CH—), 6.4-6.7 (2H, —CH═CH—)

### (Synthetic Example BP4) Synthesis of Compound BP4 Represented by Formula (BP4)

The compound BP4 represented by the formula (BP4) was synthesized by the method described below.

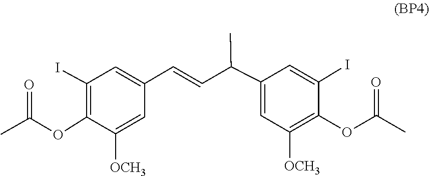 [SMILES: COc1cc(/C=C/C(C)c2cc(I)c(OC(C)=O)c(OC)c2)cc(I)c1OC(C)=O]

The following steps were conducted using the compound BP2 (trans-isomer) synthesized above.

Using a 1 L eggplant flask, 1.57 g of acetic anhydride, 1.53 g of triethylamine, 0.19 g of DMAP (4-dimethylaminopyridine), and 35 mL of a solvent (dichloromethane), which were cooled to 4° C. with ice water, were put thereinto, and stirred and dissolved to prepare a reaction solution. Under cooling with ice at 4° C., 7.43 g, 10 mmol of the compound BP2 prepared in the previous step was dissolved in 10 mL of dichloromethane to prepare a solution of the compound BP2, which was added to the solution prepared in the 1 L eggplant flask over 30 minutes. Thereafter, the mixture was stirred at 4° C. for 2 hours to allow the reaction to proceed sufficiently and washed with 40 mL of ice water and 40 mL of brine sufficiently, the obtained organic phase was dried over magnesium sulfate, the filtrate after filtration was concentrated under reduced pressure to obtain a reaction product. The reaction product was further purified by column and the developing solvent was distilled off to collect 7.1 g of the target compound BP4.

The following peaks were found by carrying out 1H-NMR measurement under the above measurement conditions, and the compound was confirmed to have the chemical structure of the compound BP4.
δ (ppm) (d₆-DMSO): 2.3 (6H, —CH3), 6.9-7.7 (4H, Ph), 1.3 (3H, —CH3), 3.6 (1H, —CH—), 6.3-6.7 (2H, —CH═CH—), 3.8 (6H, —CH3)

### (Synthetic Example BP11) Synthesis of Compound BP11 Represented by Formula (BP11)

The compound BP11 represented by the formula (BP11) was synthesized by the method described below.

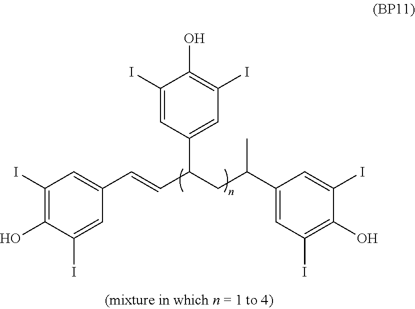

The reactor was charged with 15.6 g of 1-(4-hydroxy-3,5-diiodophenyl)ethanol, 0.15 g of methanesulfonic acid, 0.04 g of 4-hydroxy-2,2,6,6-tetramethylpiperidine 1-oxyl free radical, and 60 mL of DMSO, and stirring was initiated. Subsequently, reduced pressure conditions were regulated to reflux at 120° C. using a Dienstark and a condenser, and blowing of air into the reaction solution at a flow rate of 1 mL/minute was initiated. The moisture recovered in the Dienstark was arbitrarily discharged to the outside of the system. Subsequently, the reactor was immersed in a water bath at 90° C., and stirring was continued over 30 hours. Subsequently, the reactor was immersed in a water bath at 25° C. to cool the reaction solution. Subsequently, the reaction solution was gradually added to 500 g of an aqueous sodium hydrogen sulfite solution with a mass % concentration of 0.1 with vigorous stirring and mixed. Subsequently, the precipitate was filtered off with a suction filter, compressed, and washed with 200 mL of an aqueous methanol solution with a volume % concentration of 33.3. After oligomer components were collected from the obtained precipitate by column purification, the solvent was distilled off by evaporation, and the obtained solid was dried in vacuo at 40° C. to obtain 11.2 g of a white solid. The yield was 36%.

As a result of the analysis by mass spectrometry (FD-MS), the molecular weight was found to be 743.9, 1115.8, 1487.7, and 1859.6, and the white solid was confirmed to contain the same component as BP11 by liquid chromatography-mass spectrometry (LC-MS). As a result of these analyses, the white solid was confirmed to be the compound BP11 represented by the formula (BP11).

### (Synthetic Example BP12) Synthesis of Compound BP12 Represented by Formula (BP12)

The compound BP12 represented by the formula (BP12) was synthesized by the method described below.

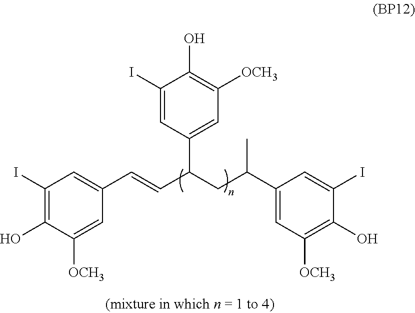

The reactor was charged with 11.8 g of 1-(4-hydroxy-3-methoxy-5-iodophenyl)ethanol, 0.2 g of methanesulfonic acid, 0.15 g of 4-methoxyphenol, and 60 mL of toluene, and stirring was initiated. Subsequently, blowing of air into the reaction solution at a flow rate of 1 mL/minute was initiated under reflux conditions at 113° C. using a Dienstark and a condenser. The moisture recovered in the Dienstark was arbitrarily discharged to the outside of the system. Subsequently, the reactor was immersed in a water bath at 90° C., and stirring was continued over 30 hours. Subsequently, the reactor was immersed in a water bath at 25° C. to cool the reaction solution. Subsequently, the reaction solution was gradually added to 500 g of an aqueous sodium hydrogen sulfite solution with a mass % concentration of 0.1 with vigorous stirring and mixed. Subsequently, the precipitate was filtered off with a suction filter, compressed, and washed with 200 mL of an aqueous methanol solution with a volume % concentration of 33.3. After oligomer components were collected from the obtained precipitate by column purification, the solvent was distilled off by evaporation, and the obtained solid was dried in vacuo at 40° C. to obtain 12.3 g of a white solid. The yield was 52%.

As a result of the analysis by mass spectrometry (FD-MS), the molecular weight was found to be 552.2, 828.2, 1104.2, and 1380.2. As a result of the analysis by LC-MS, the same component as BP12 was confirmed to be contained. As a result of the above analyses, the white solid was confirmed to be the compound BP12 represented by the formula (BP12).

### (Synthetic Examples Al to A16, ACL1, AMD3 to AMD4, AH2, and AR1 to AR-2) Synthesis of compounds A1 to A16, ACL1, AMD3 to AMD4, AH2, and AR1 to AR-2 represented by formulas (A1) to (A16), (ACL1), (AMD3) to (AMD4), (AH2), and (AR-1) to (AR-2)

The compounds (the following compounds A1 to A16, ACL1, AMD3 to AMD4, AH2, and ARI to AR-2) represented by the formulas (M1) to (M16), (MCL1), (MD3) to (MD4), (MH2), and (MR-1) to (MR-2) described in International Publication No. WO2021/029395 were synthesized according to the description in International Publication No. WO2021/029395.

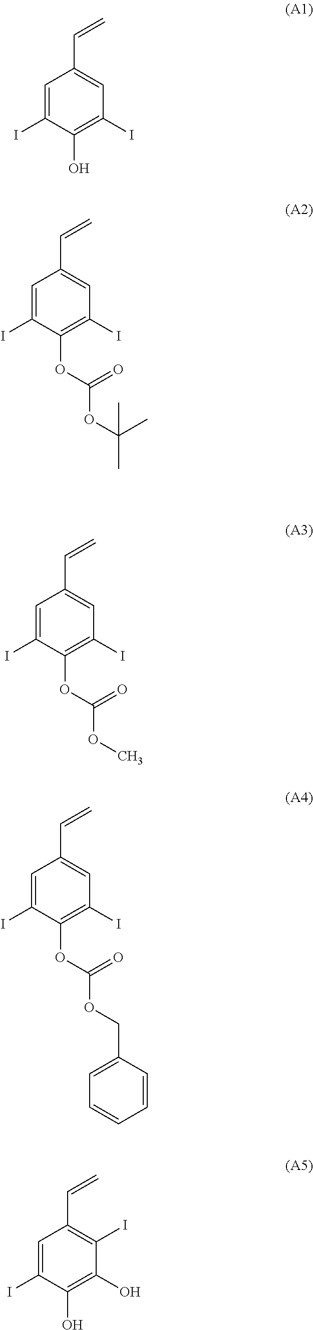 [SMILES: C=Cc1cc(I)c(O)c(I)c1 ; C=Cc1cc(I)c(OC(=O)OC(C)(C)C)c(I)c1 ; C=Cc1cc(I)c(OC(=O)OC)c(I)c1 ; C=Cc1cc(I)c(OC(=O)OCc2ccccc2)c(I)c1 ; C=Cc1cc(I)c(O)c(O)c1I]

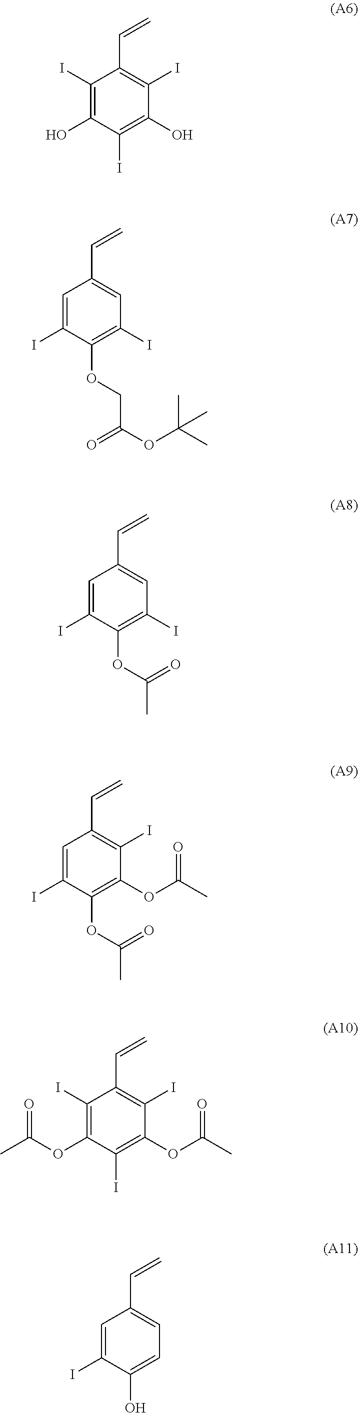

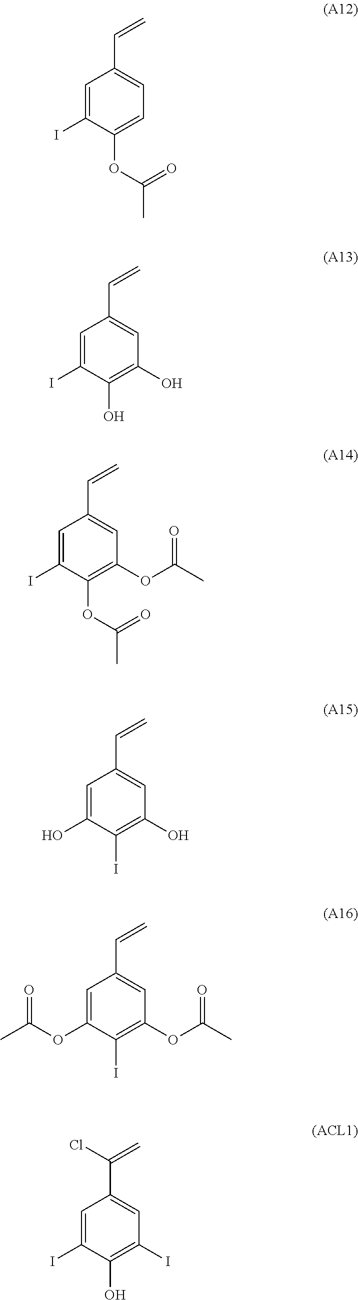

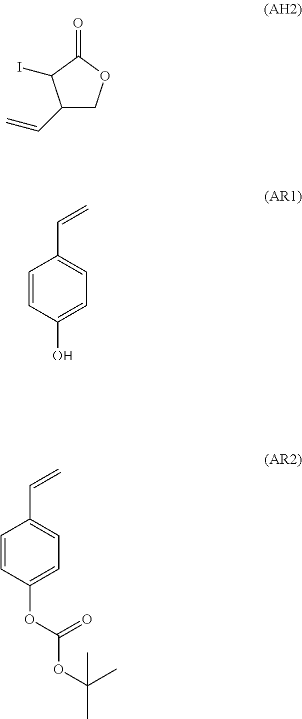

### (Synthetic Example Aa1) Synthesis of Compound Mal Represented by Formula (Mal)

Into a 3 L glass flask as a reaction vessel, 283 g (792 mmol) of triphenylphosphonium methyl bromide, 7 mg of methylhydroquinone, and 1470 mL of dehydrated THE were put and dissolved. While the temperature was regulated to 15° C. or less, 148 g (1320 mmol) of potassium tert-butoxide was added portionwise into a THE solution which was put in an ice bath, and then the mixture was stirred for 30 minutes as it was. While the temperature was further regulated to 25° C. or less, 147 g (529 mmol) of 4-hydroxy-3-iodo-5-methoxybenzenecarbaldehyde was added portionwise, and then the mixture was stirred for 30 minutes as it was. Thereafter, the reaction solution was added to 4000 mL of a 3N aqueous HCl solution, and then the mixture was further washed with 1 L of toluene and 2 L of water in the order presented. 128 g of 4-hydroxy-3-iodo-5-methoxystyrene represented by the formula (Mal) as the target substance was isolated using a silica gel column.

As a result of the analysis by liquid chromatography-mass spectrometry (LC-MS), the molecular weight was found to be 276.

The following peaks were found by carrying out 1H-NMR measurement under the above measurement conditions, and the compound was confirmed to have the chemical structure of the compound Mal represented by the formula (Mal).
δ (ppm) (d₆-DMSO): 3.8 (3H, —CH3), 7.7 (2H, Ph), 6.7 (1H, —CH═), 5.3 (1H, =CH2), 5.7 (1H, =CH2), 9.5 (1H, —OH)

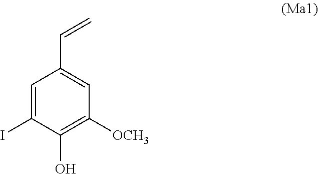

### (Synthetic Example Aala) Synthesis of compound Ala represented by formula (Ma1a) (synthesis of 4-acetoxy-3-iodo-5-methoxystyrene)

Using a 100 mL glass flask as a reaction vessel, 16.7 g (45 mmol) of 4-hydroxy-3-iodo-5-methoxystyrene was dissolved by using dimethylsulfoxide as a solvent, 2 eq. of acetic anhydride and 1 eq. of sulfuric acid were added thereto, and then the mixture was warmed to 80° C. and stirred for 3 hours. Thereafter, the stirred solution was cooled, and the precipitate was filtered off, washed, and dried to obtain 9.0 g of a white solid. The white solid sample was analyzed by liquid chromatography-mass spectrometry (LC-MS) and, as a result, the molecular weight was found to be 414 and the white solid was confirmed to be 4-acetoxy-3-iodo-5-methoxystyrene. The following peaks were found by carrying out 1H-NMR measurement under the above measurement conditions, and the compound was confirmed to have the chemical structure of 4-acetoxy-3-iodo-5-methoxystyrene of the compound Ala represented by the formula (Mala).
δ (ppm) (d₆-DMSO): 7.9 (2H, Ph), 6.6 (1H, —CH2-), 5.7 (1H, =CH2), 5.1 (1H, =CH2), 3.8 (3H, —CH3), 2.3 (3H, —CH3)

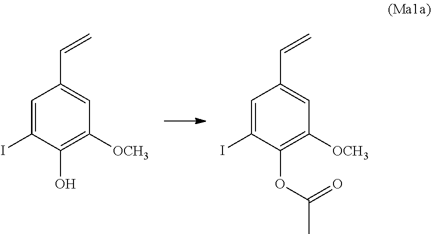

### (Synthetic Example Aa2) Synthesis of compound Ma2 represented by formula (Ma2)

The reaction was carried out in the same manner as Example A1, except that 4-hydroxy-3-iodo-5-methoxybenzenecarbaldehyde of Synthetic Example Aal was changed to ³-ethoxy-4-hydroxy-5-iodobenzenecarbaldehyde, thereby isolating 132 g of ³-ethoxy-4-hydroxy-5-iodostyrene represented by the formula (Ma2) as the target substance.

As a result of the analysis by liquid chromatography-mass spectrometry (LC-MS), the molecular weight was found to be 290.

The following peaks were found by carrying out 1H-NMR measurement under the above measurement conditions, and the compound was confirmed to have the chemical structure of the compound Ma2 represented by the formula (Ma2).
δ (ppm) (d₆-DMSO): 9.5 (1H, —OH), 7.7 (2H, Ph), 6.7 (1H, —CH═), 5.7 (1H, =CH2), 5.3 (1H, =CH2), 4.1 (2H, —CH2—), 1.4 (3H, —CH3)

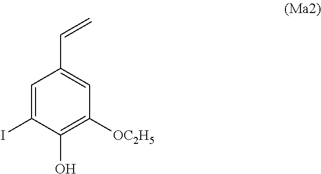

### (Synthetic Example Aa2a) Synthesis of Compound A2a Represented by Formula (Ma2a)

The reaction was carried out in the same manner as Synthetic Example 1: Example A1a except that 4-hydroxy-3-iodo-5-methoxystyrene of Synthetic Example Aala was changed to ³-ethoxy-4-hydroxy-5-iodostyrene, thereby isolating 9.1 g of a white solid. The white solid sample was analyzed by liquid chromatography-mass spectrometry (LC-MS) and, as a result, the molecular weight was found to be 332 and the white solid was confirmed to be 4-acetoxy-3-ethoxy-5-iodostyrene.

The following peaks were found by carrying out 1H-NMR measurement under the above measurement conditions, and the compound was confirmed to have the chemical structure of 4-acetoxy-3-ethoxy-5-iodostyrene of the compound A2a represented by the formula (Ma2a).
δ (ppm) (d₆-DMSO): 7.7 (2H, Ph), 6.7 (1H, —CH═), 5.7 (1H, =CH2), 5.3 (1H, =CH2), 4.1 (2H, —CH2—), 2.3 (3H, —CH3) 1.4 (3H, —CH3)

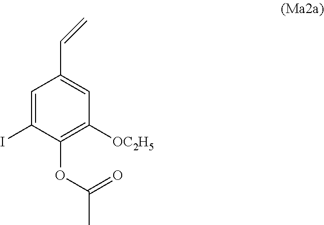 [SMILES: C=Cc1cc(I)c(OC(C)=O)c(OCC)c1]

### (Synthetic Example Aa3) Synthesis of Compound Aa3 Represented by Formula (Ma3)

Into 400 mL of dichloromethane in a 2 L flask, 41 g of the compound Mal obtained in Synthetic Example Aal, 16.2 g of triethylamine, and 0.7 g of N-(4-pyridyl)dimethylamine (DMAP) were dissolved under a nitrogen flow. 33.6 g of di-tert-butyl dicarbonate was dissolved in 100 ml of dichloromethane, which was added dropwise into the aforementioned 2 L flask with stirring, and the mixture was stirred at room temperature for 3 hours. Thereafter, water washing was conducted three times by a separation operation using 100 ml of water, the solvent was distilled off from the obtained organic phase, original components were removed by silica gel chromatography using dichloromethane/hexane, and the solvent was further distilled off to obtain 4.5 g of a BOC group-substituted compound (a compound represented by the following formula (Ma3), hereinafter, also referred to as the “compound Aa3”) of the compound Mal, as the target component.

As a result of the analysis by liquid chromatography-mass spectrometry (LC-MS), the molecular weight was found to be 376.

The following peaks were found by carrying out 1H-NMR measurement under the above measurement conditions, and the compound was confirmed to have the chemical structure of the compound represented by the formula (Ma3).
δ (ppm) (d₆-DMSO): 7.7 (2H, Ph), 6.7 (1H, —CH═), 5.7 (1H, =CH2), 5.3 (1H, =CH2), 3.8 (3H, —CH3), 1.4 (9H, —C—(CH3) 3)

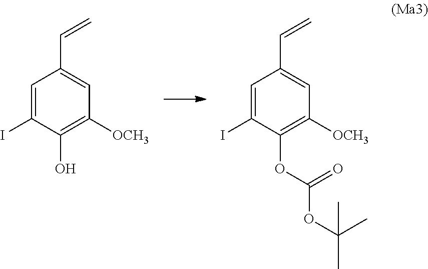 [SMILES: C=Cc1cc(I)c(O)c(OC)c1 ; C=Cc1cc(I)c(OC(=O)OC(C)(C)C)c(OC)c1]

### (Synthetic Example Aa4) Synthesis of Compound Aa4 Represented by Formula (Ma4)

In a container (internal capacity: 200 mL) equipped with a stirrer, a condenser tube, and a burette, 100 mL of acetone was charged with 4.61 g (12.4 mmol) of the compound Mal obtained in the above Synthetic Example Aal and 2.42 g (12.4 mmol) of ethylvinyl ether, 2.5 g of pyridinium p-toluenesulfonate was added, and the contents were reacted by being stirred at room temperature for 24 hours to obtain a reaction solution. Next, the reaction solution was concentrated, and the reaction product was filtered to separate solid matter.

The obtained solid matter was filtered and then dried, and then the solid matter was separated and purified by column chromatography to obtain 3.2 g of the compound Aa4 (a compound represented by the following formula (Ma4)).

As a result of the analysis by liquid chromatography-mass spectrometry (LC-MS), the molecular weight was found to be 348.

The following peaks were found by carrying out 1H-NMR measurement under the above measurement conditions, and the compound was confirmed to have the chemical structure of the compound represented by the formula (Ma4).
δ (ppm) (d₆-DMSO): 7.7 (2H, Ph), 6.7 (1H, —CH═), 5.7 (1H, =CH2), 5.6 (1H, CH₃CH—), 5.3 (1H, =CH2), 3.8 (3H, —CH3), 3.9 (2H, CH₃CH2—), 1.6 (3H, CH₃CH—), 1.2 (3H, CH3CH2-)

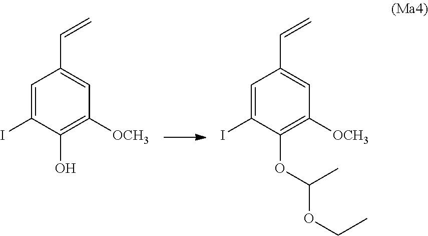 [SMILES: C=Cc1cc(I)c(O)c(OC)c1 ; C=Cc1cc(I)c(OC(C)OCC)c(OC)c1]

### (Synthetic Example Aa5) Synthesis of Compound Aa5 Represented by Formula (Ma5)

In a container (internal capacity: 200 mL) equipped with a stirrer, a condenser tube, and a burette, 4.61 g (12.4 mmol) of the compound Mal obtained in the above Synthetic Example Aal and 2.42 g (12.4 mmol) of tetrahydropyran were charged to 100 mL of acetone, 2.5 g of pyridinium p-toluenesulfonate was added, and the contents were reacted by being stirred at room temperature for 24 hours to obtain a reaction solution. Next, the reaction solution was concentrated, and the reaction product was filtered to separate solid matter.

The obtained solid matter was filtered and then dried, and then the solid matter was separated and purified by column chromatography to obtain 3.2 g of the compound Aa5 (a compound represented by the following formula (Ma5)).

The following peaks were found by carrying out ¹H-NMR measurement under the above measurement conditions, and the compound was confirmed to have the chemical structure of the compound represented by the formula (Ma5).

As a result of the analysis by liquid chromatography-mass spectrometry (LC-MS), the molecular weight was found to be 360.
δ (ppm) (d₆-DMSO): 7.7 (2H, Ph), 6.7 (1H, —CH═), 5.8 (1H, proton of tetrahydropyranyl group ═CH—), 5.7 (1H, =CH2), 5.3 (1H, =CH2), 3.8 (3H, —CH3), 1.6-3.7 (8H, proton of tetrahydropyranyl group-CH2-)

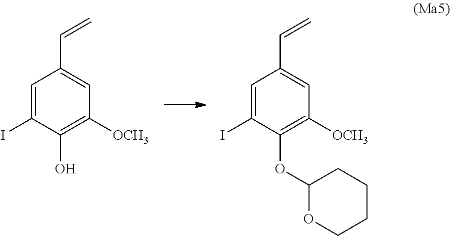 [SMILES: C=Cc1cc(I)c(O)c(OC)c1 ; C=Cc1cc(I)c(OC2CCCCO2)c(OC)c1]

### (Synthetic Example Aa6) Synthesis of Compound Aa6 Represented by Formula (Ma6)

In a container (internal capacity: 200 mL) equipped with a stirrer, a condenser tube, and a burette, 4.61 g (12.4 mmol) of the compound Mal obtained in the above Synthetic Example Aal and 2.42 g (12.4 mmol) of tert-butyl bromoacetate were charged to 100 mL of acetone, 1.71 g (12.4 mmol) of potassium carbonate and 0.4 g of 18-crown-6 (IUPAC name: 1,4,7,10,13,16-hexaoxacyclooctadecane) was added, and the contents were reacted by being stirred under reflux for 3 hours to obtain a reaction liquid. Next, the reaction solution was concentrated, and the reaction product was precipitated by the addition of 100 g of pure water to the concentrate, cooled to room temperature, and then filtered to separate solid matter.

The obtained solid matter was filtered and then dried, and then the solid matter was separated and purified by column chromatography to obtain 3.2 g of the compound Aa6 (a compound represented by the following formula (Ma6)).

As a result of the analysis by liquid chromatography-mass spectrometry (LC-MS), the molecular weight was found to be 390.

The following peaks were found by carrying out 1H-NMR measurement under the above measurement conditions, and the compound was confirmed to have the chemical structure of the compound represented by the formula (Ma6). δ (ppm) (d₆-DMSO): 7.7 (2H, Ph), 6.7 (1H, —CH═), 5.7 (1H, =CH2), 5.3 (1H, =CH2), 5.0 (2H, —CH2—), 3.8 (3H, —CH3), 1.4 (9H, —C—(CH3) 3)

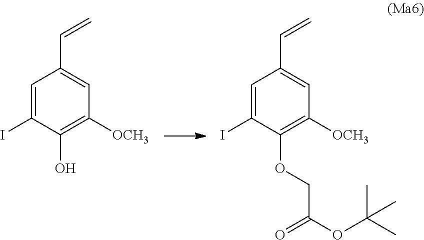 [SMILES: C=Cc1cc(I)c(O)c(OC)c1 ; C=Cc1cc(I)c(OCC(=O)OC(C)(C)C)c(OC)c1]

### (Synthetic Example Aa7) Synthesis of Compound Aa7 Represented by Formula (Ma7)

In a container (internal capacity: 200 mL) equipped with a stirrer, a condenser tube, and a burette, 4.61 g (12.4 mmol) of the compound Mal obtained in the above Synthetic Example Aal and 2.42 g (12.4 mmol) of bromoacetic acid 2-methyl-2-adamantyl ester were charged to 100 mL of acetone, 1.71 g (12.4 mmol) of potassium carbonate and 0.4 g of 18-crown-6 (IUPAC name: 1,4,7,10,13,16-hexaoxacyclooctadecane) was added, and the contents were reacted by being stirred under reflux for 3 hours to obtain a reaction liquid. Next, the reaction solution was concentrated, and the reaction product was precipitated by the addition of 100 g of pure water to the concentrate, cooled to room temperature, and then filtered to separate solid matter.

The obtained solid matter was filtered and then dried, and then the solid matter was separated and purified by column chromatography to obtain 3.2 g of the compound Aa7 (a compound represented by the following formula (Ma7)).

The following peaks were found by carrying out 1H-NMR measurement under the above measurement conditions, and the compound was confirmed to have the chemical structure of the compound represented by the formula (Ma 7).

As a result of the analysis by liquid chromatography-mass spectrometry (LC-MS), the molecular weight was found to be 482.
δ (ppm) (d₆-DMSO): 7.7 (2H, Ph), 6.7 (1H, —CH═), 5.7 (1H, =CH2), 5.3 (1H, =CH2), 5.0 (2H, —CH2—), 3.8 (3H, —CH3), 0.8-2.4 (17H, protons of 2-methyl-2-adamantyl group)

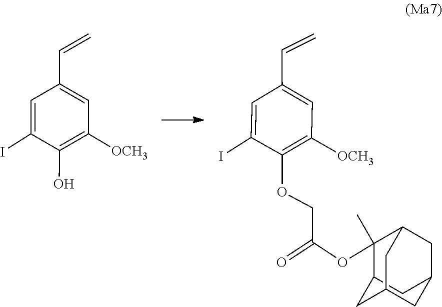 [SMILES: C=Cc1cc(I)c(O)c(OC)c1 ; C=Cc1cc(I)c(OCC(=O)OC2(C)C3CC4CC(C3)CC2C4)c(OC)c1]

### (Synthetic Example Aa8) Synthesis of Compound Aa8 Represented by Formula (Ma8)

In a container (internal capacity: 200 mL) equipped with a stirrer, a condenser tube, and a burette, 4.61 g (12.4 mmol) of the compound Mal obtained in the above Synthetic Example Aal and 1.70 g (12.4 mmol) of t-butyl bromide were charged to 100 mL of acetone, 1.71 g (12.4 mmol) of potassium carbonate and 0.4 g of 18-crown-6 (IUPAC name: 1,4,7,10,13,16-hexaoxacyclooctadecane) was added, and the contents were reacted by being stirred under reflux for 3 hours to obtain a reaction liquid. Next, the reaction solution was concentrated, and the reaction product was precipitated by the addition of 100 g of pure water to the concentrate, cooled to room temperature, and then filtered to separate solid matter.

The obtained solid matter was filtered and then dried, and then the solid matter was separated and purified by column chromatography to obtain 0.5 g of the compound Aa8 (a compound represented by the following formula (Ma8)).

The following peaks were found by carrying out 1H-NMR measurement under the above measurement conditions, and the compound was confirmed to have the chemical structure of the compound represented by the formula (Ma8).

As a result of the analysis by liquid chromatography-mass spectrometry (LC-MS), the molecular weight was found to be 332.
δ (ppm) (d₆-DMSO): 7.7 (2H, Ph), 6.7 (1H, —CH═), 5.7 (1H, =CH2), 5.3 (1H, =CH2), 3.8 (3H, —CH3), 1.4 (9H, —C—(CH3) 3)

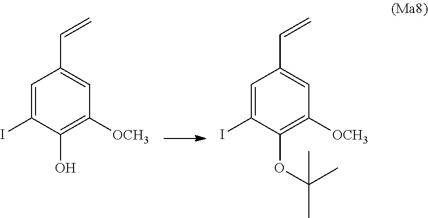 [SMILES: C=Cc1cc(I)c(O)c(OC)c1 ; C=Cc1cc(I)c(OC(C)(C)C)c(OC)c1]

### (Synthetic Example Aa9) Synthesis of Compound Aa9 Represented by Formula (Ma9)

In Synthetic Example Aa3, the reaction was carried out in the same manner as Example Aa3, except that 4-hydroxy-3-iodo-5-methoxystyrene (compound Mal) was changed to ³-ethoxy-4-hydroxy-5-iodostyrene, thereby obtaining 4.6 g of a BOC group-substituted compound of the compound A2 represented by the formula (Ma9) as the target substance (a compound represented by the following formula (Ma9), hereinafter, also referred to as the “compound Aa9”).

As a result of the analysis by liquid chromatography-mass spectrometry (LC-MS), the molecular weight was found to be 390.

The following peaks were found by carrying out 1H-NMR measurement under the above measurement conditions, and the compound was confirmed to have the chemical structure of the compound represented by the formula (Ma9). δ (ppm) (d₆-DMSO): 7.7 (2H, Ph), 6.7 (1H, —CH═), 5.7 (1H, =CH2), 5.3 (1H, =CH2), 4.1 (2H, —CH2—), 1.4 (3H, —CH3), 1.3 (H, —C—(CH3) 3)

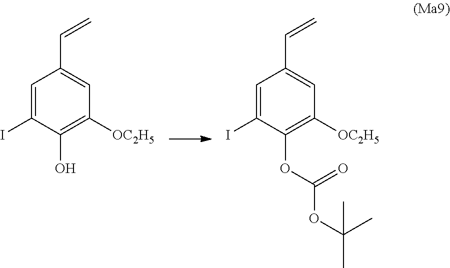 [SMILES: C=Cc1cc(I)c(O)c(OCC)c1 ; C=Cc1cc(I)c(OC(=O)OC(C)(C)C)c(OCC)c1]

### (Synthetic Example Aa10) Synthesis of Compound Aa10 Represented by Formula (Ma10)

In Synthetic Example A4, the reaction was carried out in the same manner as Example Aa4, except that 4-hydroxy-3-iodo-5-methoxystyrene (compound Mal) was changed to ³-ethoxy-4-hydroxy-5-iodostyrene, thereby obtaining 3.5 g of a compound represented by the formula (Ma10) as the target substance, hereinafter, also referred to as the “compound Aa10”).

As a result of the analysis by liquid chromatography-mass spectrometry (LC-MS), the molecular weight was found to be 362.

The following peaks were found by carrying out ¹H-NMR measurement under the above measurement conditions, and the compound was confirmed to have the chemical structure of the compound represented by the formula (Ma10). δ (ppm) (d₆-DMSO): 7.7 (2H, Ph), 6.7 (1H, —CH═), 5.7 (1H, =CH2), 5.6 (1H, CH₃CH—), 5.3 (1H, =CH2), 4.1 (2H, —CH2—), 3.9 (2H, CH₃CH2—), 1.6 (3H, CH₃CH—), 1.4 (3H, —CH3), 1.2 (3H, CH₃CH2-)

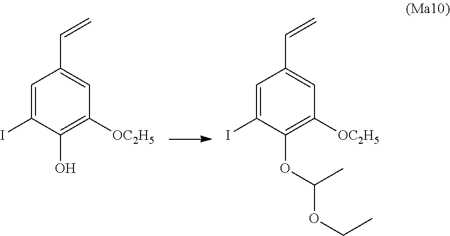 [SMILES: C=Cc1cc(I)c(O)c(OCC)c1 ; C=Cc1cc(I)c(OC(C)OCC)c(OCC)c1]

### (Synthetic Example Aa11) Synthesis of Compound Aa11 Represented by Formula (Ma11)

In Synthetic Example A5, the reaction was carried out in the same manner as Synthetic Example Aa5, except that 4-hydroxy-3-iodo-5-methoxystyrene (compound Mal) was changed to ³-ethoxy-4-hydroxy-5-iodostyrene, thereby obtaining 3.6 g of a compound represented by the formula (Ma11) as the target substance, hereinafter, also referred to as the “compound Aa11”).

As a result of the analysis by liquid chromatography-mass spectrometry (LC-MS), the molecular weight was found to be 374.

The following peaks were found by carrying out 1H-NMR measurement under the above measurement conditions, and the compound was confirmed to have the chemical structure of the compound represented by the formula (Ma11).
δ (ppm) (d₆-DMSO): 7.7 (2H, Ph), 6.7 (1H, —CH═), 5.8 (1H, proton of tetrahydropyranyl group ═CH—), 5.7 (1H, =CH2), 5.3 (1H, =CH2), 4.1 (2H, —CH2—), 1.6-3.7 (8H, proton of tetrahydropyranyl group-CH2—), 1.4 (3H, —CH3)

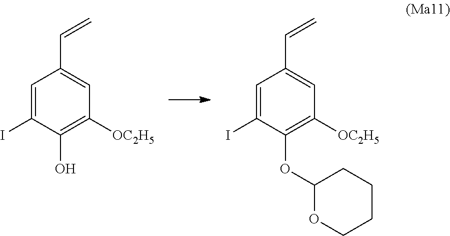 [SMILES: C=Cc1cc(I)c(O)c(OCC)c1 ; C=Cc1cc(I)c(OC2CCCCO2)c(OCC)c1]

### (Synthetic Example Aa12) Synthesis of Compound Aa12 Represented by Formula (Ma12)

In Synthetic Example Aa6, the reaction was carried out in the same manner as Example Aa6, except that 4-hydroxy-3-iodo-5-methoxystyrene (compound Mal) was changed to ³-ethoxy-4-hydroxy-5-iodostyrene, thereby obtaining 3.8 g of a compound represented by the formula (Ma12) as the target substance, hereinafter, also referred to as the “compound Aa12”).

As a result of the analysis by liquid chromatography-mass spectrometry (LC-MS), the molecular weight was found to be 404.

The following peaks were found by carrying out ¹H-NMR measurement under the above measurement conditions, and the compound was confirmed to have the chemical structure of the compound represented by the formula (Ma12).
δ (ppm) (d₆-DMSO): 7.7 (2H, Ph), 6.7 (1H, —CH═), 5.7 (1H, =CH2), 5.3 (1H, =CH2), 5.0 (2H, —CH2—), 4.1 (2H, —CH2—), 1.4 (9H, —C—(CH3) 3), 1.3 (3H, —CH3)

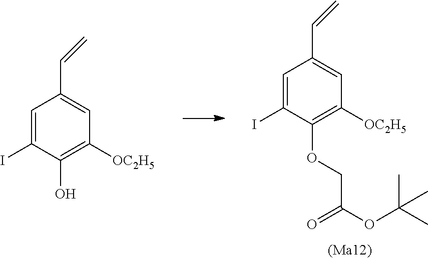

### (Synthetic Example Aa13) Synthesis of Compound Aa13 Represented by Formula (Ma13)

In Synthetic Example Aa7, the reaction was carried out in the same manner as Synthetic Example Aa7, except that 4-hydroxy-3-iodo-5-methoxystyrene (compound Mal) was changed to ³-ethoxy-4-hydroxy-5-iodostyrene, thereby obtaining 4.1 g of a compound represented by the formula (Ma13) as the target substance, hereinafter, also referred to as the “compound Aa13”).

As a result of the analysis by liquid chromatography-mass spectrometry (LC-MS), the molecular weight was found to be 496.

The following peaks were found by carrying out 1H-NMR measurement under the above measurement conditions, and the compound was confirmed to have the chemical structure of the compound represented by the formula (Ma13).
δ (ppm) (d₆-DMSO): 7.7 (2H, Ph), 6.7 (1H, —CH═), 5.7 (1H, =CH2), 5.3 (1H, =CH2), 5.0 (2H, —CH2—), 4.1 (2H, —CH2—), 0.8-2.4 (17H, protons of 2-methyl-2-adamantyl group+3H, —CH3)

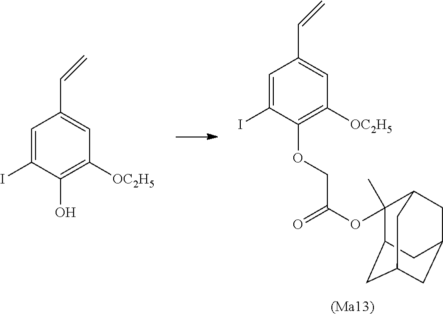

### (Synthetic Example Aa14) Synthesis of Compound Aa14 Represented by Formula (Ma14)

In Synthetic Example Aa8, the reaction was carried out in the same manner as Example Aa8, except that 4-hydroxy-3-iodo-5-methoxystyrene (compound Mal) was changed to ³-ethoxy-4-hydroxy-5-iodostyrene, thereby obtaining 3.5 g of a compound represented by the formula (Ma14) as the target substance, hereinafter, also referred to as the “compound Aa14”).

As a result of the analysis by liquid chromatography-mass spectrometry (LC-MS), the molecular weight was found to be 346.

The following peaks were found by carrying out 1H-NMR measurement under the above measurement conditions, and the compound was confirmed to have the chemical structure of the compound represented by the formula (Ma14).
δ (ppm) (d₆-DMSO): 7.7 (2H, Ph), 6.7 (1H, —CH═), 5.7 (1H, =CH2), 5.3 (1H, =CH2), 4.1 (2H, —CH2—), 1.4 (9H, —C—(CH3) 3), 1.3 (3H, —CH3)

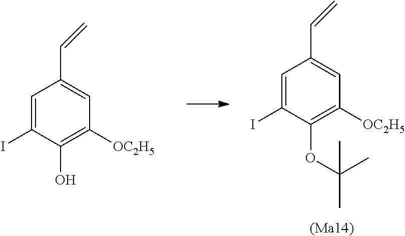

### (Synthetic Example BP5) Synthesis of Compound BP5 Represented by Formula (BP5)

The compound BP5 (trans-isomer) represented by the formula (BP5) was synthesized by the method described below.

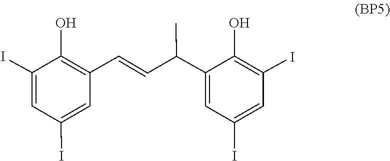 [SMILES: CC(/C=C/c1cc(I)cc(I)c1O)c1cc(I)cc(I)c1O]

The reactor was charged with 15.6 g of 1-(2-hydroxy-3,5-diiodophenyl)ethanol, 0.15 g of methanesulfonic acid, 0.04 g of 4-hydroxy-2,2,6,6-tetramethylpiperidine 1-oxyl free radical, and 60 mL of DMSO (dimethylsulfoxide), and stirring was initiated. Subsequently, reduced pressure conditions were regulated to reflux at 120° C. using a Dienstark and a condenser, and blowing of air into the reaction solution at a flow rate of 1 mL/minute was initiated. The moisture recovered in the Dienstark was arbitrarily discharged to the outside of the system. Subsequently, the reactor was immersed in a water bath at 90° C., and stirring was continued over 30 hours. Subsequently, the reactor was immersed in a water bath at 25° C. to cool the reaction solution. Subsequently, the reaction solution was gradually added to 500 g of an aqueous sodium hydrogen sulfite solution with a mass % concentration of 0.1 with vigorous stirring and mixed. Subsequently, the precipitate was filtered off with a suction filter, compressed, and washed with 200 mL of an aqueous methanol solution with a volumes concentration of 33.3. After only main components (trans-isomer) were isolated from the obtained precipitate by column purification, the solvent was distilled off by evaporation, and the obtained solid was dried in vacuo at 40° C. to obtain 7.1 g of a white solid. The yield was 23%.

As a result of the analysis by liquid chromatography-mass spectrometry (LC-MS), the molecular weight was found to be 743.9, and the white solid was confirmed to be the compound BP5 represented by the formula (BP5).

The following peaks were found by carrying out 1H-NMR measurement under the above measurement conditions, and the compound was confirmed to have the chemical structure of the compound BP5.
δ (ppm) (d₆-DMSO): 10.2 (1H, OH), 9.6 (1H, OH), 7.8 (2H, Ph), 7.7 (1H, Ph), 7.5 (1H, Ph), 3.6 (1H, —CH—), 1.3 (3H, —CH3), 6.5-6.7 (2H, —CH═CH—)

### (Synthetic Example BP6) Synthesis of Compound BP6 Represented by Formula (BP6)

The compound BP6 (trans-isomer) represented by the formula (BP6) was synthesized by the method described below.

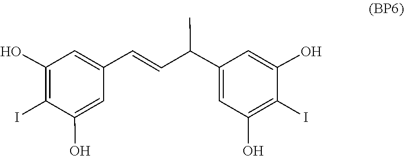 [SMILES: CC(/C=C/c1cc(O)c(I)c(O)c1)c1cc(O)c(I)c(O)c1]

The reactor was charged with 11.2 g of 1-(3,5-dihydroxy-4-iodophenyl)ethanol, 0.15 g of methanesulfonic acid, 0.04 g of 4-hydroxy-2,2,6,6-tetramethylpiperidine 1-oxyl free radical, and 60 mL of DMSO (dimethylsulfoxide), and stirring was initiated. Subsequently, reduced pressure conditions were regulated to reflux at 120° C. using a Dienstark and a condenser, and blowing of air into the reaction solution at a flow rate of 1 mL/minute was initiated. The moisture recovered in the Dienstark was arbitrarily discharged to the outside of the system. Subsequently, the reactor was immersed in a water bath at 90° C., and stirring was continued over 30 hours. Subsequently, the reactor was immersed in a water bath at 25° C. to cool the reaction solution.

Subsequently, the reaction solution was gradually added to 500 g of an aqueous sodium hydrogen sulfite solution with a mass % concentration of 0.1 with vigorous stirring and mixed. Subsequently, the precipitate was filtered off with a suction filter, compressed, and washed with 200 mL of an aqueous methanol solution with a volume % concentration of 33.3. After only main components (trans-isomer) were isolated from the obtained precipitate by column purification, the solvent was distilled off by evaporation, and the obtained solid was dried in vacuo at 40° C. to obtain 5.0 g of a white solid. The yield was 23%.

As a result of the analysis by liquid chromatography-mass spectrometry (LC-MS), the molecular weight was found to be 524.1, and the white solid was confirmed to be the compound BP6 represented by the formula (BP6).

The following peaks were found by carrying out 1H-NMR measurement under the above measurement conditions, and the compound was confirmed to have the chemical structure of the compound BP6.
δ (ppm) (d₆-DMSO): 10.8 (4H, OH), 6.7 (1H, —CH═CH—), 6.4 (1H, —CH═CH—), 6.3 (2H, Ph), 6.0 (2H, Ph), 3.6 (1H, —CH—), 1.3 (3H, —CH3)

### (Synthetic Example Aa15) Synthesis of Compound Aa15 Represented by Formula (Ma15)

### (Step 1) Synthesis of 1-(4-hydroxy-3,5-diiodophenyl)ethanol

A reactor was charged with 120 g of 1-(4-hydroxyphenyl)ethanol, 177 g of iodine, 1400 mL of methanol, and 200 mL of pure water, the reactor was immersed in an ice bath, and stirring was initiated. Subsequently, 87 g of an aqueous iodic acid solution with a mass % concentration of 70 was added dropwise thereto for 30 minutes. Subsequently, the reactor was immersed in a water bath at 25° C., and stirring was continued over 3.5 hours. Subsequently, 18 mL of an aqueous sodium hydrogen sulfite solution with a mass % concentration of 35 was added to quench the reaction. Subsequently, the reaction solution was gradually added to 3.5 L of pure water with vigorous stirring and mixed. Subsequently, the precipitate was filtered off with a suction filter, compressed, and washed with an aqueous methanol solution with a volume % concentration of 33.3. Subsequently, the precipitate was dried in vacuo at 40° C. to obtain 310 g of a mixture of 1-(4-hydroxy-3,5-diiodophenyl)ethanol and 2,6-diiodo-4-(1-methoxyethyl) phenol. As a result of the HPLC analysis using a UV detector at a measurement wavelength of 254 nm, the ratio between 1-(4-hydroxy-3,5-diiodophenyl)ethanol and 2,6-diiodo-4-(1-methoxyethyl) phenol was 50.88:47.15.

As a result of the analysis by liquid chromatography-mass spectrometry (LC-MS), the molecular weights were found to be 390 and 404, and the substance was confirmed to be a mixture of 1-(4-hydroxy-3,5-diiodophenyl)ethanol and 2,6-diiodo-4-(1-methoxyethyl) phenol.

The following peaks were found by carrying out 1H-NMR measurement under the above measurement conditions, and the compound was confirmed to have the chemical structure.
δ (ppm) (d₆-DMSO): 9.4 (1H, —OH), 7.7 (2H, Ph), 5.2 (0.5H, —CH—OH), 4.6-4.3 (1H, —CH—OH), 3.0 (1.5H, —O—CH3), 1.3 (3H, —CH3)

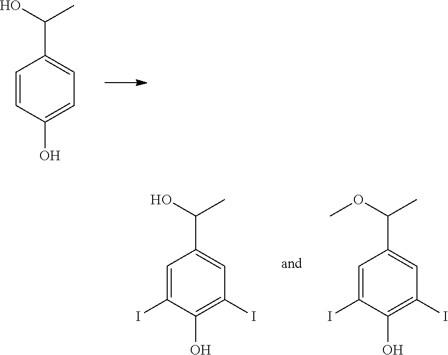

### (Step 2) Synthesis of 4-hydroxy-3,5-diiodostyrene

The reactor equipped with a refulx tube and Dienstark was charged with 200 g of a mixture of 1-(4-hydroxy-3,5-diiodophenyl)ethanol and 2,6-dijodo-4-(1-methoxyethyl) phenol obtained in the above (step 1), 29 mL of concentrated sulfuric acid, 0.2 g of 4-hydroxy-2,2,6,6-tetramethylpiperidine 1-oxyl free radical, 0.2 g of 4-methoxyphenol, 2.5 L of dimethylsulfoxide, and 0.5 L of toluene, and stirring was initiated. Subsequently, the pressure in the reactor was reduced to 30 hPa, and blowing of air into the reaction solution at a flow rate of 1 mL/minute was initiated. Subsequently, the reactor was immersed in a water bath at 90° C., and stirring was continued over 3 hours. Subsequently, the reactor was immersed in a water bath at 25° C. to cool the reaction solution. Subsequently, the reaction solution was gradually added to 30 g of an aqueous sodium hydrogen sulfite solution with a mass % concentration of 0.1 with vigorous stirring and mixed. Subsequently, the precipitate was filtered off with a suction filter, compressed, and washed with 15 mL of an aqueous methanol solution with a volumes concentration of 33.3. Subsequently, the precipitate was dried in vacuo at 40° C. to obtain 181 g of 4-hydroxy-3,5-diiodostyrene. The yield was 94.9%.

As a result of the analysis by liquid chromatography-mass spectrometry (LC-MS), the molecular weight was found to be 372, and the substance was confirmed to be the compound Aa15 represented by the formula (Ma15) (4-hydroxy-3,5-diiodostyrene).

The following peaks were found by carrying out 1H-NMR measurement under the above measurement conditions, and the compound was confirmed to have the chemical structure.
δ (ppm) (d₆-DMSO): 9.6 (1H, OH), 7.9 (2H, Ph), 6.6 (1H, —CH2—), 5.7 (1H, =CH2), 5.1 (1H, =CH2)

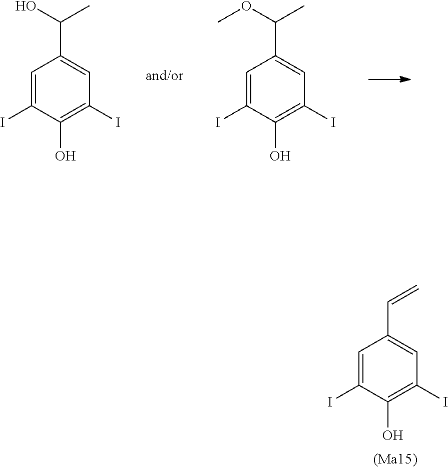

### (Synthetic Example Aa16) Synthesis of compound Aa16 represented by formula (Ma16) (synthesis of 4-acetoxy-3,5-diiodostyrene)

Using a 100 mL glass flask as a reaction vessel, 16.7 g (45 mmol) of 4-hydroxy-3,5-diiodostyrene obtained in (Synthetic Example Aa15) was dissolved by using dimethylsulfoxide as a solvent, 2 eq. of acetic anhydride and 1 eq. of sulfuric acid were added thereto, and then the mixture was warmed to 80° C. and stirred for 3 hours. Thereafter, the stirred solution was cooled, and the precipitate was filtered off, washed, and dried to obtain 9.0 g of a white solid. As a result of the analysis of the white solid sample by liquid chromatography-mass spectrometry (LC-MS), the molecular weight was found to be 414, and the white solid sample was confirmed to be the compound Aa16 represented by the formula (Ma16) (4-acetoxy-3,5-diiodostyrene).

The following peaks were found by carrying out 1H-NMR measurement under the above measurement conditions, and the compound was confirmed to have the chemical structure.
δ (ppm) (d₆-DMSO): 7.9 (2H, Ph), 6.6 (1H, —CH2-), 5.7 (1H, =CH2), 5.1 (1H, =CH2), 2.3 (3H, —CH3)

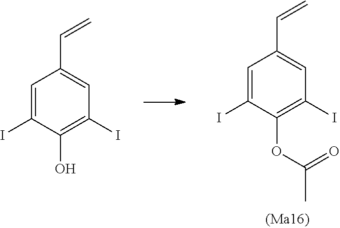

### (Synthetic Example Aa17) Synthesis of compound Aa17 represented by formula (Ma17) (4-hydroxy-3,5-diiodostyrene)

The (step 1) and (step 2) were conducted in the same manner as the above Synthetic Example Aa15, except for using 1-(2-hydroxyphenyl)ethanol instead of 1-(4-hydroxyphenyl)ethanol, thereby obtaining the compound Aa17 represented by the formula (Ma17) (2-hydroxy-3,5-diiodostyrene).

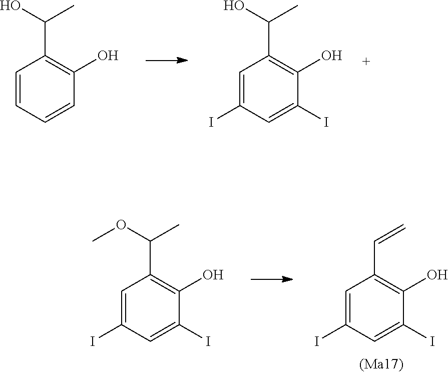

### (Synthetic Example Aa18) Synthesis of compound Aa18 represented by formula (Ma18) (4-acetoxy-3,5-diiodostyrene)

The compound Aa18 represented by the formula (Ma18) (2-acetoxy-3,5-diiodostyrene) was obtained in the same manner as the above Synthetic Example Aa15 except for using 2-hydroxy-3,5-diiodostyrene instead of 4-hydroxy-3,5-diiodostyrene.

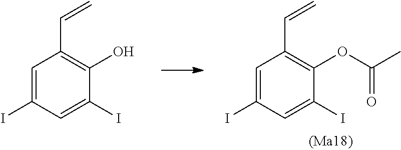

### (Synthetic Example Aa19) Synthesis of compound Aa19 represented by formula (Ma19) (3,5-dihydroxy-4-iodostyrene)

### (Synthetic Example Aa19-1) Synthesis of 3′,5′-dihydroxy-4′-iodoacetophenone

A 500 mL glass flask as a reaction vessel was charged with 8.00 g (52.6 mmol) of 3′,5′-dihydroxyacetophenone, 146 mL of methanol, and 12.9 mL of ion exchanged water, and stirring was initiated under the conditions of room temperature at 20° C. Subsequently, blowing of nitrogen at a flow rate of 10 mL/minute was initiated. After 5.34 g (21.0 mmol) of iodine was added, 6.12 g (10.5 mmol) of an aqueous iodic acid solution with a mass % concentration of 30 was added dropwise, while the temperature was further regulated to 30° C. or less. After stirring for 1 hour, 3 g of an aqueous sodium hydrogen sulfite solution with a mass % concentration of 5 was added, and the solution was concentrated and added dropwise to 100 g of water. The obtained precipitate was recovered by suction filtration, and then dried in vacuo at 40° C. to obtain 12.6 g of a white solid. The yield was 86%.

As a result of the analysis by liquid chromatography-mass spectrometry (LC-MS), the molecular weight was found to be 278.

The following peaks were found by carrying out 1H-NMR measurement under the above measurement conditions, and the compound was confirmed to have the chemical structure of 3′,5′-dihydroxy-4′-iodoacetophenone.
δ (ppm) (d₆-DMSO): 10.5 (2H, OH), 6.5 (2H, ArH), 2.5 (3H, —CH3)

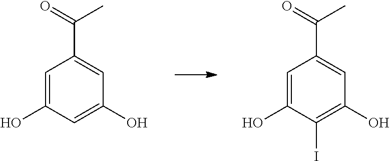

### (Synthetic Example Aa19-2) Synthesis of 1-(3,5-hydroxy-4-iodophenyl)ethanol

A 500 mL glass flask as a reaction vessel was charged with 12.0 g (43.2 mmol) of 3′,5′-dihydroxy-4′-iodoacetophenone of Synthetic Example Aa19-1 and 129 mL of methanol, and stirring was initiated at 0° C. Subsequently, blowing of nitrogen at a flow rate of 10 mL/minute was initiated. While the temperature was regulated to 10° C. or less, 1.63 g (43.2 mmol) of sodium borohydride was added portionwise, and the mixture was stirred for 1 hour. After 2 M hydrochloric acid was added until the reaction solution turns acidic, and 50 g of ion exchanged water was added. Subsequently, the pressure in the reactor was reduced to 50 hPa, immersed in a water bath at 20° C. to concentrate the reaction solution. 30 g of brine and 100 g of ethyl acetate were added to the concentrate, and the mixture was stirred. The organic layer was washed with ion exchanged water and brine, and concentrated to dryness, thereby recovering a crude. The crude was dried in vacuo at 40° C. to obtain 9.0 g of a white solid. The yield was 75%.

As a result of the analysis by liquid chromatography-mass spectrometry (LC-MS), the molecular weight was found to be 280.

The following peaks were found by carrying out 1H-NMR measurement under the above measurement conditions, and the compound was confirmed to have the chemical structure of 1-(3,5-hydroxy-4-iodophenyl)ethanol.
δ (ppm) (d₆-DMSO): 11.6 (2H, ArOH), 6.2 (2H, ArH), 5.2 (1H, —CHOH—), 5.0 (1H, —CHOH—), 1.5 (3H, —CH3)

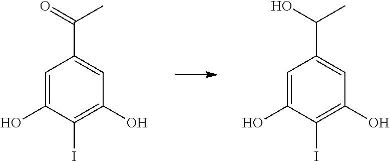

### (Synthetic Example Aa19-3) Synthesis of compound Aa19 represented by formula (Ma19) (synthesis of 3,5-dihydroxy-4-iodostyrene)

A 300 mL glass flask as a reaction vessel was charged with 8.5 g of 1-(3,5-hydroxy-4-iodophenyl)ethanol of Synthetic Example Aa19-2, 0.40 g of concentrated sulfuric acid, 0.015 g of 4-hydroxy-2,2,6,6-tetramethylpiperidine 1-oxyl free radical, and 76 mL of dimethylsulfoxide, and stirring was initiated. Subsequently, the pressure in the reactor was reduced to 30 hPa, and blowing of air into the reaction solution at a flow rate of 9 mL/minute was initiated. Subsequently, the reactor was immersed in a water bath at 90° C., and stirring was continued over 5 hours. Subsequently, the reactor was immersed in a water bath at 25° C. to cool the reaction solution. Subsequently, the reaction solution was gradually added to 153 g of an aqueous sodium hydrogen sulfite solution with a mass % concentration of 0.1 with vigorous stirring and mixed. Subsequently, the precipitate was filtered off with a suction filter, compressed, and washed with 76 mL of an aqueous methanol solution with a volume % concentration of 33.3. Subsequently, the precipitate was dried in vacuo at 25° C. to obtain 7.6 g of a white solid. The yield was 96%.

As a result of the analysis by liquid chromatography-mass spectrometry (LC-MS), the molecular weight was found to be 262, and the white solid was confirmed to be the compound Aa19 represented by the formula (Ma19) (3,5-dihydroxy-4-iodostyrene).

The following peaks were found by carrying out 1H-NMR measurement under the above measurement conditions, and the compound was confirmed to have the following chemical structure.
δ (ppm) (d₆-DMSO): 11.6 (2H, OH), 6.7 (1H, —CH═), 6.0 (2H, ArH), 5.7 (1H, =CH2), 5.3 (1H, =CH2)

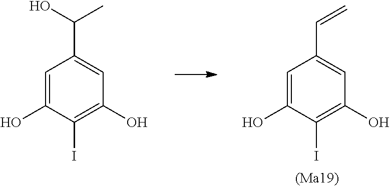

### (Synthetic Example Aa19-4) Synthesis of Compound Aa20 Represented by Formula (Ma20)

Using a 300 mL glass flask as a reaction vessel, 7.0 g (0.027 mol) of 3,5-dihydroxy-4-iodostyrene obtained in Synthetic Example Aa19-3 was dissolved by using 74 mL of chloroform as a solvent, 8.2 g (0.080 mol) of triethylamine and 0.98 g (0.0080 mol) of 4-dimethylaminopyridine were added thereto, and then the mixture was immersed in ice water and stirred while cooling to 0° C. 8.2 g (0.080 mol) of acetic anhydride was added thereto for 20 minutes, the mixture was stirred for 2 hours under ice cooling, and 64 g of 0.2 M hydrochloric acid was added dropwise for 20 minutes. 5.3 mL of chloroform was added thereto to separate the mixture, and the organic layer was washed with 5% sodium bicarbonate water and water. The solution was concentrated, an excess of heptane was then added thereto, the solution was cooled, and the obtained precipitate was recovered by suction filtration and dried in vacuo at 25° C. to obtain 8.3 g of a white solid. The yield was 90%.

As a result of the analysis by liquid chromatography-mass spectrometry (LC-MS), the molecular weight was found to be 346, and the white solid was confirmed to be the compound Aa20 represented by the formula (Ma20) (3,5-diacetoxy-4-iodostyrene).

The following peaks were found by carrying out 1H-NMR measurement under the above measurement conditions, and the compound was confirmed to have the following chemical structure.
δ (ppm) (d₆-DMSO): 6.8 (2H, ArH), 6.7 (1H, —CH═), 5.8 (1H, =CH2), 5.3 (1H, =CH2), 2.3 (6H, —CH3)

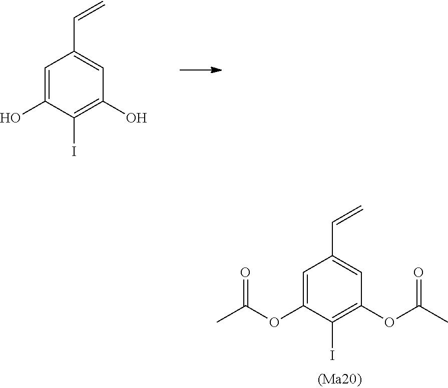 [SMILES: C=Cc1cc(O)c(I)c(O)c1 ; C=Cc1cc(OC(C)=O)c(I)c(OC(C)=O)c1]

### (Synthetic Example Aa19-5) Synthesis of 3′,5′-diacetoxy-4′-iodoacetophenone

Using a 500 mL glass flask as a reaction vessel, 12.0 g (0.043 mol) of 3′,5′-dihydroxy-4′-iodoacetophenone obtained in Synthetic Example Aa19-1 was dissolved by using 156 g of ethyl acetate as a solvent, 13 g (0.13 mol) of triethylamine and 1.6 g (0.013 mol) of 4-dimethylaminopyridine were added thereto, and then the mixture was immersed in ice water and stirred while cooling to 0° C. 13 g (0.13 mol) of acetic anhydride was added thereto for 20 minutes, the mixture was stirred for 2 hours under ice cooling, and 206 g of 0.2 M hydrochloric acid was added dropwise for 20 minutes. Hexane was added, the layer separation was confirmed, and then the organic layer was washed with 5% sodium bicarbonate water and water. The solution was concentrated, an excess of a 2-propanol/water mixture was then added thereto, the solution was cooled, and the obtained precipitate was recovered by suction filtration and dried in vacuo at 25° C. to obtain 14 g of a white solid. The yield was 92%.

As a result of the analysis by liquid chromatography-mass spectrometry (LC-MS), the molecular weight was found to be 362, and the white solid was confirmed to be 3′,5′-diacetoxy-4′-iodoacetophenone.

The following peaks were found by carrying out 1H-NMR measurement under the above measurement conditions, and the compound was confirmed to have the following chemical structure.
δ (ppm) (d₆-DMSO): 7.3 (2H, ArH), 2.5 (3H, —CH3), 2.3 (6H, —CH3)

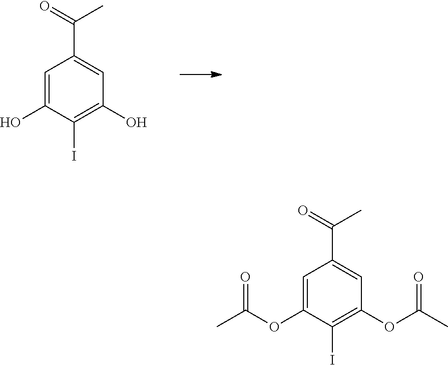 [SMILES: CC(=O)c1cc(O)c(I)c(O)c1 ; CC(=O)Oc1cc(C(C)=O)cc(OC(C)=O)c1I]

### (Synthetic Example Aa19-6) Synthesis of 1-(3,5-diacetoxy-4-iodophenyl)ethanol

A 500 mL glass flask as a reaction vessel was charged with 13.5 g (37.2 mmol) of 3′,5′-diacetoxy-4′-iodoacetophenone of Synthetic Example Aa19-5 and 111 mL of methanol, and stirring was initiated at 0° C. Subsequently, blowing of nitrogen at a flow rate of 10 mL/minute was initiated. While the temperature was regulated to 10° C. or less, 1.41 g (37.2 mmol) of sodium borohydride was added portionwise, and the mixture was stirred for 1 hour. The reaction solution was added dropwise to 100 g of 0.5 M hydrochloric acid.

Subsequently, the pressure in the reactor was reduced to 50 hPa, immersed in a water bath at 20° C. to concentrate the reaction solution. 30 g of brine and 100 g of ethyl acetate were added to the concentrate, and the mixture was stirred. The organic layer was washed with ion exchanged water and brine, and concentrated to dryness, thereby recovering a crude. The crude was dried in vacuo at 40° C. to obtain 11.9 g of a white solid. The yield was 88%.

As a result of the analysis by liquid chromatography-mass spectrometry (LC-MS), the molecular weight was found to be 364.

The following peaks were found by carrying out 1H-NMR measurement under the above measurement conditions, and the compound was confirmed to have the chemical structure of 1-(3,5-diacetoxy-4-iodophenyl)ethanol.
δ (ppm) (d₆-DMSO): 6.9 (2H, ArH), 5.2 (1H, —CHOH—), 5.0 (1H, —CHOH—), 2.3 (6H, —CH3), 1.5 (3H, —CH3)

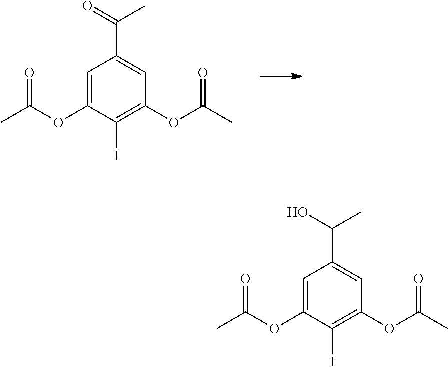 [SMILES: CC(=O)Oc1cc(C(C)=O)cc(OC(C)=O)c1I ; CC(=O)Oc1cc(C(C)O)cc(OC(C)=O)c1I]

### (Synthetic Example Aa19-7) Synthesis of Compound Aa20 Represented by Formula (Ma20) (3,5-Dihydroxy-4-Iodostyrene)

A 300 mL glass flask as a reaction vessel was charged with 11.5 g of 1-(3,5-diacetoxy-4-iodophenyl)ethanol of Synthetic Example Aa19-6, 0.42 g of concentrated sulfuric acid, 0.016 g of 4-hydroxy-2,2,6,6-tetramethylpiperidine 1-oxyl free radical, and 79 mL of dimethylsulfoxide, and stirring was initiated. Subsequently, the pressure in the reactor was reduced to 30 hPa, and blowing of air into the reaction solution at a flow rate of 9 mL/minute was initiated. Subsequently, the reactor was immersed in a water bath at 90° C., and stirring was continued over 5 hours. Subsequently, the reactor was immersed in a water bath at 25° C. to cool the reaction solution. Subsequently, the reaction solution was gradually added to 159 g of an aqueous sodium hydrogen sulfite solution with a mass % concentration of 0.1 with vigorous stirring and mixed. Subsequently, the precipitate was filtered off with a suction filter, compressed, and washed with 79 mL of an aqueous methanol solution with a volumes concentration of 33.3. Subsequently, the precipitate was dried in vacuo at 25° C. to obtain 10.6 g of a white solid. The yield was 97%.

As a result of the analysis by liquid chromatography-mass spectrometry (LC-MS), the molecular weight was found to be 346, and the substance was confirmed to be the compound Aa20 represented by the formula (Ma20) (3,5-dihydroxy-4-iodostyrene).

The following peaks were found by carrying out 1H-NMR measurement under the above measurement conditions, and the compound was confirmed to have the chemical structure.
δ (ppm) (d₆-DMSO): 6.8 (2H, ArH), 6.7 (1H, —CH═), 5.8 (1H, =CH2), 5.3 (1H, =CH2), 2.3 (6H, —CH3)

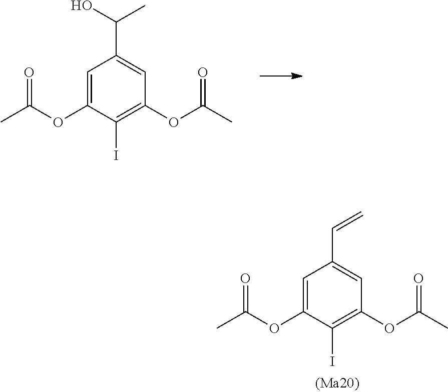 [SMILES: CC(=O)Oc1cc(C(C)O)cc(OC(C)=O)c1I ; C=Cc1cc(OC(C)=O)c(I)c(OC(C)=O)c1]

### (Synthetic Examples Aa20-1 to 10) Synthesis of Compounds Represented by Formula (Ma21) to Formula (Ma30)

The compounds Aa21 to Aa30 represented by the formula (Ma21) to the formula (Ma30) were synthesized according to the following schemes. The raw materials were obtained from the market.

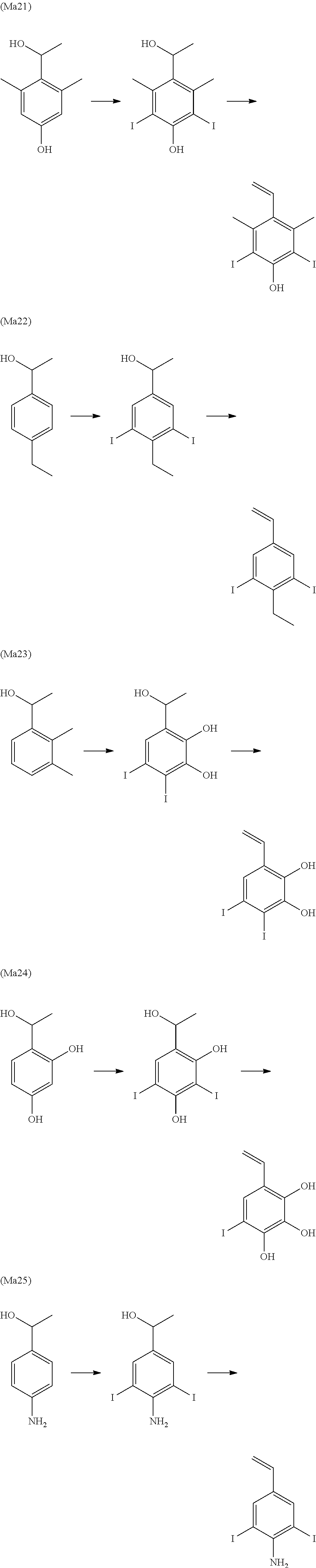

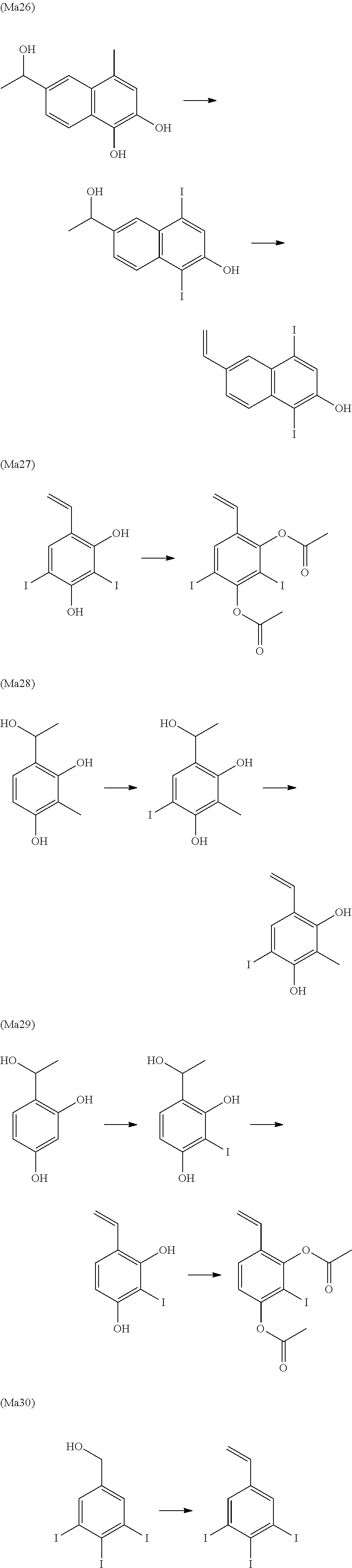

TABLE 1A

| | Structural | Molecular | |
|---|---|---|---|
| Compound | formula | weight | 1H-NMR, σ (ppm) (d6-DMSO) |
| Aa21 | Ma21 | 400 | 9.6 (1H, —OH), 7.1 (1H, —CH═), 5.7 (1H, ═CH2), 5.5 |
| | | | (1H, ═CH2), 2.3 (6H, Ph-CH3) |
| Aa22 | Ma22 | 384 | 7.7 (2H, Ph-H), 6.7 (1H, —CH═), 5.7 (1H, ═CH2), 5.3 |
| | | | (1H, ═CH2), 2.7 (2H, —CH2—), 1.2 (3H, —CH3) |
| Aa23 | Ma23 | 388 | 13.8 (1H, Ph-OH), 9.6 (1H, Ph-OH), 7.4 (1H, —CH═), |
| | | | 6.9 (1H, Ph-H), 5.6-5.7 (2H, ═CH2) |
| Aa24 | Ma24 | 388 | 15.2 (1H, Ph-OH), 9.6 (1H, Ph-OH), 7.4 (1H, —CH═), |
| | | | 7.3 (1H, Ph-H), 5.6-5.7 (2H, ═CH2) |
| Aa25 | Ma25 | 371 | 7.5 (2H, Ph-H), 6.7 (1H, —CH═), 5.8 (1H, ═CH2), |
| | | | 5.2-5.3 (3H, ═CH2, —NH2) |
| Aa26 | Ma26 | 422 | 11.6 (1H, Naph-OH), 7.1-8.2 (4H, Naph-H), 6.7 |
| | | | (1H, —CH═), 5.8 (1H, ═CH2), 5.2 (1H, ═CH2) |
| Aa27 | Ma27 | 472 | 7.7 (1H, Ph-OH), 7.3 (1H, —CH═), 5.6-5.7 (2H, ═CH2), |
| | | | 2.4 (6H, —CH3) |
| Aa28 | Ma28 | 276 | 9.6 (1H, Ph-OH), 7.2-7.4 (2H, Ph-H, —CH═), 5.6-5.8 |
| | | | (3H, Ph-OH, ═CH2) 2.2 (Ph-CH3) |
| Aa29 | Ma29 | 346 | 8.0 (1H, Ph-H) 7.4 (1H, —CH═), 6.8 (1H, Ph-H), |
| | | | 5.6-5.7 (2H, ═CH2), 2.3 (6H, —CH3) |
| Aa30 | Ma30 | 482 | 7.4 (2H, Ph-H), 6.7 (1H, —CH═), 5.2-5.8 (2H, ═CH2) |

### (Synthetic Example B1) Synthesis of Polymer B1 Represented by Formula (MA1)

1.5 g of the compound Al obtained in Synthetic Example A1, 4.0 g of 2-methyl-2-adamantylmethacrylate, 0.9 g of γ-butyrolactone methacrylate, and 1.5 g of hydroxyadamantyl methacrylate were dissolved in 45 mL of tetrahydrofuran, and 0.20 g of azobisisobutyronitrile was added thereto. After the mixture was refluxed for 12 hours, the reaction solution was added dropwise to 2 L of n-heptane. The polymer precipitated was filtered off and dried under reduced-pressure to obtain a white powdery polymer B1 represented by the following formula (MA1). This polymer had a weight average molecular weight (Mw) of 12,000 and a dispersity (Mw/Mn) of 1.90. As a result of the measurement of ¹³C-NMR, the composition ratio (molar ratio) in the following formula (MA1) was a: b: c: d=60:10:15:15. Although the following formula (MA1) is illustrated in a simplified form to show the ratio of respective constitutional units, the order of arrangement of respective constitutional units is random and this polymer is not a block copolymer in which respective constitutional units form an independent block. The molar ratio was determined based on the integral ratio of each of the carbon on the bottom of a benzene ring for the polystyrene monomer (the compound A1) and the carbonyl carbon of an ester bond for methacrylate monomer (2-methyl-2-adamantyl methacrylate, γ-butyrolactone methacrylate, and hydroxyadamantyl methacrylate). The kind of respective monomers, the ratio thereof, and the composition ratio in the polymer obtained in Synthetic Example B1 are shown in Table 1. The kind of respective monomers, the ratio thereof, and the composition ratio in the polymers obtained in Examples described below are also shown in Table 1.

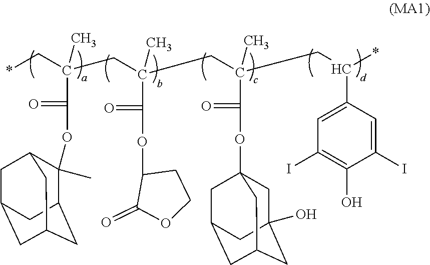

### Synthetic Examples B2 to B42, Comparative Examples B1 to B2

The polymers B2 to B52 and the polymers BR1 to BR2 represented by the formulas (MA1a) to (MA2a), the formulas (MA2) to (MA50), and the formulas (MAR1) to (MAR2) were obtained by the method described in Synthetic Example B1, except that 1.5 g of the compound Al was changed to the kind and the amount shown in Table 1.

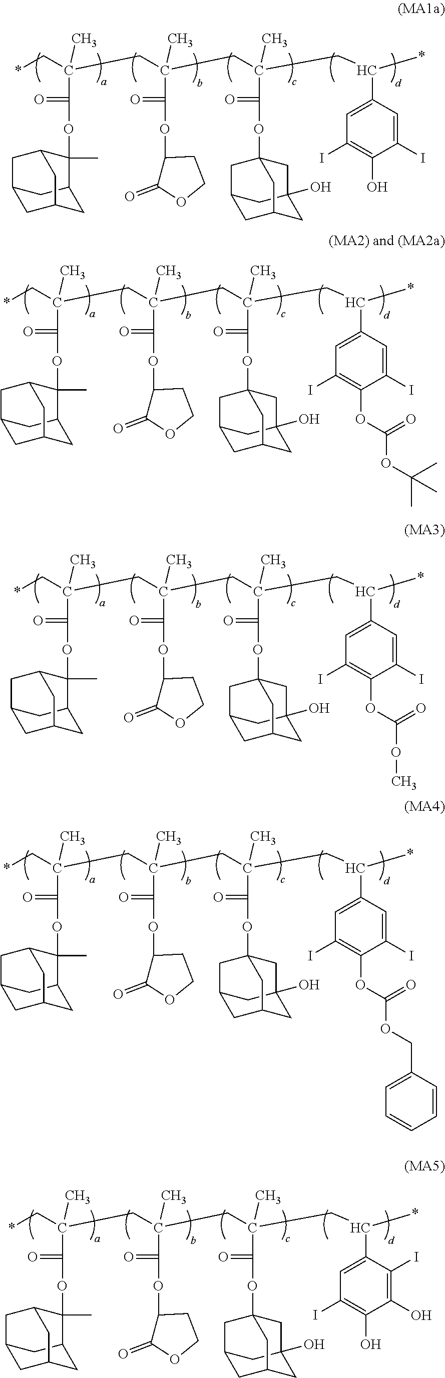

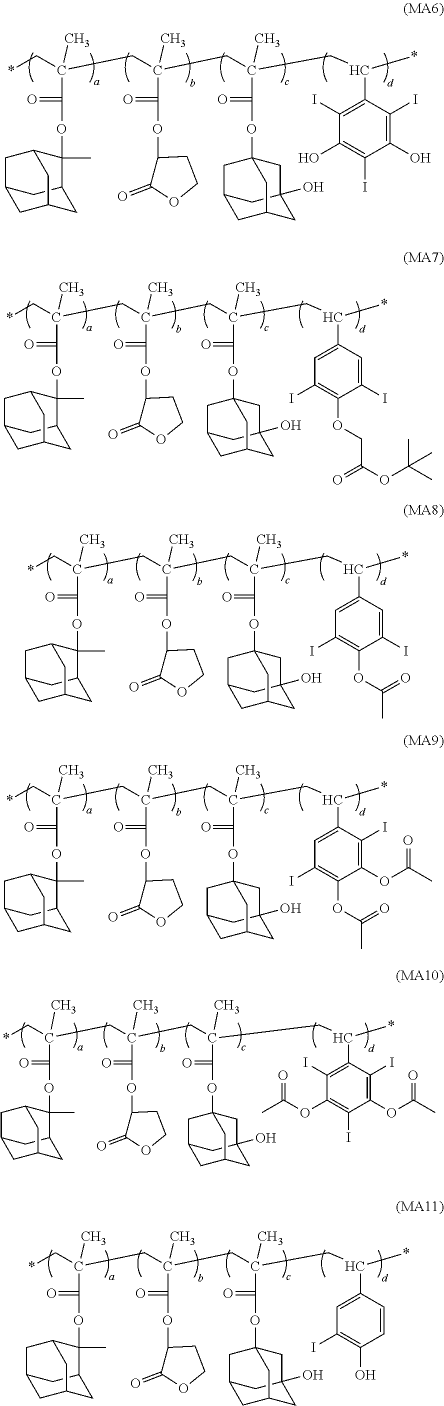

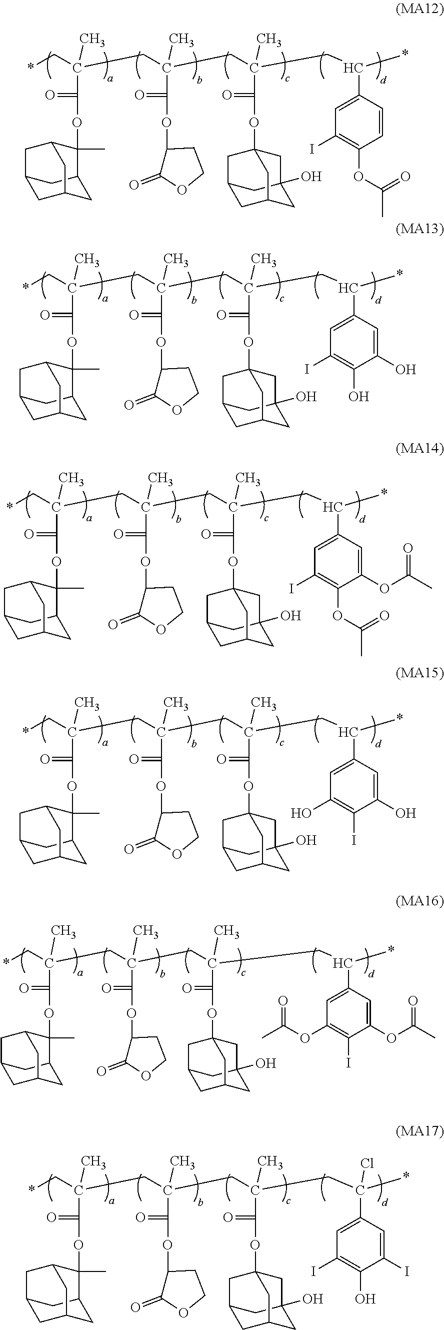

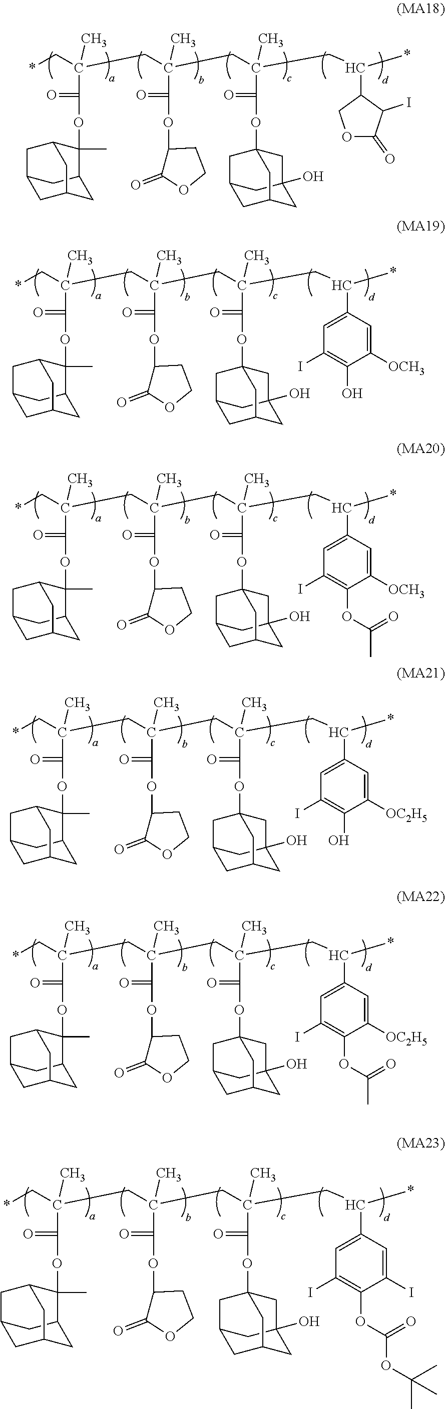

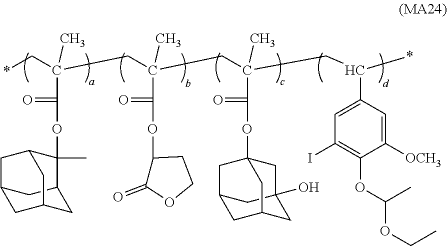

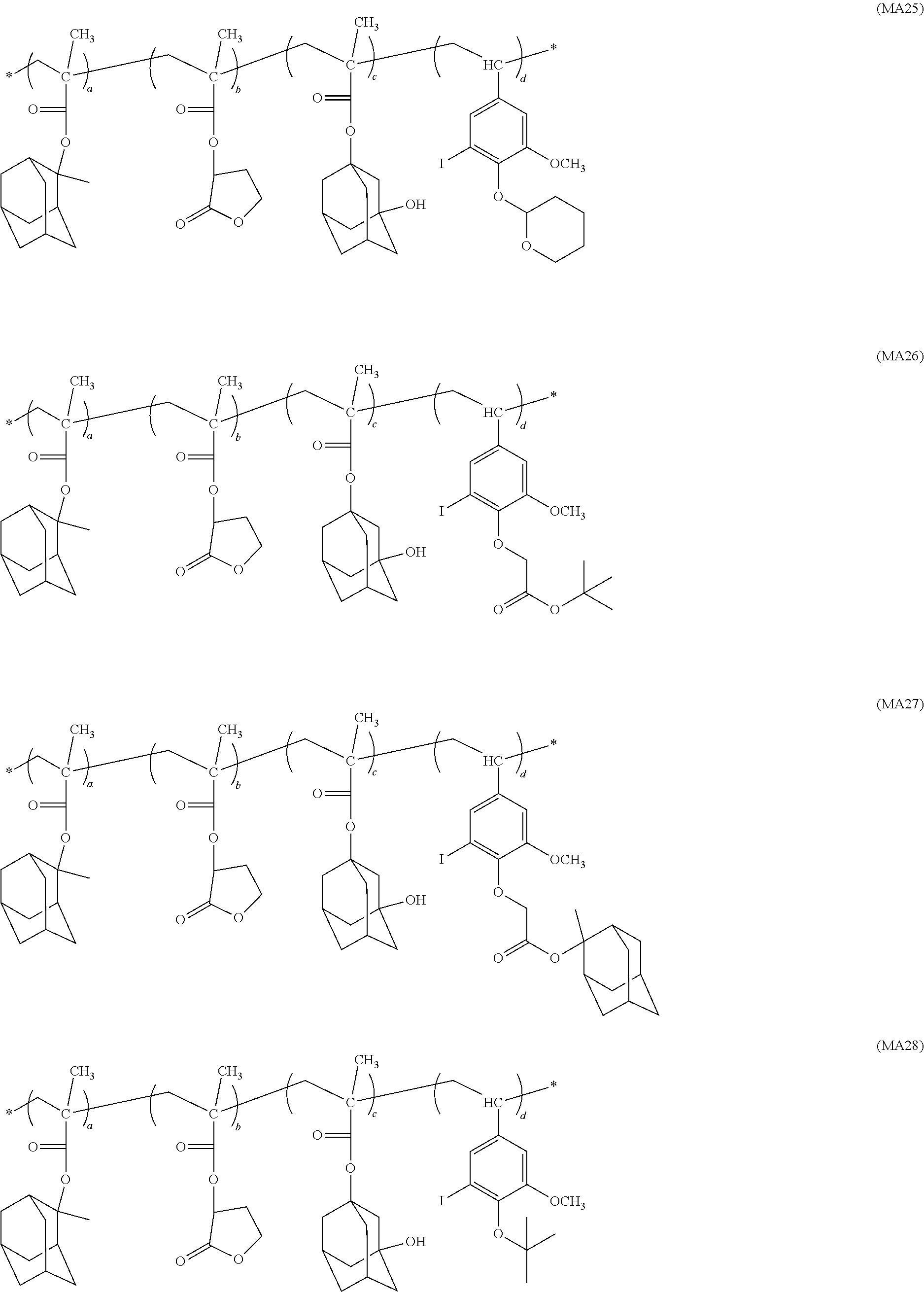

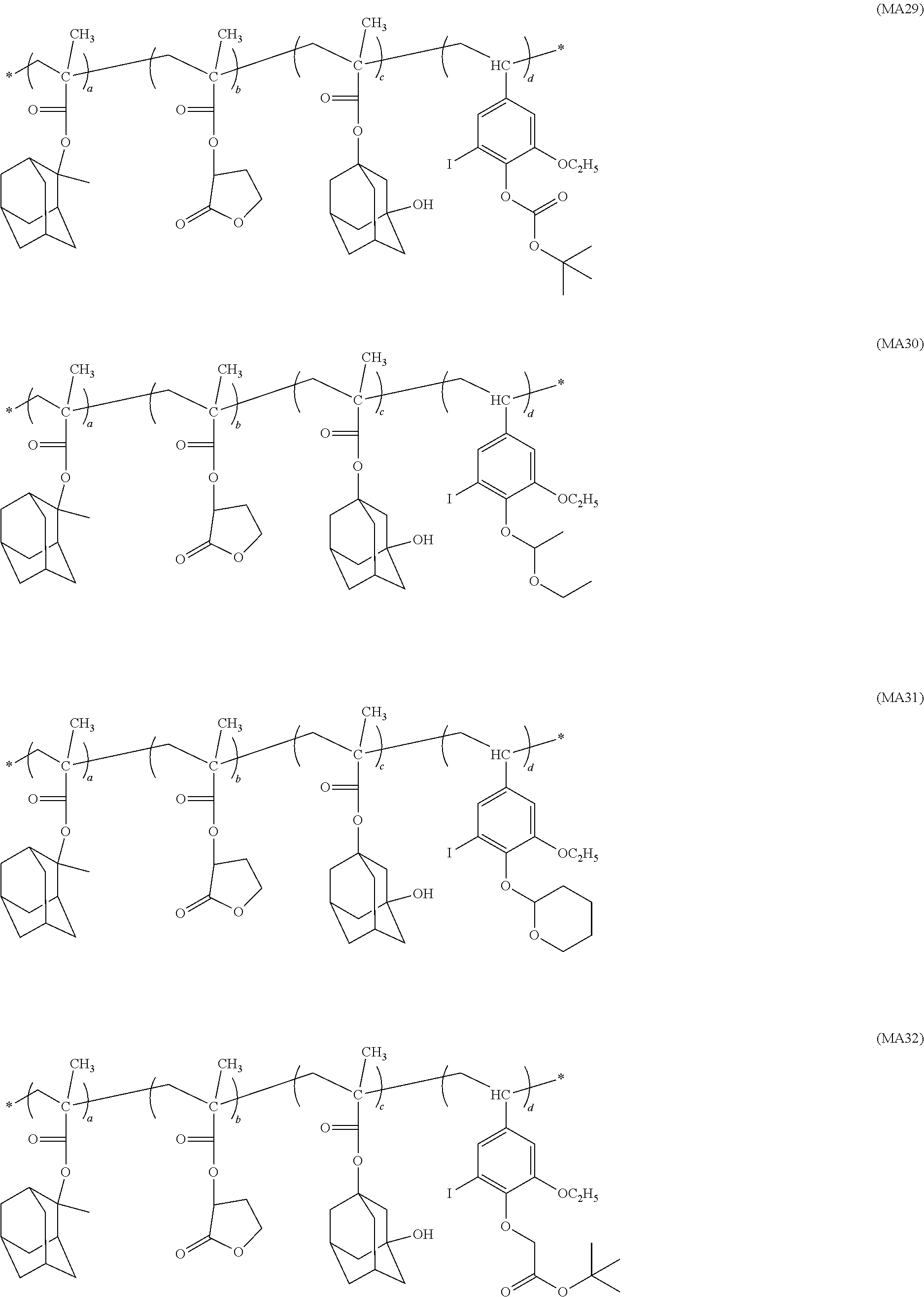

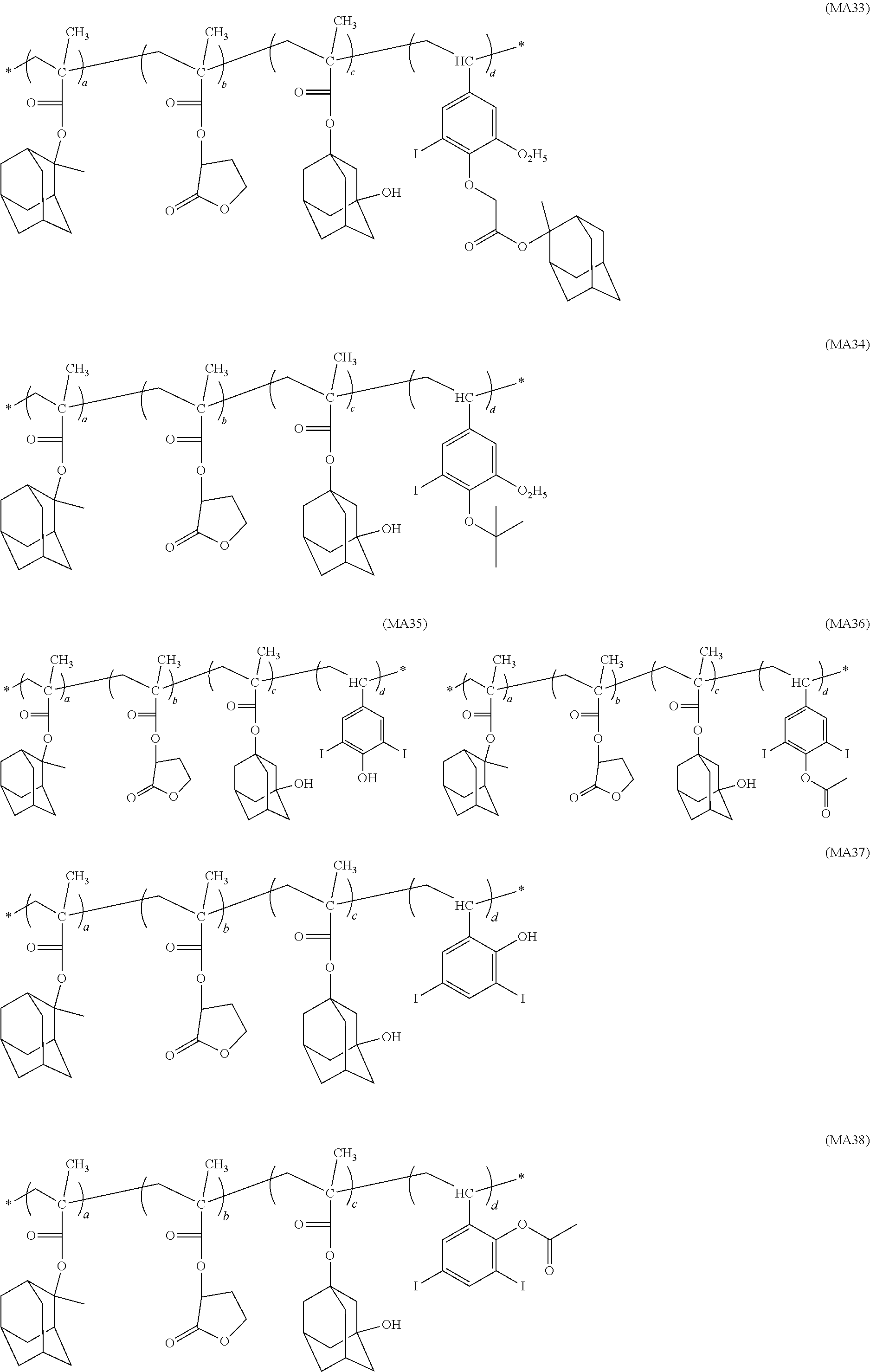

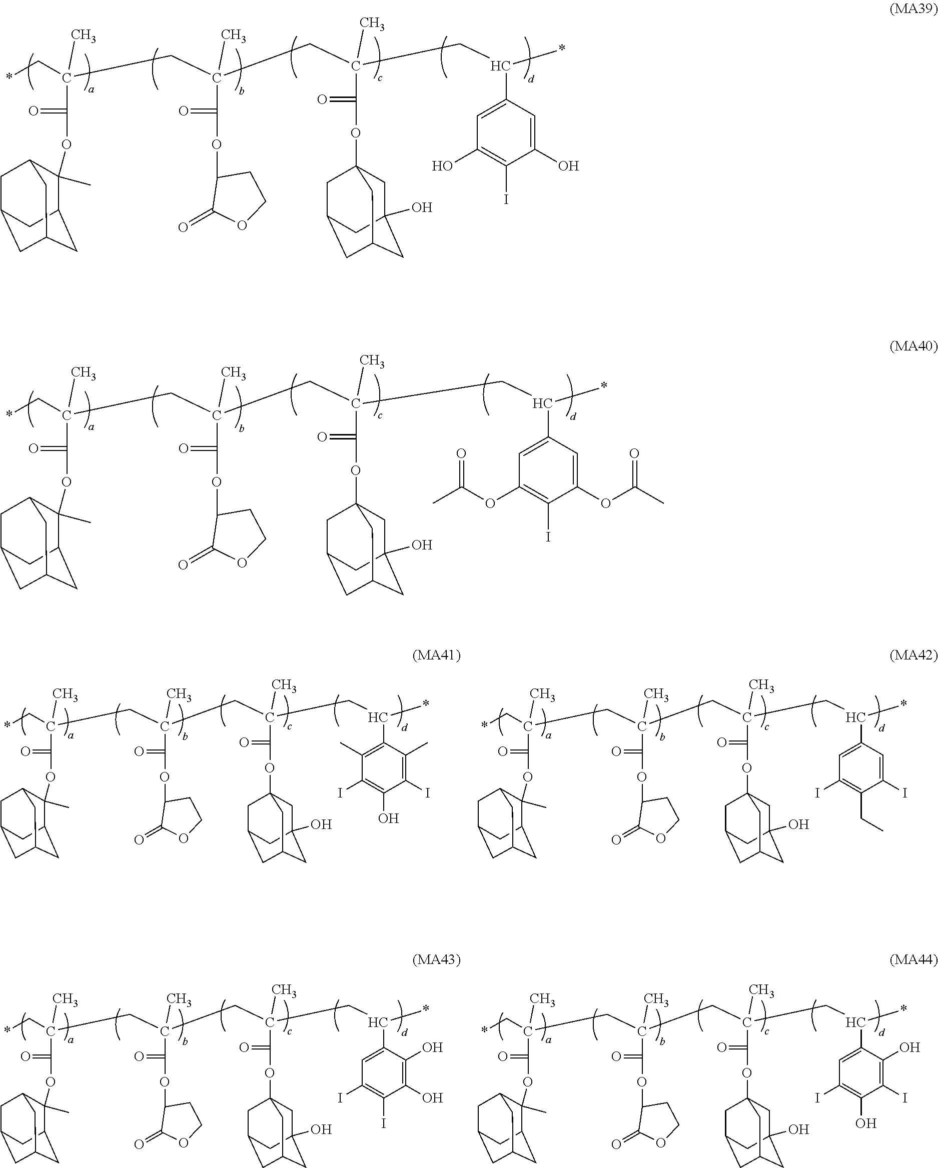

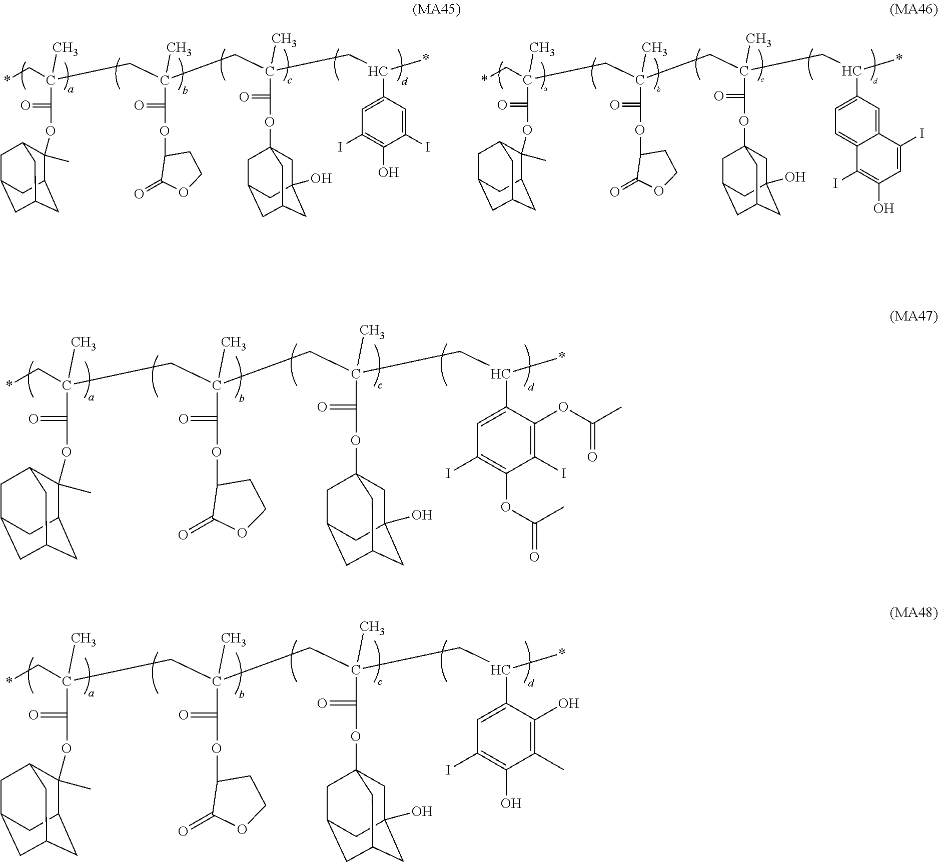

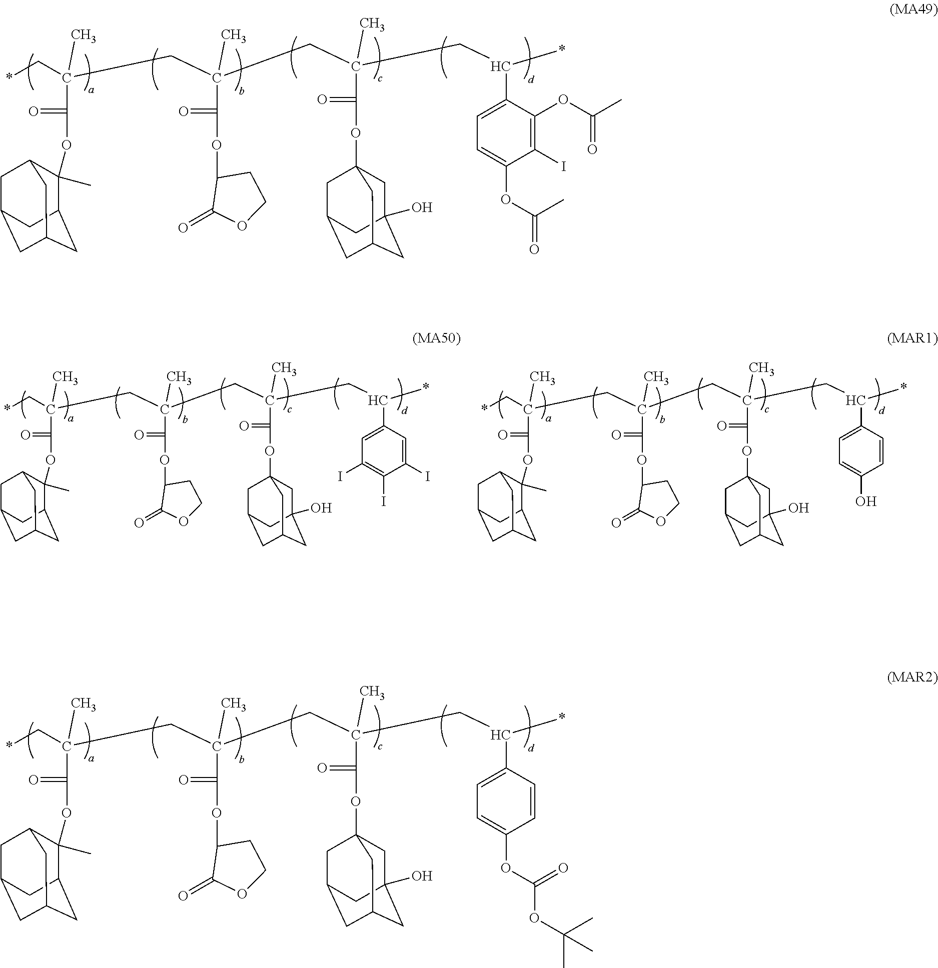

TABLE 1

| | Monomer | | | | | Polymer | | | | | |
|---|---|---|---|---|---|---|---|---|---|---|---|
| | Compound | | MAMA | BLMA | HAMA | | | a | b | c | d |
| | | Amount | Amount | Amount | Amount | | Structural | (Molar | (Molar | (Molar | (Molar |
| | No. | (g) | (g) | (g) | (g) | No. | formula | ratio) | ratio) | ratio) | ratio) |
| Synthetic | A1 | 1.5 | 4 | 0.9 | 1.5 | B1 | MA1 | 52 | 16 | 19 | 12 |
| Example B1 | | | | | | | | | | | |
| Synthetic | A1 | 1.5 | 3 | 0.9 | 1.5 | B2 | Ma1a | 45 | 20 | 20 | 15 |
| Example B2 | | | | | | | | | | | |
| Synthetic | A2 | 1.9 | 4 | 0.9 | 1.5 | B3 | MA2 | 52 | 16 | 19 | 12 |
| Example B3 | | | | | | | | | | | |
| Synthetic | A2 | 1.9 | 3 | 0.9 | 1.5 | B4 | MA2a | 45 | 20 | 20 | 15 |
| Example B4 | | | | | | | | | | | |
| Synthetic | A3 | 1.7 | 4 | 0.9 | 1.5 | B5 | MA3 | 52 | 16 | 19 | 12 |
| Example B5 | | | | | | | | | | | |
| Synthetic | A4 | 2.1 | 4 | 0.9 | 1.5 | B6 | MA4 | 52 | 16 | 19 | 12 |
| Example B6 | | | | | | | | | | | |
| Synthetic | A5 | 1.6 | 4 | 0.9 | 1.5 | B7 | MA5 | 52 | 16 | 19 | 12 |
| Example B7 | | | | | | | | | | | |
| Synthetic | A6 | 2.1 | 4 | 0.9 | 1.5 | B8 | MA6 | 52 | 16 | 19 | 12 |
| Example B8 | | | | | | | | | | | |
| Synthetic | A7 | 2 | 4 | 0.9 | 1.5 | B9 | MA7 | 52 | 16 | 19 | 12 |
| Example B9 | | | | | | | | | | | |
| Synthetic | A8 | 1.7 | 4 | 0.9 | 1.5 | B10 | MA8 | 52 | 16 | 19 | 12 |
| Example B10 | | | | | | | | | | | |
| Synthetic | A9 | 1.9 | 4 | 0.9 | 1.5 | B11 | MA9 | 52 | 16 | 19 | 12 |
| Example B11 | | | | | | | | | | | |
| Synthetic | A10 | 2.5 | 4 | 0.9 | 1.5 | B12 | MA10 | 52 | 16 | 19 | 12 |
| Example B12 | | | | | | | | | | | |
| Synthetic | A11 | 1 | 4 | 0.9 | 1.5 | B13 | MA11 | 52 | 16 | 19 | 12 |
| Example B13 | | | | | | | | | | | |
| Synthetic | A12 | 1.2 | 4 | 0.9 | 1.5 | B14 | MA12 | 52 | 16 | 19 | 12 |
| Example B14 | | | | | | | | | | | |
| Synthetic | A13 | 1.1 | 4 | 0.9 | 1.5 | B15 | MA13 | 52 | 16 | 19 | 12 |
| Example B15 | | | | | | | | | | | |
| Synthetic | A14 | 1.4 | 4 | 0.9 | 1.5 | B16 | MA14 | 52 | 16 | 19 | 12 |
| Example B16 | | | | | | | | | | | |
| Synthetic | A15 | 1.1 | 4 | 0.9 | 1.5 | B17 | MA15 | 52 | 16 | 19 | 12 |
| Example B17 | | | | | | | | | | | |
| Synthetic | A16 | 1.4 | 4 | 0.9 | 1.5 | B18 | MA16 | 52 | 16 | 19 | 12 |
| Example B18 | | | | | | | | | | | |
| Synthetic | ACL1 | 1.7 | 4 | 0.9 | 1.5 | B19 | MA17 | 52 | 16 | 19 | 12 |
| Example B19 | | | | | | | | | | | |
| Synthetic | AH2 | 1 | 4 | 0.9 | 1.5 | B20 | MA 18 | 52 | 16 | 19 | 12 |
| Example B20 | | | | | | | | | | | |
| Synthetic | Ma1 | 1.1 | 4 | 0.9 | 1.5 | B21 | MA19 | 52 | 16 | 19 | 12 |
| Example B21 | | | | | | | | | | | |
| Synthetic | A1a | 1.3 | 4 | 0.9 | 1.5 | B22 | MA20 | 52 | 16 | 19 | 12 |
| Example B22 | | | | | | | | | | | |
| Synthetic | Ma2 | 1.2 | 4 | 0.9 | 1.5 | B23 | MA21 | 52 | 16 | 19 | 12 |
| Example B23 | | | | | | | | | | | |
| Synthetic | A2a | 1.4 | 4 | 0.9 | 1.5 | B24 | MA22 | 52 | 16 | 19 | 12 |
| Example B24 | | | | | | | | | | | |
| Synthetic | Aa3 | 1.5 | 4 | 0.9 | 1.5 | B25 | MA23 | 52 | 16 | 19 | 12 |
| Example B25 | | | | | | | | | | | |
| Synthetic | Aa4 | 1.4 | 4 | 0.9 | 1.5 | B26 | MA24 | 52 | 16 | 19 | 12 |
| Example B26 | | | | | | | | | | | |
| Synthetic | Aa5 | 1.5 | 4 | 0.9 | 1.5 | B27 | MA25 | 52 | 16 | 19 | 12 |
| Example B27 | | | | | | | | | | | |
| Synthetic | Aa6 | 1.6 | 4 | 0.9 | 1.5 | B28 | MA26 | 52 | 16 | 19 | 12 |
| Example B28 | | | | | | | | | | | |
| Synthetic | Aa7 | 2 | 4 | 0.9 | 1.5 | B29 | MA27 | 52 | 16 | 19 | 12 |
| Example B29 | | | | | | | | | | | |
| Synthetic | Aa8 | 1.4 | 4 | 0.9 | 1.5 | B30 | MA28 | 52 | 16 | 19 | 12 |
| Example B30 | | | | | | | | | | | |
| Synthetic | Aa9 | 1.4 | 4 | 0.9 | 1.5 | B31 | MA29 | 52 | 16 | 19 | 12 |
| Example B31 | | | | | | | | | | | |
| Synthetic | Aa10 | 1.5 | 4 | 0.9 | 1.5 | B32 | MA30 | 52 | 16 | 19 | 12 |
| Example B32 | | | | | | | | | | | |
| Synthetic | Aa11 | 1.5 | 4 | 0.9 | 1.5 | B33 | MA31 | 52 | 16 | 19 | 12 |
| Example B33 | | | | | | | | | | | |
| Synthetic | Aa12 | 1.7 | 4 | 0.9 | 1.5 | B34 | MA32 | 52 | 16 | 19 | 12 |
| Example B34 | | | | | | | | | | | |
| Synthetic | Aa13 | 2.1 | 4 | 0.9 | 1.5 | B35 | MA33 | 52 | 16 | 19 | 12 |
| Example B35 | | | | | | | | | | | |
| Synthetic | Aa14 | 1.4 | 4 | 0.9 | 1.5 | B36 | MA34 | 52 | 16 | 19 | 12 |
| Example B36 | | | | | | | | | | | |
| Synthetic | Aa15 | 1.5 | 4 | 0.9 | 1.5 | B37 | MA35 | 52 | 16 | 19 | 12 |
| Example B37 | | | | | | | | | | | |
| Synthetic | Aa16 | 1.7 | 4 | 0.9 | 1.5 | B38 | MA36 | 52 | 16 | 19 | 12 |
| Example B38 | | | | | | | | | | | |
| Synthetic | Aa17 | 1.5 | 4 | 0.9 | 1.5 | B39 | MA37 | 52 | 16 | 19 | 12 |
| Example B39 | | | | | | | | | | | |
| Synthetic | Aa18 | 1.7 | 4 | 0.9 | 1.5 | B40 | MA38 | 52 | 16 | 19 | 12 |
| Example B40 | | | | | | | | | | | |
| Synthetic | Aa19 | 1.7 | 4 | 0.9 | 1.5 | B41 | MA39 | 52 | 16 | 19 | 12 |
| Example B41 | | | | | | | | | | | |
| Synthetic | Aa20 | 1.7 | 4 | 0.9 | 1.5 | B42 | MA40 | 52 | 16 | 19 | 12 |
| Example B42 | | | | | | | | | | | |
| Synthetic | Aa21 | 1.7 | 4 | 0.9 | 1.5 | B43 | MA41 | 60 | 10 | 15 | 15 |
| Example B43 | | | | | | | | | | | |
| Synthetic | Aa22 | 1.7 | 4 | 0.9 | 1.5 | B44 | MA42 | 60 | 10 | 15 | 15 |
| Example B44 | | | | | | | | | | | |
| Synthetic | Aa23 | 1.7 | 4 | 0.9 | 1.5 | B45 | MA43 | 60 | 10 | 15 | 15 |
| Example B45 | | | | | | | | | | | |
| Synthetic | Aa24 | 1.7 | 4 | 0.9 | 1.5 | B46 | MA44 | 60 | 10 | 15 | 15 |
| Example B46 | | | | | | | | | | | |
| Synthetic | Aa25 | 1.7 | 4 | 0.9 | 1.5 | B47 | MA45 | 60 | 10 | 15 | 15 |
| Example B47 | | | | | | | | | | | |
| Synthetic | Aa26 | 1.7 | 4 | 0.9 | 1.5 | B48 | MA46 | 60 | 10 | 15 | 15 |
| Example B48 | | | | | | | | | | | |
| Synthetic | Aa27 | 1.7 | 4 | 0.9 | 1.5 | B49 | MA47 | 60 | 10 | 15 | 15 |
| Example B49 | | | | | | | | | | | |
| Synthetic | Aa28 | 1.7 | 4 | 0.9 | 1.5 | B50 | MA48 | 60 | 10 | 15 | 15 |
| Example B50 | | | | | | | | | | | |
| Synthetic | Aa29 | 1.7 | 4 | 0.9 | 1.5 | B51 | MA49 | 60 | 10 | 15 | 15 |
| Example B51 | | | | | | | | | | | |
| Synthetic | Aa30 | 1.7 | 4 | 0.9 | 1.5 | B42 | MA50 | 60 | 10 | 15 | 15 |
| Example B52 | | | | | | | | | | | |
| Comparative | AR1 | 0.5 | 4 | 0.9 | 1.5 | BR1 | MAR1 | 60 | 10 | 15 | 15 |
| Example B1 | | | | | | | | | | | |
| Comparative | AR2 | 0.9 | 4 | 0.9 | 1.5 | BR2 | MAR2 | 60 | 10 | 15 | 15 |
| Example B2 | | | | | | | | | | | |

### Synthetic Examples C1 to C76

Each polymer described in Table 2 to Table 4 was obtained in the same manner as Synthetic Example B1, except that 1.5 g of the compound Al used in Synthetic Example B1 was changed to the kind and the amount of the compounds shown in Table 2 to Table 4.

TABLE 2

| | Monomer | | | | | | | |
|---|---|---|---|---|---|---|---|---|
| | Compound 1 | | Compound 2 | | MAMA | BLMA | HAMA | |
| | | Amount | | Amount | Amount | Amount | Amount | Polymer |
| | No. | (g) | No. | (g) | (g) | (g) | (g) | No. |
| Synthetic Example C1 | A1 | 1.5 | BP1 | 0.04 | 4 | 0.9 | 1.5 | C1 |
| Synthetic Example C2 | A1 | 1.5 | BP1 | 0.02 | 4 | 0.9 | 1.5 | C2 |
| Synthetic Example C3 | A1 | 1.5 | BP1 | 0.01 | 4 | 0.9 | 1.5 | C3 |
| Synthetic Example C4 | A1 | 1.5 | BP1 | 0.005 | 4 | 0.9 | 1.5 | C4 |
| Synthetic Example C5 | A1 | 1.5 | BP2 | 0.01 | 4 | 0.9 | 1.5 | C5 |
| Synthetic Example C6 | A1 | 1.5 | BP3 | 0.01 | 4 | 0.9 | 1.5 | C6 |
| Synthetic Example C7 | A1 | 1.5 | BP4 | 0.01 | 4 | 0.9 | 1.5 | C7 |
| Synthetic Example C8 | A1 | 1.5 | BP11 | 0.01 | 4 | 0.9 | 1.5 | C8 |
| Synthetic Example C9 | A1 | 1.5 | BP12 | 0.01 | 4 | 0.9 | 1.5 | C9 |
| Synthetic Example C10 | A1 | 1.5 | BP1 | 0.01 | 3 | 0.9 | 1.5 | C10 |
| Synthetic Example C11 | A1 | 1.5 | BP2 | 0.01 | 3 | 0.9 | 1.5 | C11 |
| Synthetic Example C12 | A2 | 1.9 | BP1 | 0.01 | 4 | 0.9 | 1.5 | C12 |
| Synthetic Example C13 | A2 | 1.9 | BP1 | 0.01 | 3 | 0.9 | 1.5 | C13 |
| Synthetic Example C14 | A3 | 1.9 | BP1 | 0.01 | 4 | 0.9 | 1.5 | C14 |
| Synthetic Example C15 | A4 | 2.1 | BP1 | 0.01 | 4 | 0.9 | 1.5 | C15 |
| Synthetic Example C16 | A5 | 1.6 | BP1 | 0.01 | 4 | 0.9 | 1.5 | C16 |
| Synthetic Example C17 | A6 | 2.1 | BP1 | 0.01 | 4 | 0.9 | 1.5 | C17 |
| Synthetic Example C18 | A7 | 2 | BP1 | 0.01 | 4 | 0.9 | 1.5 | C18 |
| Synthetic Example C19 | A8 | 1.7 | BP1 | 0.01 | 4 | 0.9 | 1.5 | C19 |
| Synthetic Example C20 | A9 | 1.9 | BP1 | 0.01 | 4 | 0.9 | 1.5 | C20 |
| Synthetic Example C21 | A10 | 2.5 | BP1 | 0.01 | 4 | 0.9 | 1.5 | C21 |
| Synthetic Example C22 | A11 | 1 | BP1 | 0.01 | 4 | 0.9 | 1.5 | C22 |
| Synthetic Example C23 | A12 | 1.2 | BP1 | 0.01 | 4 | 0.9 | 1.5 | C23 |
| Synthetic Example C24 | A13 | 1.1 | BP1 | 0.01 | 4 | 0.9 | 1.5 | C24 |
| Synthetic Example C25 | A14 | 1.4 | BP1 | 0.01 | 4 | 0.9 | 1.5 | C25 |
| Synthetic Example C26 | A15 | 1.1 | BP1 | 0.01 | 4 | 0.9 | 1.5 | C26 |
| Synthetic Example C27 | A16 | 1.4 | BP1 | 0.01 | 4 | 0.9 | 1.5 | C27 |
| Synthetic Example C28 | MCL1 | 1.7 | BP1 | 0.01 | 4 | 0.9 | 1.5 | C28 |
| Synthetic Example C29 | AH2 | 1 | BP1 | 0.01 | 4 | 0.9 | 1.5 | C29 |
| Synthetic Example C30 | Ma1 | 1.1 | BP1 | 0.01 | 4 | 0.9 | 1.5 | C30 |
| Synthetic Example C31 | Ma1 | 1.1 | BP2 | 0.01 | 4 | 0.9 | 1.5 | C31 |
| Synthetic Example C32 | Ma1 | 1.1 | BP3 | 0.01 | 4 | 0.9 | 1.5 | C32 |
| Synthetic Example C33 | Ma1 | 1.1 | BP4 | 0.01 | 4 | 0.9 | 1.5 | C33 |
| Synthetic Example C34 | Ma1 | 1.1 | BP11 | 0.01 | 4 | 0.9 | 1.5 | C34 |
| Synthetic Example C35 | Ma1 | 1.1 | BP12 | 0.01 | 4 | 0.9 | 1.5 | C35 |
| Synthetic Example C36 | Ma1a | 1.3 | BP2 | 0.01 | 4 | 0.9 | 1.5 | C36 |
| Synthetic Example C37 | Ma2 | 1.2 | BP2 | 0.01 | 4 | 0.9 | 1.5 | C37 |
| Synthetic Example C38 | Ma2a | 1.4 | BP2 | 0.01 | 4 | 0.9 | 1.5 | C38 |
| Synthetic Example C39 | Ma3 | 1.5 | BP2 | 0.01 | 4 | 0.9 | 1.5 | C39 |

TABLE 3

| | Monomer | | | | | | | |
|---|---|---|---|---|---|---|---|---|
| | Compound 1 | | Compound 2 | | MAMA | BLMA | HAMA | |
| | | Amount | | Amount | Amount | Amount | Amount | Polymer |
| | No. | (g) | No. | (g) | (g) | (g) | (g) | No. |
| Synthetic Example C40 | Ma4 | 1.4 | BP2 | 0.01 | 4 | 0.9 | 1.5 | C40 |
| Synthetic Example C41 | Ma5 | 1.5 | BP2 | 0.01 | 4 | 0.9 | 1.5 | C41 |
| Synthetic Example C42 | Ma6 | 1.6 | BP2 | 0.01 | 4 | 0.9 | 1.5 | C42 |
| Synthetic Example C43 | Ma7 | 2 | BP2 | 0.01 | 4 | 0.9 | 1.5 | C43 |
| Synthetic Example C44 | Ma8 | 1.4 | BP2 | 0.01 | 4 | 0.9 | 1.5 | C44 |
| Synthetic Example C45 | Ma9 | 1.4 | BP2 | 0.01 | 4 | 0.9 | 1.5 | C45 |
| Synthetic Example C46 | Ma10 | 1.5 | BP2 | 0.01 | 4 | 0.9 | 1.5 | C46 |
| Synthetic Example C47 | Ma11 | 1.5 | BP2 | 0.01 | 4 | 0.9 | 1.5 | C47 |
| Synthetic Example C48 | Ma12 | 1.7 | BP2 | 0.01 | 4 | 0.9 | 1.5 | C48 |
| Synthetic Example C49 | Ma13 | 2.1 | BP2 | 0.01 | 4 | 0.9 | 1.5 | C49 |
| Synthetic Example C50 | Ma14 | 1.4 | BP2 | 0.01 | 4 | 0.9 | 1.5 | C50 |
| Synthetic Example C61 | Ma15 | 1.5 | BP1 | 0.01 | 4 | 0.9 | 1.5 | C61 |
| Synthetic Example C62 | Ma16 | 1.7 | BP1 | 0.01 | 4 | 0.9 | 1.5 | C62 |
| Synthetic Example C63 | Ma17 | 1.5 | BP5 | 0.01 | 4 | 0.9 | 1.5 | C63 |
| Synthetic Example C64 | Ma18 | 1.7 | BP5 | 0.01 | 4 | 0.9 | 1.5 | C64 |
| Synthetic Example C65 | Ma19 | 1.7 | BP6 | 0.01 | 4 | 0.9 | 1.5 | C65 |
| Synthetic Example C66 | Ma20 | 1.7 | BP6 | 0.01 | 4 | 0.9 | 1.5 | C66 |
| Synthetic Example C67 | Ma21 | 1.5 | BP1 | 0.01 | 4 | 0.9 | 1.5 | C67 |
| Synthetic Example C68 | Ma22 | 1.5 | BP2 | 0.01 | 4 | 0.9 | 1.5 | C68 |
| Synthetic Example C69 | Ma23 | 1.5 | BP6 | 0.01 | 4 | 0.9 | 1.5 | C69 |
| Synthetic Example C70 | Ma24 | 1.5 | BP6 | 0.01 | 4 | 0.9 | 1.5 | C70 |
| Synthetic Example C71 | Ma25 | 1.5 | BP1 | 0.01 | 4 | 0.9 | 1.5 | C71 |
| Synthetic Example C72 | Ma26 | 1.5 | BP2 | 0.01 | 4 | 0.9 | 1.5 | C72 |
| Synthetic Example C73 | Ma27 | 1.5 | BP6 | 0.01 | 4 | 0.9 | 1.5 | C73 |
| Synthetic Example C74 | Ma28 | 1.5 | BP6 | 0.01 | 4 | 0.9 | 1.5 | C74 |
| Synthetic Example C75 | Ma29 | 1.5 | BP6 | 0.01 | 4 | 0.9 | 1.5 | C75 |
| Synthetic Example C76 | Ma30 | 1.5 | BP1 | 0.01 | 4 | 0.9 | 1.5 | C76 |

TABLE 4

| | Monomer | | | | | | | | | |
|---|---|---|---|---|---|---|---|---|---|---|
| | Compound 1 | | Compound 2 | | Compound 3 | | MAMA | BLMA | HAMA | |
| | | Amount | | Amount | | Amount | Amount | Amount | Amount | Polymer |
| | No. | (g) | No. | (g) | No. | (g) | (g) | (g) | (g) | No. |
| Synthetic Example C51 | A1 | 1.5 | BP1 | 0.05 | BP2 | 0.05 | 4 | 0.9 | 1.5 | C51 |
| Synthetic Example C52 | A1 | 1.5 | BP1 | 0.05 | BP3 | 0.05 | 4 | 0.9 | 1.5 | C52 |
| Synthetic Example C53 | A1 | 1.5 | BP1 | 0.05 | BP4 | 0.05 | 4 | 0.9 | 1.5 | C53 |
| Synthetic Example C54 | A1 | 1.5 | BP1 | 0.05 | BP11 | 0.05 | 4 | 0.9 | 1.5 | C54 |
| Synthetic Example C55 | A1 | 1.5 | BP1 | 0.05 | BP12 | 0.05 | 4 | 0.9 | 1.5 | C55 |
| Synthetic Example C56 | Ma1 | 1.1 | BP1 | 0.05 | BP2 | 0.05 | 4 | 0.9 | 1.5 | C56 |
| Synthetic Example C57 | Ma1 | 1.1 | BP1 | 0.05 | BP3 | 0.05 | 4 | 0.9 | 1.5 | C57 |
| Synthetic Example C58 | Ma1 | 1.1 | BP1 | 0.05 | BP4 | 0.05 | 4 | 0.9 | 1.5 | C58 |
| Synthetic Example C59 | Ma1 | 1.1 | BP1 | 0.05 | BP11 | 0.05 | 4 | 0.9 | 1.5 | C59 |
| Synthetic Example C60 | Ma1 | 1.1 | BP1 | 0.05 | BP12 | 0.05 | 4 | 0.9 | 1.5 | C60 |

The meanings of the abbreviations in Tables 2 to 4 are as follows.
MAMA: 2-methyl-2-adamantyl methacrylate
BLMA: γ-butyrolactone methacrylate
HAMA: hydroxyadamantyl methacrylate

### (Inorganic Element Content and Organic Impurities Content)

The inorganic element content and organic impurity content of the polymers obtained from Synthetic Examples described in Tables 2 to 4 were measured by the aforementioned method. The results are shown in Table 4-1.

TABLE 4-1

| | | Polymer impurity content (ppm) | | | | | |
|---|---|---|---|---|---|---|---|
| | | | | | | | Phosphorus- |
| | | | | | | | containing |
| | Polymer | Mn | Al | Si | Li | Maleic acid | compound |
| Synthetic Example C1 | C1 | 0.01 | 0.01 | 0.01 | 0.01 | 0.5 | 0.1 |
| Synthetic Example C2 | C2 | 0.01 | 0.01 | 0.01 | 0.01 | 0.1 | 0.1 |
| Synthetic Example C3 | C3 | 0.01 | 0.01 | 0.01 | 0.01 | 0.1 | 0.1 |
| Synthetic Example C4 | C4 | 0.01 | 0.01 | 0.01 | 0.01 | 0.1 | 0.1 |
| Synthetic Example C5 | C5 | 0.01 | 0.01 | 0.01 | 0.01 | 0.1 | 0.1 |
| Synthetic Example C6 | C6 | 0.01 | 0.01 | 0.01 | 0.01 | 0.1 | 0.1 |
| Synthetic Example C7 | C7 | 0.01 | 0.01 | 0.01 | 0.01 | 0.1 | 0.1 |
| Synthetic Example C8 | C8 | 0.01 | 0.01 | 0.01 | 0.01 | 0.1 | 0.1 |
| Synthetic Example C9 | C9 | 0.01 | 0.01 | 0.01 | 0.01 | 0.1 | 0.1 |
| Synthetic Example C10 | C10 | 0.01 | 0.01 | 0.01 | 0.01 | 0.1 | 0.1 |
| Synthetic Example C11 | C11 | 0.01 | 0.01 | 0.01 | 0.01 | 0.1 | 0.1 |
| Synthetic Example C12 | C12 | 0.01 | 0.01 | 0.01 | 0.01 | 0.1 | 0.1 |
| Synthetic Example C13 | C13 | 0.01 | 0.01 | 0.01 | 0.01 | 0.1 | 0.1 |
| Synthetic Example C14 | C14 | 0.01 | 0.01 | 0.01 | 0.01 | 0.1 | 0.1 |
| Synthetic Example C15 | C15 | 0.01 | 0.01 | 0.01 | 0.01 | 0.1 | 0.1 |
| Synthetic Example C16 | C16 | 0.01 | 0.01 | 0.01 | 0.01 | 0.1 | 0.1 |
| Synthetic Example C17 | C17 | 0.01 | 0.01 | 0.01 | 0.01 | 0.1 | 0.1 |
| Synthetic Example C18 | C18 | 0.01 | 0.01 | 0.01 | 0.01 | 0.1 | 0.1 |
| Synthetic Example C19 | C19 | 0.01 | 0.01 | 0.01 | 0.01 | 0.1 | 0.1 |
| Synthetic Example C20 | C20 | 0.01 | 0.01 | 0.01 | 0.01 | 0.1 | 0.1 |
| Synthetic Example C21 | C21 | 0.01 | 0.01 | 0.01 | 0.01 | 0.1 | 0.1 |
| Synthetic Example C22 | C22 | 0.01 | 0.01 | 0.01 | 0.01 | 0.1 | 0.1 |
| Synthetic Example C23 | C23 | 0.01 | 0.01 | 0.01 | 0.01 | 0.1 | 0.1 |
| Synthetic Example C24 | C24 | 0.01 | 0.01 | 0.01 | 0.01 | 0.1 | 0.1 |
| Synthetic Example C25 | C25 | 0.01 | 0.01 | 0.01 | 0.01 | 0.1 | 0.1 |
| Synthetic Example C26 | C26 | 0.01 | 0.01 | 0.01 | 0.01 | 0.1 | 0.1 |
| Synthetic Example C27 | C27 | 0.01 | 0.01 | 0.01 | 0.01 | 0.1 | 0.1 |
| Synthetic Example C28 | C28 | 0.01 | 0.01 | 0.01 | 0.01 | 0.1 | 0.1 |
| Synthetic Example C29 | C29 | 0.01 | 0.01 | 0.01 | 0.01 | 0.1 | 0.1 |
| Synthetic Example C30 | C30 | 0.01 | 0.01 | 0.01 | 0.01 | 0.1 | 0.1 |
| Synthetic Example C31 | C31 | 0.01 | 0.01 | 0.01 | 0.01 | 0.1 | 0.1 |
| Synthetic Example C32 | C32 | 0.01 | 0.01 | 0.01 | 0.01 | 0.1 | 0.1 |
| Synthetic Example C33 | C33 | 0.01 | 0.01 | 0.01 | 0.01 | 0.1 | 0.1 |
| Synthetic Example C34 | C34 | 0.01 | 0.01 | 0.01 | 0.01 | 0.1 | 0.1 |
| Synthetic Example C35 | C35 | 0.01 | 0.01 | 0.01 | 0.01 | 0.1 | 0.1 |
| Synthetic Example C36 | C36 | 0.01 | 0.01 | 0.01 | 0.01 | 0.1 | 0.1 |
| Synthetic Example C37 | C37 | 0.01 | 0.01 | 0.01 | 0.01 | 0.1 | 0.1 |
| Synthetic Example C38 | C38 | 0.01 | 0.01 | 0.01 | 0.01 | 0.1 | 0.1 |
| Synthetic Example C39 | C39 | 0.01 | 0.01 | 0.01 | 0.01 | 0.1 | 0.1 |
| Synthetic Example C40 | C40 | 0.01 | 0.01 | 0.01 | 0.01 | 0.1 | 0.1 |
| Synthetic Example C41 | C41 | 0.01 | 0.01 | 0.01 | 0.01 | 0.1 | 0.1 |
| Synthetic Example C42 | C42 | 0.01 | 0.01 | 0.01 | 0.01 | 0.1 | 0.1 |
| Synthetic Example C43 | C43 | 0.01 | 0.01 | 0.01 | 0.01 | 0.1 | 0.1 |
| Synthetic Example C44 | C44 | 0.01 | 0.01 | 0.01 | 0.01 | 0.1 | 0.1 |
| Synthetic Example C45 | C45 | 0.01 | 0.01 | 0.01 | 0.01 | 0.1 | 0.1 |
| Synthetic Example C46 | C46 | 0.01 | 0.01 | 0.01 | 0.01 | 0.1 | 0.1 |
| Synthetic Example C47 | C47 | 0.01 | 0.01 | 0.01 | 0.01 | 0.1 | 0.1 |
| Synthetic Example C48 | C48 | 0.01 | 0.01 | 0.01 | 0.01 | 0.1 | 0.1 |
| Synthetic Example C49 | C49 | 0.01 | 0.01 | 0.01 | 0.01 | 0.1 | 0.1 |
| Synthetic Example C50 | C50 | 0.01 | 0.01 | 0.01 | 0.01 | 0.1 | 0.1 |
| Synthetic Example C51 | C51 | 0.01 | 0.01 | 0.01 | 0.01 | 0.1 | 0.1 |
| Synthetic Example C52 | C52 | 0.01 | 0.01 | 0.01 | 0.01 | 0.1 | 0.1 |
| Synthetic Example C53 | C53 | 0.01 | 0.01 | 0.01 | 0.01 | 0.1 | 0.1 |
| Synthetic Example C54 | C54 | 0.01 | 0.01 | 0.01 | 0.01 | 0.1 | 0.1 |
| Synthetic Example C55 | C55 | 0.01 | 0.01 | 0.01 | 0.01 | 0.1 | 0.1 |
| Synthetic Example C56 | C56 | 0.01 | 0.01 | 0.01 | 0.01 | 0.1 | 0.1 |
| Synthetic Example C57 | C57 | 0.01 | 0.01 | 0.01 | 0.01 | 0.1 | 0.1 |
| Synthetic Example C58 | C58 | 0.01 | 0.01 | 0.01 | 0.01 | 0.1 | 0.1 |
| Synthetic Example C59 | C59 | 0.01 | 0.01 | 0.01 | 0.01 | 0.1 | 0.1 |
| Synthetic Example C60 | C60 | 0.01 | 0.01 | 0.01 | 0.01 | 0.1 | 0.1 |
| Synthetic Example C61 | C61 | 0.01 | 0.01 | 0.01 | 0.01 | 0.1 | 0.1 |
| Synthetic Example C62 | C62 | 0.01 | 0.01 | 0.01 | 0.01 | 0.1 | 0.1 |
| Synthetic Example C63 | C63 | 0.01 | 0.01 | 0.01 | 0.01 | 0.1 | 0.1 |
| Synthetic Example C64 | C64 | 0.01 | 0.01 | 0.01 | 0.01 | 0.1 | 0.1 |
| Synthetic Example C65 | C65 | 0.01 | 0.01 | 0.01 | 0.01 | 0.1 | 0.1 |
| Synthetic Example C66 | C66 | 0.01 | 0.01 | 0.01 | 0.01 | 0.1 | 0.1 |
| Synthetic Example C67 | C67 | 0.01 | 0.01 | 0.01 | 0.01 | 0.1 | 0.1 |
| Synthetic Example C68 | C68 | 0.01 | 0.01 | 0.01 | 0.01 | 0.1 | 0.1 |
| Synthetic Example C69 | C69 | 0.01 | 0.01 | 0.01 | 0.01 | 0.1 | 0.1 |
| Synthetic Example C70 | C70 | 0.01 | 0.01 | 0.01 | 0.01 | 0.1 | 0.1 |
| Synthetic Example C71 | C71 | 0.01 | 0.01 | 0.01 | 0.01 | 0.1 | 0.1 |
| Synthetic Example C72 | C72 | 0.01 | 0.01 | 0.01 | 0.01 | 0.1 | 0.1 |
| Synthetic Example C73 | C73 | 0.01 | 0.01 | 0.01 | 0.01 | 0.1 | 0.1 |
| Synthetic Example C74 | C74 | 0.01 | 0.01 | 0.01 | 0.01 | 0.1 | 0.1 |
| Synthetic Example C75 | C75 | 0.01 | 0.01 | 0.01 | 0.01 | 0.1 | 0.1 |
| Synthetic Example C76 | C76 | 0.01 | 0.01 | 0.01 | 0.01 | 0.1 | 0.1 |

### Synthetic Examples C1P to C76P, Comparative Examples B1 to B2

For the synthesized compound A1, purification treatments of respective raw materials were additionally conducted before synthesis of the polymer. Using ethyl acetate (PrimePure manufactured by Kanto Chemical Co., Inc.) as a solvent, a 10% by mass ethyl acetate solution in which the compound Al was dissolved was obtained. To remove metal impurities, an ion exchange resin “AMBERLYST MSPS2-1.DRY” (product name, manufactured by ORGANO CORPORATION) was immersed in ethyl acetate (PrimePure manufactured by Kanto Chemical Co., Inc.), stirred for 1 hour, and then the solvent was removed. Washing of the ion exchange resin was carried out by repeating washing in this manner 10 times. In the above ethyl acetate solution of the compound A1, the same mass of the washed ion exchange resin as the resin solid content was put and stirred at room temperature for a day, and then the ion exchange resin was filtered off. Washing in which an ion exchange treatment was carried out in this manner was repeated three times to obtain an ion-exchanged ethyl acetate solution of the compound A1. Furthermore, the same treatment was carried out for other monomers, thereby obtaining an ion-exchanged monomer-containing ethyl acetate solution. Synthesis was carried out according to the same scheme as the synthesis of the polymer B1 using the composition of Synthetic Example B1 by using the obtained ion exchange treated monomer-containing ethyl acetate solution, using Pruimepure manufactured by Kanto Chemical Co., Inc., which is electronic grade as the solvent such as n-heptane and tetrahydrofuran, and further using instruments, all of which were immersed in nitric acid for a day and then washed with ultrapure water, as the reaction vessel such as a flask. Further in the treatment after synthesis, a purification treatment was carried out by using a 5 nm Nylon filter (manufactured by Pall) and a 15 nm PTFE filter (manufactured by Entegris) in the order presented, and the purified product was dried under reduced pressure to obtain a white powdery polymer C1P. The inorganic element content and organic impurity content of the polymer were measured by the aforementioned method, and the results are shown in Table 4-2.

The polymers C2P to C76P were obtained in the same manner as C1P, except that 1.5 g of the compound Al was changed to the kind and the amount of the compounds shown in Table 2 and Table 3. In addition, the inorganic element content and organic impurity content of the obtained polymers were measured by the aforementioned method, and the results are shown in Table 4-2.

TABLE 4-2

| | | Polymer impurity content (ppm) | | | | | |
|---|---|---|---|---|---|---|---|
| | | | | | | | Phosphorus- |
| | | | | | | Maleic | containing |
| | Polymer | Mn | Al | Si | Li | acid | compound |
| Synthetic Example C1P | C1P | 0.0001 | 0.0001 | 0.001 | 0.0001 | 0.1 | 0.1 |
| Synthetic Example C2P | C2P | 0.0001 | 0.0001 | 0.001 | 0.0001 | 0.1 | 0.1 |
| Synthetic Example C3P | C3P | 0.0001 | 0.0001 | 0.001 | 0.0001 | 0.1 | 0.1 |
| Synthetic Example C4P | C4P | 0.0001 | 0.0001 | 0.001 | 0.0001 | 0.1 | 0.1 |
| Synthetic Example C5P | C5P | 0.0001 | 0.0001 | 0.001 | 0.0001 | 0.1 | 0.1 |
| Synthetic Example C6P | C6P | 0.0001 | 0.0001 | 0.001 | 0.0001 | 0.1 | 0.1 |
| Synthetic Example C7P | C7P | 0.0001 | 0.0001 | 0.001 | 0.0001 | 0.1 | 0.1 |
| Synthetic Example C8P | C8P | 0.0001 | 0.0001 | 0.001 | 0.0001 | 0.1 | 0.1 |
| Synthetic Example C9P | C9P | 0.0001 | 0.0001 | 0.001 | 0.0001 | 0.1 | 0.1 |
| Synthetic Example C10P | C10P | 0.0001 | 0.0001 | 0.001 | 0.0001 | 0.1 | 0.1 |
| Synthetic Example C11P | C11P | 0.0001 | 0.0001 | 0.001 | 0.0001 | 0.1 | 0.1 |
| Synthetic Example C12P | C12P | 0.0001 | 0.0001 | 0.001 | 0.0001 | 0.1 | 0.1 |
| Synthetic Example C13P | C13P | 0.0001 | 0.0001 | 0.001 | 0.0001 | 0.1 | 0.1 |
| Synthetic Example C14P | C14P | 0.0001 | 0.0001 | 0.001 | 0.0001 | 0.1 | 0.1 |
| Synthetic Example C15P | C15P | 0.0001 | 0.0001 | 0.001 | 0.0001 | 0.1 | 0.1 |
| Synthetic Example C16P | C16P | 0.0001 | 0.0001 | 0.001 | 0.0001 | 0.1 | 0.1 |
| Synthetic Example C17P | C17P | 0.0001 | 0.0001 | 0.001 | 0.0001 | 0.1 | 0.1 |
| Synthetic Example C18P | C18P | 0.0001 | 0.0001 | 0.001 | 0.0001 | 0.1 | 0.1 |
| Synthetic Example C19P | C19P | 0.0001 | 0.0001 | 0.001 | 0.0001 | 0.1 | 0.1 |
| Synthetic Example C20P | C20F | 0.0001 | 0.0001 | 0.001 | 0.0001 | 0.1 | 0.1 |
| Synthetic Example C21P | C21P | 0.0001 | 0.0001 | 0.001 | 0.0001 | 0.1 | 0.1 |
| Synthetic Example C22P | C22P | 0.0001 | 0.0001 | 0.001 | 0.0001 | 0.1 | 0.1 |
| Synthetic Example C23P | C23P | 0.0001 | 0.0001 | 0.001 | 0.0001 | 0.1 | 0.1 |
| Synthetic Example C24P | C24P | 0.0001 | 0.0001 | 0.001 | 0.0001 | 0.1 | 0.1 |
| Synthetic Example C25P | C25P | 0.0001 | 0.0001 | 0.001 | 0.0001 | 0.1 | 0.1 |
| Synthetic Example C26P | C26P | 0.0001 | 0.0001 | 0.001 | 0.0001 | 0.1 | 0.1 |
| Synthetic Example C27P | C27P | 0.0001 | 0.0001 | 0.001 | 0.0001 | 0.1 | 0.1 |
| Synthetic Example C28P | C28P | 0.0001 | 0.0001 | 0.001 | 0.0001 | 0.1 | 0.1 |
| Synthetic Example C29P | C29P | 0.0001 | 0.0001 | 0.001 | 0.0001 | 0.1 | 0.1 |
| Synthetic Example C30P | C30F | 0.0001 | 0.0001 | 0.001 | 0.0001 | 0.1 | 0.1 |
| Synthetic Example C31P | C31P | 0.0001 | 0.0001 | 0.001 | 0.0001 | 0.1 | 0.1 |
| Synthetic Example C32P | C32P | 0.0001 | 0.0001 | 0.001 | 0.0001 | 0.1 | 0.1 |
| Synthetic Example C33P | C33P | 0.0001 | 0.0001 | 0.001 | 0.0001 | 0.1 | 0.1 |
| Synthetic Example C34P | C34P | 0.0001 | 0.0001 | 0.001 | 0.0001 | 0.1 | 0.1 |
| Synthetic Example C35P | C35P | 0.0001 | 0.0001 | 0.001 | 0.0001 | 0.1 | 0.1 |
| Synthetic Example C36P | C36P | 0.0001 | 0.0001 | 0.001 | 0.0001 | 0.1 | 0.1 |
| Synthetic Example C37P | C37P | 0.0001 | 0.0001 | 0.001 | 0.0001 | 0.1 | 0.1 |
| Synthetic Example C38P | C38P | 0.0001 | 0.0001 | 0.001 | 0.0001 | 0.1 | 0.1 |
| Synthetic Example C39P | C39P | 0.0001 | 0.0001 | 0.001 | 0.0001 | 0.1 | 0.1 |
| Synthetic Example C40P | C40P | 0.0001 | 0.0001 | 0.001 | 0.0001 | 0.1 | 0.1 |
| Synthetic Example C41P | C41F | 0.0001 | 0.0001 | 0.001 | 0.0001 | 0.1 | 0.1 |
| Synthetic Example C42P | C42P | 0.0001 | 0.0001 | 0.001 | 0.0001 | 0.1 | 0.1 |
| Synthetic Example C43P | C43P | 0.0001 | 0.0001 | 0.001 | 0.0001 | 0.1 | 0.1 |
| Synthetic Example C44P | C44P | 0.0001 | 0.0001 | 0.001 | 0.0001 | 0.1 | 0.1 |
| Synthetic Example C45P | C45P | 0.0001 | 0.0001 | 0.001 | 0.0001 | 0.1 | 0.1 |
| Synthetic Example C46P | C46P | 0.0001 | 0.0001 | 0.001 | 0.0001 | 0.1 | 0.1 |
| Synthetic Example C47P | C47P | 0.0001 | 0.0001 | 0.001 | 0.0001 | 0.1 | 0.1 |
| Synthetic Example C48P | C48P | 0.0001 | 0.0001 | 0.001 | 0.0001 | 0.1 | 0.1 |
| Synthetic Example C49P | C49P | 0.0001 | 0.0001 | 0.001 | 0.0001 | 0.1 | 0.1 |
| Synthetic Example C50P | C50P | 0.0001 | 0.0001 | 0.001 | 0.0001 | 0.1 | 0.1 |
| Synthetic Example C51P | C51P | 0.0001 | 0.0001 | 0.001 | 0.0001 | 0.1 | 0.1 |
| Synthetic Example C52P | C52P | 0.0001 | 0.0001 | 0.001 | 0.0001 | 0.1 | 0.1 |
| Synthetic Example C53P | C53P | 0.0001 | 0.0001 | 0.001 | 0.0001 | 0.1 | 0.1 |
| Synthetic Example C54P | C54P | 0.0001 | 0.0001 | 0.001 | 0.0001 | 0.1 | 0.1 |
| Synthetic Example C55P | C55P | 0.0001 | 0.0001 | 0.001 | 0.0001 | 0.1 | 0.1 |
| Synthetic Example C56P | C56P | 0.0001 | 0.0001 | 0.001 | 0.0001 | 0.1 | 0.1 |
| Synthetic Example C57P | C57P | 0.0001 | 0.0001 | 0.001 | 0.0001 | 0.1 | 0.1 |
| Synthetic Example C58P | C58P | 0.0001 | 0.0001 | 0.001 | 0.0001 | 0.1 | 0.1 |
| Synthetic Example C59P | C59P | 0.0001 | 0.0001 | 0.001 | 0.0001 | 0.1 | 0.1 |
| Synthetic Example C60P | C60P | 0.0001 | 0.0001 | 0.001 | 0.0001 | 0.1 | 0.1 |
| Synthetic Example C61P | C61P | 0.0001 | 0.0001 | 0.001 | 0.0001 | 0.1 | 0.1 |
| Synthetic Example C62P | C62P | 0.0001 | 0.0001 | 0.001 | 0.0001 | 0.1 | 0.1 |
| Synthetic Example C63P | C63P | 0.0001 | 0.0001 | 0.001 | 0.0001 | 0.1 | 0.1 |
| Synthetic Example C64P | C64P | 0.0001 | 0.0001 | 0.001 | 0.0001 | 0.1 | 0.1 |
| Synthetic Example C65P | C65P | 0.0001 | 0.0001 | 0.001 | 0.0001 | 0.1 | 0.1 |
| Synthetic Example C66P | C66P | 0.0001 | 0.0001 | 0.001 | 0.0001 | 0.1 | 0.1 |
| Synthetic Example C67P | C67P | 0.0001 | 0.0001 | 0.001 | 0.0001 | 0.1 | 0.1 |
| Synthetic Example C68P | C68P | 0.0001 | 0.0001 | 0.001 | 0.0001 | 0.1 | 0.1 |
| Synthetic Example C69P | C69P | 0.0001 | 0.0001 | 0.001 | 0.0001 | 0.1 | 0.1 |
| Synthetic Example C70P | C70P | 0.0001 | 0.0001 | 0.001 | 0.0001 | 0.1 | 0.1 |
| Synthetic Example C71P | C71P | 0.0001 | 0.0001 | 0.001 | 0.0001 | 0.1 | 0.1 |
| Synthetic Example C72P | C72P | 0.0001 | 0.0001 | 0.001 | 0.0001 | 0.1 | 0.1 |
| Synthetic Example C73P | C73P | 0.0001 | 0.0001 | 0.001 | 0.0001 | 0.1 | 0.1 |
| Synthetic Example C74P | C74P | 0.0001 | 0.0001 | 0.001 | 0.0001 | 0.1 | 0.1 |
| Synthetic Example C75P | C75P | 0.0001 | 0.0001 | 0.001 | 0.0001 | 0.1 | 0.1 |
| Synthetic Example C76P | C76P | 0.0001 | 0.0001 | 0.001 | 0.0001 | 0.1 | 0.1 |
| Comparative Example B1 | BR1 | 0.1 | 0.1 | 0.1 | 0.1 | 0.5 | 0.5 |
| Comparative Example B2 | BR2 | 0.1 | 0.1 | 0.1 | 0.1 | 0.5 | 0.5 |

### [Evaluation]

The aforementioned polymers obtained in Synthetic Examples and Comparative Examples were evaluated as follows. The results are shown in Table 4-3, Table 5, and Table 6.

### (EUV Sensitivity-Aqueous TMAH Solution Development)

A solution was prepared by blending 5 parts by mass of the polymer obtained in Examples or Comparative

Examples, 1 part by mass of triphenylsulfonium nonafluorobutanesulfonate, 0.2 parts by mass of tributylamine, 80 parts by mass of PGMEA, and 12 parts by mass of PGME.

The solution was applied on a silicon wafer, which was baked at 110° C. for 60 seconds to form a photoresist layer having a film thickness of 100 nm.

Then, using an extreme ultraviolet (EUV) exposure apparatus “EUVES-7000” (product name, manufactured by Litho Tech Japan Corporation), the photoresist layer was subjected to shot exposure without masking by incrementing the exposure amount by 1 mJ/cm² from 1 mJ/cm² to 80 mJ/cm², baked (PEB) at 110° C. for 90 seconds, and developed with a 2.38% by mass aqueous tetramethylammonium hydroxide (TMAH) solution for 60 seconds to obtain a wafer on which 80 shots of shot exposure was carried out. For each obtained shot exposure area, the film thickness was measured by using an optical interference film thickness meter “VM3200” (product name, manufactured by SCREEN Semiconductor Solutions Co., Ltd.), profile data about the film thickness relative to the exposure amount was obtained, and the exposure amount at which the slope of film thickness variation relative to an exposure amount was the largest was calculated as a sensitivity value (mJ/cm²), which was used as an index of the EUV sensitivity of the resist.

### (Evaluation of Sensitivity Due to Aging)

The solution prepared in the aforementioned EUV sensitivity evaluation was subjected to a forced aging treatment under light-shielding conditions at 40° C./240 hours, and the solution after the aging treatment was evaluated for EUV sensitivity in the same manner. Evaluations were conducted based on the amount of change of sensitivity. As the specific evaluation method, in a film thickness-sensitivity curve after development when the abscissa was set to sensitivity and the ordinate was set to film thickness in the EUV sensitivity evaluation, the sensitivity value at which the slope value was maximum was measured as the standard sensitivity. The standard sensitivities of the solutions before and after being subjected to a forced aging treatment were determined, and sensitivity variations due to the aging treatment were evaluated from the numerical value obtained by the following calculation expression. The evaluation criteria are as follows.

$$[ Sensitivity variation ] = 1 - ( [ standard sensitivity of solution after aging ] / [ standard sensitivity of solution before aging ] )$$

### (Evaluation Criteria)

A: [sensitivity variation]≤0.005
B: 0.005< [sensitivity variation]≤0.02
C: 0.02< [sensitivity variation]≤0.05
D: 0.05< [sensitivity variation] (EB pattern-aqueous TMAH solution development)

A solution was prepared by blending 5 parts by mass of the compound or the polymer obtained in Examples or Comparative Examples, 1 part by mass of triphenylsulfonium nonafluorobutanesulfonate, 0.1 parts by mass of tributylamine, and 92 parts by mass of PGMEA.

The solution was applied on a silicon wafer, which was baked at 110 to 130° C. for 60 seconds to form a resist film having a film thickness of 100 nm.

Then, the resist film was exposed using an electron beam lithography system “ELS-7500” (product name, manufactured by ELIONIX INC., 50 keV), baked (PEB) at 115° C. for 90 seconds, and developed with a 2.38 mass % tetramethylammonium hydroxide (TMAH) aqueous solution for 60 seconds to obtain a positive type pattern. The exposure amount was regulated to have a line and space pattern with a half pitch of 50 nm.

For the obtained resist pattern, 80 pattern images were obtained with a scanning electron microscope “S-4800” (product name, manufactured by Hitachi, Ltd.) at 100000 times magnification, the number of residues on the space portion between resist patterns were counted, and evaluations were carried out from the total amount of the residues. The evaluation criteria are as follows.

### (Evaluation Criteria)

A: Number of residues ≤ 10
B: 10<number of residues≤80
C: 80<number of residues <400
D: 400<number of residues

### (Evaluation of Etching Defect)

A solution was prepared by blending 5 parts by mass of the polymer obtained in Examples or Comparative Examples, 1 part by mass of triphenylsulfonium nonafluorobutanesulfonate, 0.2 parts by mass of tributylamine, 80 parts by mass of PGMEA, and 12 parts by mass of PGME.

The solution was applied on a 8 inch silicon wafer, on the outermost layer of which an oxide film having a film thickness of 100 nm was formed, and this was baked at 110° C. for 60 seconds to form a photoresist layer having a film thickness of 100 nm.

Then, using an extreme ultraviolet (EUV) exposure apparatus “EUVES-7000” (product name, manufactured by Litho Tech Japan Corporation), the photoresist layer was subjected to shot exposure with an exposure amount that is 10% less than the EUV sensitivity value obtained in the above EUV sensitivity evaluation on the entire wafer surface, further baked (PEB) at 110° C. for 90 seconds, and developed with a 2.38% by mass aqueous tetramethylammonium hydroxide (TMAH) solution for 60 seconds to obtain a wafer on the entire surface of which 80 shots of shot exposure was carried out.

The prepared exposed wafer was subjected to an etching treatment with an etching apparatus “Telius SCCM” (product name, manufactured by Tokyo Electron Ltd.), using CF₄/Ar gas until the oxide film was etched by 50 nm. Evaluation of defects were carried out for the wafer prepared by etching with a defect inspection apparatus “Surfscan SP5” (product name, manufactured by KLA), and the number of cone defects with a size of 19 nm or more was determined as an index of the etching defect.

(Evaluation criteria)
A: Number of cone defects≤10
B: 10<number of cone defects <80
C: 80<number of cone defects≤400
D: 400<number of cone defects

### (Evaluation of Change of Etching Defect Due to Aging)

The solution prepared in the aforementioned evaluation of the etching defect was allowed to stand under light-shielding conditions at room temperature for 7 days, and the solution after being allowed to stand was evaluated for the etching defect in the same manner. Evaluations were conducted based on the amount of change of the number of defects. As the specific evaluation method, the case where the change of the EUV sensitivity before and after being allowed to stand was less than 6% was evaluated “G”, and the case where it was 6% or more was evaluated “N”.

TABLE 4-3

| | | | Evaluation | | | | |
|---|---|---|---|---|---|---|---|
| | | | EUV sensitivity | Change of | EB pattern | | Change of |
| | | | aqueous TMAH | sensitivity | aqueous TMAH | | etching |
| | | Structural | solution development | due to | solution | Etching | defect due to |
| | Polymer | formula | (mJ/cm2) | aging | development | defect | aging |
| Comparative Example B1 | B1 | MA1 | 18 | B | B | B | N |
| Comparative Example B2 | B2 | Ma1a | 18 | B | B | B | N |
| Comparative Example B3 | B3 | MA2 | 19 | B | B | B | N |
| Comparative Example B4 | B4 | MA2a | 19 | B | B | B | N |
| Comparative Example B5 | B5 | MA3 | 19 | B | B | B | N |
| Comparative Example B6 | B6 | MA4 | 21 | B | B | B | N |
| Comparative Example B7 | B7 | MA5 | 20 | B | B | B | N |
| Comparative Example B8 | B8 | MA6 | 17 | B | B | B | N |
| Comparative Example B9 | B9 | MA7 | 20 | B | B | B | N |
| Comparative Example B10 | B10 | MA8 | 20 | B | B | B | N |
| Comparative Example B11 | B11 | MA9 | 20 | B | B | B | N |
| Comparative Example B12 | B12 | MA10 | 17 | B | B | B | N |
| Comparative Example B13 | B13 | MA11 | 22 | B | B | B | N |
| Comparative Example B14 | B14 | MA12 | 23 | B | B | B | N |
| Comparative Example B15 | B15 | MA13 | 21 | B | B | B | N |
| Comparative Example B16 | B16 | MA14 | 22 | B | B | B | N |
| Comparative Example B17 | B17 | MA15 | 21 | B | B | B | N |
| Comparative Example B18 | B18 | MA16 | 22 | B | B | B | N |
| Comparative Example B19 | B19 | MA17 | 19 | B | B | B | N |
| Comparative Example B20 | B20 | MA18 | 22 | B | B | B | N |
| Comparative Example B21 | B21 | MA19 | 22 | B | B | B | N |
| Comparative Example B22 | B22 | MA20 | 23 | B | B | B | N |
| Comparative Example B23 | B23 | MA21 | 24 | B | B | B | N |
| Comparative Example B24 | B24 | MA22 | 23 | B | B | B | N |
| Comparative Example B25 | B25 | MA23 | 23 | B | B | B | N |
| Comparative Example B26 | B26 | MA24 | 23 | B | B | B | N |
| Comparative Example B27 | B27 | MA25 | 24 | B | B | B | N |
| Comparative Example B28 | B28 | MA26 | 23 | B | B | B | N |
| Comparative Example B29 | B29 | MA27 | 24 | B | B | B | N |
| Comparative Example B30 | B30 | MA28 | 22 | B | B | B | N |
| Comparative Example B31 | B31 | MA29 | 22 | B | B | B | N |
| Comparative Example B32 | B32 | MA30 | 21 | B | B | B | N |
| Comparative Example B33 | B33 | MA31 | 23 | B | B | B | N |
| Comparative Example B34 | B34 | MA32 | 23 | B | B | B | N |
| Comparative Example B35 | B35 | MA33 | 25 | B | B | B | N |
| Comparative Example B36 | B36 | MA34 | 22 | B | B | B | N |
| Comparative Example B37 | B37 | MA35 | 22 | B | B | B | N |
| Comparative Example B38 | B38 | MA36 | 22 | B | B | B | N |
| Comparative Example B39 | B39 | MA37 | 22 | B | B | B | N |
| Comparative Example B40 | B40 | MA38 | 22 | B | B | B | N |
| Comparative Example B41 | B41 | MA39 | 22 | B | B | B | N |
| Comparative Example B42 | B42 | MA40 | 22 | B | B | B | N |
| Comparative Example B43 | B43 | MA41 | 22 | B | B | B | N |
| Comparative Example B44 | B44 | MA42 | 22 | B | B | B | N |
| Comparative Example B45 | B45 | MA43 | 22 | B | B | B | N |
| Comparative Example B46 | B46 | MA44 | 22 | B | B | B | N |
| Comparative Example B47 | B47 | MA45 | 22 | B | B | B | N |
| Comparative Example B48 | B48 | MA46 | 22 | B | B | B | N |
| Comparative Example B49 | B49 | MA47 | 22 | B | B | B | N |
| Comparative Example B50 | B50 | MA48 | 22 | B | B | B | N |
| Comparative Example B51 | B51 | MA49 | 22 | B | B | B | N |
| Comparative Example B52 | B52 | MA50 | 22 | B | B | B | N |
| Comparative Example B43 | BR1 | MAR1 | 50 | C | C | C | N |
| Comparative Example B44 | BR2 | MAR2 | 40 | C | C | C | N |

TABLE 5

| | | Evaluation | | | | |
|---|---|---|---|---|---|---|
| | | EUV sensitivity aqueous | Change of | EB pattern | | Change of |
| | | TMAH solution | sensitivity | aqueous TMAH | | etching defect |
| | | development | due to | solution | Etching | due to |
| | Polymer | (mJ/cm2) | aging | development | defect | aging |
| Example C1 | C1 | 19 | B | B | B | G |
| Example C2 | C2 | 19 | B | B | B | G |
| Example C3 | C3 | 18 | B | B | B | G |
| Example C4 | C4 | 18 | B | B | B | G |
| Example C5 | C5 | 18 | B | B | B | G |
| Example C6 | C6 | 18 | B | B | B | G |
| Example C7 | C7 | 18 | B | B | B | G |
| Example C8 | C8 | 18 | B | B | B | G |
| Example C9 | C9 | 18 | B | B | B | G |
| Example C10 | C10 | 18 | B | B | B | G |
| Example C11 | C11 | 18 | B | B | B | G |
| Example C12 | C12 | 18 | B | B | B | G |
| Example C13 | C13 | 18 | B | B | B | G |
| Example C14 | C14 | 19 | B | B | B | G |
| Example C15 | C15 | 19 | B | B | B | G |
| Example C16 | C16 | 19 | B | B | B | G |
| Example C17 | C17 | 21 | B | B | B | G |
| Example C18 | C18 | 20 | B | B | B | G |
| Example C19 | C19 | 17 | B | B | B | G |
| Example C20 | C20 | 20 | B | B | B | G |
| Example C21 | C21 | 20 | B | B | B | G |
| Example C22 | C22 | 20 | B | B | B | G |
| Example C23 | C23 | 17 | B | B | B | G |
| Example C24 | C24 | 22 | B | B | B | G |
| Example C25 | C25 | 23 | B | B | B | G |
| Example C26 | C26 | 21 | B | B | B | G |
| Example C27 | C27 | 22 | B | B | B | G |
| Example C28 | C28 | 19 | B | B | B | G |
| Example C29 | C29 | 22 | B | B | B | G |
| Example C30 | C30 | 22 | B | B | B | G |
| Example C31 | C31 | 22 | B | B | B | G |
| Example C32 | C32 | 22 | B | B | B | G |
| Example C33 | C33 | 22 | B | B | B | G |
| Example C34 | C34 | 22 | B | B | B | G |
| Example C35 | C35 | 22 | B | B | B | G |
| Example C36 | C36 | 23 | B | B | B | G |
| Example C37 | C37 | 24 | B | B | B | G |
| Example C38 | C38 | 23 | B | B | B | G |
| Example C39 | C39 | 23 | B | B | B | G |
| Example C40 | C40 | 23 | B | B | B | G |
| Example C41 | C41 | 24 | B | B | B | G |
| Example C42 | C42 | 23 | B | B | B | G |
| Example C43 | C43 | 24 | B | B | B | G |
| Example C44 | C44 | 22 | B | B | B | G |
| Example C45 | C45 | 22 | B | B | B | G |
| Example C46 | C46 | 21 | B | B | B | G |
| Example C47 | C47 | 23 | B | B | B | G |
| Example C48 | C48 | 23 | B | B | B | G |
| Example C49 | C49 | 25 | B | B | B | G |
| Example C50 | C50 | 19 | B | B | B | G |
| Example C51 | C51 | 19 | B | B | B | G |
| Example C52 | C52 | 19 | B | B | B | G |
| Example C53 | C53 | 19 | B | B | B | G |
| Example C54 | C54 | 19 | B | B | B | G |
| Example C55 | C55 | 19 | B | B | B | G |
| Example C56 | C56 | 22 | B | B | B | G |
| Example C57 | C57 | 22 | B | B | B | G |
| Example C58 | C58 | 22 | B | B | B | G |
| Example C59 | C59 | 22 | B | B | B | G |
| Example C60 | C60 | 22 | B | B | B | G |
| Example C61 | C61 | 22 | B | B | B | G |
| Example C62 | C62 | 22 | B | B | B | G |
| Example C63 | C63 | 22 | B | B | B | G |
| Example C64 | C64 | 22 | B | B | B | G |
| Example C65 | C65 | 22 | B | B | B | G |
| Example C66 | C66 | 22 | B | B | B | G |
| Example C67 | C67 | 22 | B | B | B | G |
| Example C68 | C68 | 22 | B | B | B | G |
| Example C69 | C69 | 22 | B | B | B | G |
| Example C70 | C70 | 22 | B | B | B | G |
| Example C71 | C71 | 22 | B | B | B | G |
| Example C72 | C72 | 22 | B | B | B | G |
| Example C73 | C73 | 22 | B | B | B | G |
| Example C74 | C74 | 22 | B | B | B | G |
| Example C75 | C75 | 22 | B | B | B | G |
| Example C76 | C66 | 22 | B | B | B | G |

TABLE 6

| | | Evaluation | | | | |
|---|---|---|---|---|---|---|
| | | EUV sensitivity | Change of | EB pattern | | Change of |
| | | aqueous TMAH | sensitivity | aqueous TMAH | | etching |
| | | solution development | due to | solution | Etching | defect due to |
| | Polymer | (mJ/cm2) | aging | development | defect | aging |
| Example C1P | C1P | 19 | A | A | A | G |
| Example C2P | C2P | 19 | A | A | A | G |
| Example C3P | C3P | 18 | A | A | A | G |
| Example C4P | C4P | 18 | A | A | A | G |
| Example C5P | C5P | 18 | A | A | A | G |
| Example C6P | C6P | 18 | A | A | A | G |
| Example C7P | C7P | 18 | A | A | A | G |
| Example C8P | C8P | 18 | A | A | A | G |
| Example C9P | C9P | 18 | A | A | A | G |
| Example C10P | C10P | 18 | A | A | A | G |
| Example C11P | C11P | 18 | A | A | A | G |
| Example C12P | C12P | 18 | A | A | A | G |
| Example C13P | C13P | 18 | A | A | A | G |
| Example C14P | C14P | 19 | A | A | A | G |
| Example C15P | C15P | 19 | A | A | A | G |
| Example C16P | C16P | 19 | A | A | A | G |
| Example C17P | C17P | 21 | A | A | A | G |
| Example C18P | C18P | 20 | A | A | A | G |
| Example C19P | C19P | 17 | A | A | A | G |
| Example C20P | C20P | 20 | A | A | A | G |
| Example C21P | C21P | 20 | A | A | A | G |
| Example C22P | C22P | 20 | A | A | A | G |
| Example C23P | C23P | 17 | A | A | A | G |
| Example C24P | C24P | 22 | A | A | A | G |
| Example C25P | C25P | 23 | A | A | A | G |
| Example C26P | C26P | 21 | A | A | A | G |
| Example C27P | C27P | 22 | A | A | A | G |
| Example C28P | C28P | 19 | A | A | A | G |
| Example C29P | C29P | 22 | A | A | A | G |
| Example C30P | C30P | 22 | A | A | A | G |
| Example C31P | C31P | 22 | A | A | A | G |
| Example C32P | C32P | 22 | A | A | A | G |
| Example C33P | C33P | 22 | A | A | A | G |
| Example C34P | C34P | 22 | A | A | A | G |
| Example C35P | C35P | 22 | A | A | A | G |
| Example C36P | C36P | 23 | A | A | A | G |
| Example C37P | C37P | 24 | A | A | A | G |
| Example C38P | C38P | 23 | A | A | A | G |
| Example C39P | C39P | 23 | A | A | A | G |
| Example C40P | C40P | 23 | A | A | A | G |
| Example C41P | C41P | 24 | A | A | A | G |
| Example C42P | C42P | 23 | A | A | A | G |
| Example C43P | C43P | 24 | A | A | A | G |
| Example C44P | C44P | 22 | A | A | A | G |
| Example C45P | C45P | 22 | A | A | A | G |
| Example C46P | C46P | 21 | A | A | A | G |
| Example C47P | C47P | 23 | A | A | A | G |
| Example C48P | C48P | 23 | A | A | A | G |
| Example C49P | C49P | 25 | A | A | A | G |
| Example C50P | C50P | 19 | A | A | A | G |
| Example C51P | C51P | 19 | A | A | A | G |
| Example C52P | C52P | 19 | A | A | A | G |
| Example C53P | C53P | 19 | A | A | A | G |
| Example C54P | C54P | 19 | A | A | A | G |
| Example C55P | C55P | 19 | A | A | A | G |
| Example C56P | C56P | 22 | A | A | A | G |
| Example C57P | C57P | 22 | A | A | A | G |
| Example C58P | C58P | 22 | A | A | A | G |
| Example C59P | C59P | 22 | A | A | A | G |
| Example C60P | C60P | 22 | A | A | A | G |
| Example C61P | C61P | 22 | A | A | A | G |
| Example C62P | C62P | 22 | A | A | A | G |
| Example C63P | C63P | 22 | A | A | A | G |
| Example C64P | C64P | 22 | A | A | A | G |
| Example C65P | C65P | 22 | A | A | A | G |
| Example C66P | C66P | 22 | A | A | A | G |
| Example C67P | C67P | 22 | A | A | A | G |
| Example C68P | C68P | 22 | A | A | A | G |
| Example C69P | C69P | 22 | A | A | A | G |
| Example C70P | C70P | 22 | A | A | A | G |
| Example C71P | C71P | 22 | A | A | A | G |
| Example C72P | C72P | 22 | A | A | A | G |
| Example C73P | C73P | 22 | A | A | A | G |
| Example C74P | C74P | 22 | A | A | A | G |
| Example C75P | C75P | 22 | A | A | A | G |
| Example C76P | C76P | 22 | A | A | A | G |

It was confirmed from Table 4-3 and Table 5 that the compound A can improve the aging stability of the etching defect by containing a trace amount of the compound B such as BP1 to BP-4, BP11, or BP12.

As shown in Table 4-3, Table 5, and Table 6, the compound A of the present invention can improve the aging stability of etching defects by containing a trace amount of the compound B such as BP1 to BP6, BP11, or BP12, and when impurities such as metal, maleic acid, and the phosphorus-containing compound were low, the change of EUV sensitivity due to aging was suppressed, the residues were reduced, and the aging stability of the etching defect was improved.

### (Change of Etching Defect Due to Aging by Addition of Compound B)

Each composition prepared by using 5 parts by mass of each of the polymers B1 to B52 obtained in Synthetic Examples B1 to B52 and any one of BP1 to BP6, BP11, and BP12 as shown in Table 7 was evaluated in the same manner as the above evaluation of the change of the etching defect due to aging. The evaluation results are shown in Table 7.

TABLE 7

| | Polymer | Compound B | | Change of etching |
|---|---|---|---|---|
| | (5 parts by mass) | Compound | part by mass | defect due to aging |
| Example D1 | B1 | BP1 | 0.02 | A |
| Example D1a | B1 | BP2 | 0.02 | A |
| Example D1b | B1 | BP3 | 0.02 | A |
| Example D2c | B1 | BP4 | 0.02 | A |
| Example D2d | B1 | BP11 | 0.02 | A |
| Example D3e | B1 | BP12 | 0.02 | A |
| Example D2 | B2 | BP1 | 0.02 | A |
| Example D3 | B3 | BP1 | 0.02 | A |
| Example D4 | B4 | BP1 | 0.02 | A |
| Example D5 | B5 | BP1 | 0.02 | A |
| Example D6 | B6 | BP1 | 0.02 | A |
| Example D7 | B7 | BP1 | 0.02 | A |
| Example D8 | B8 | BP1 | 0.02 | A |
| Example D9 | B9 | BP1 | 0.02 | A |
| Example D10 | B10 | BP1 | 0.02 | A |
| Example D11 | B11 | BP1 | 0.02 | A |
| Example D12 | B12 | BP1 | 0.02 | A |
| Example D13 | B13 | BP1 | 0.02 | A |
| Example D14 | B14 | BP1 | 0.02 | A |
| Example D15 | B15 | BP1 | 0.02 | A |
| Example D16 | B16 | BP1 | 0.02 | A |
| Example D17 | B17 | BP1 | 0.02 | A |
| Example D18 | B18 | BP1 | 0.02 | A |
| Example D19 | B19 | BP1 | 0.02 | A |
| Example D20 | B20 | BP1 | 0.02 | A |
| Example D21 | B21 | BP1 | 0.02 | A |
| Example D21a | B21 | BP2 | 0.02 | A |
| Example D21b | B21 | BP3 | 0.02 | A |
| Example D21c | B21 | BP4 | 0.02 | A |
| Example D21d | B21 | BP11 | 0.02 | A |
| Example D21e | B21 | BP12 | 0.02 | A |
| Example D22 | B22 | BP1 | 0.02 | A |
| Example D23 | B23 | BP1 | 0.02 | A |
| Example D24 | B24 | BP1 | 0.02 | A |
| Example D25 | B25 | BP1 | 0.02 | A |
| Example D26 | B26 | BP1 | 0.02 | A |
| Example D27 | B27 | BP1 | 0.02 | A |
| Example D28 | B28 | BP1 | 0.02 | A |
| Example D29 | B29 | BP1 | 0.02 | A |
| Example D30 | B30 | BP1 | 0.02 | A |
| Example D31 | B31 | BP1 | 0.02 | A |
| Example D32 | B32 | BP1 | 0.02 | A |
| Example D33 | B33 | BP1 | 0.02 | A |
| Example D34 | B34 | BP1 | 0.02 | A |
| Example D35 | B35 | BP1 | 0.02 | A |
| Example D36 | B36 | BP1 | 0.02 | A |
| Example D37 | B37 | BP1 | 0.02 | A |
| Example D38 | B38 | BP1 | 0.02 | A |
| Example D39 | B39 | BP5 | 0.02 | A |
| Example D40 | B40 | BP5 | 0.02 | A |
| Example D41 | B41 | BP6 | 0.02 | A |
| Example D42 | 342 | BP6 | 0.02 | A |
| Example D43 | B43 | BP1 | 0.02 | A |
| Example D44 | B44 | BP1 | 0.02 | A |
| Example D45 | B45 | BP1 | 0.02 | A |
| Example D46 | B46 | BP1 | 0.02 | A |
| Example D47 | B47 | BP1 | 0.02 | A |
| Example D48 | B48 | BP1 | 0.02 | A |
| Example D49 | B49 | BP1 | 0.02 | A |
| Example D50 | B50 | BP1 | 0.02 | A |
| Example D51 | B51 | BP1 | 0.02 | A |
| Example D52 | B52 | BP1 | 0.02 | A |

It was confirmed from Table 4-3 and Table 7 that the polymer of the present invention can improve the aging stability of the etching defect by containing a trace amount of the compound B such as BP1 to BP-6, BP11, or BP12.

### (Evaluation on Organic Solvent Development)

The polymers B1, C3, C5, C3P, C5P, BR1, and BR2 were subjected to organic solvent development by the following method, and evaluations were carried out in the same manner as Comparative Examples B1, B2, B37, and B38, and Examples Cl, C2, C1P, and C2P. The evaluation results are shown in Table 8.

### (EUV Sensitivity-Organic Solvent Development)

A solution containing the polymer obtained in Examples or Comparative Examples was prepared in the same manner as the EUV sensitivity-aqueous TMAH solution development, which was applied on a silicon wafer and baked at 110° C. for 60 seconds to form a photoresist layer having a film thickness of 100 nm.

Then, using an extreme ultraviolet (EUV) exposure apparatus “EUVES-7000” (product name, manufactured by Litho Tech Japan Corporation), the photoresist layer was subjected to shot exposure without masking by incrementing the exposure amount by 1 mJ/cm² from 1 mJ/cm² to 80 mJ/cm², baked (PEB) at 110° C. for 90 seconds, and developed with butyl acetate for 30 seconds to obtain a wafer on which 80 shots of shot exposure was carried out. For each obtained shot exposure area, the film thickness was measured by using an optical interference film thickness meter “VM3200” (product name, manufactured by SCREEN Semiconductor Solutions Co., Ltd.), profile data about the film thickness relative to the exposure amount was obtained, and the exposure amount at which the slope of film thickness variation relative to an exposure amount was the largest was calculated as a sensitivity value (mJ/cm²), which was used as an index of the EUV sensitivity of the resist.

Evaluations of the sensitivity due to aging were carried out in the same manner as the EUV sensitivity-aqueous TMAH solution development. The evaluation results are shown in Table 8.

### (EB Pattern-Organic Solvent Development)

The compound or the polymer obtained in Examples or Comparative Examples was prepared in the same manner as the EB pattern-aqueous TMAH solution development, which was applied on a silicon wafer and baked at 110 to 130° C. for 60 seconds to form a resist film having a film thickness of 100 nm.

Then, the resist film was exposed using an electron beam lithography system “ELS-7500” (product name, manufactured by ELIONIX INC., 50 keV), baked (PEB) at 115° C. for 90 seconds, and developed with a 2.38 mass % tetramethylammonium hydroxide (TMAH) aqueous solution for 60 seconds to obtain a negative type pattern. The exposure amount was regulated to have a line and space pattern with a half pitch of 50 nm.

For the obtained resist pattern, 80 pattern images were obtained with a scanning electron microscope “S-4800” (product name, manufactured by Hitachi, Ltd.) at 100000 times magnification, the number of residues on the space portion between resist patterns were counted, and evaluations were carried out from the total amount of the residues. The evaluation criteria are as follows.

(Evaluation criteria)
A: Number of residues≤10
B: 10<number of residues≤80
C: 80<number of residues≤400
D: 400<number of residues

Evaluations of the etching defect and evaluations of the change of the etching defect due to aging were carried out in the same manner as the EUV sensitivity-aqueous TMAH solution development. The evaluation results are shown in Table 8.

TABLE 8

| | | Evaluation | | | | |
|---|---|---|---|---|---|---|
| | | EUV sensitivity | | | | Change of |
| | | organic solvent | Change of | EB pattern | | etching |
| | | development | sensitivity | organic solvent | Etching | defect due |
| | Polymer | (mJ/cm2) | due to aging | development | defect | to aging |
| Example E1 | C3 | 19 | B | B | B | G |
| Example E2 | C5 | 19 | B | B | B | G |
| Example | C3P | 17 | A | A | A | G |
| E1P | | | | | | |
| Example | C5P | 18 | A | A | A | G |
| E2P | | | | | | |
| Comparative | B1 | 18 | B | B | B | N |
| Example E1 | | | | | | |
| Comparative | BR1 | 55 | C | C | C | N |
| Example E3 | | | | | | |
| Comparative | BR2 | 42 | C | C | C | N |
| Example E4 | | | | | | |

It was confirmed from Table 8 that the aging stability of the etching defect was improved also in the organic solvent development.

### (Resin Synthetic Example D1) Synthesis of P-MA8 Resin

3.00 g of MA8, 4.5 g of EADMA, 0.62 g of γ-butyrolactone methacrylate, and 0.87 g of 4-vinyl phenol were dissolved in 50 mL of tetrahydrofuran, and 0.20 g of azobisisobutyronitrile was added thereto. After the mixture was refluxed for 12 hours, the reaction solution was added dropwise to 2 L of n-heptane. The deposited resin was filtered off and dried under reduced pressure to obtain a white powdery resin represented by the following chemical formula (P-MA8). The resin had a molecular weight (Mw) of 11000 and a dispersity (Mw/Mn) of 1.93. As a result of the measurement of ¹³C-NMR, the composition ratio (molar ratio) in the following chemical formula (P-MA8) was a: b: c: d=10:20:50:20. Although the chemical formula (P-MA-8) shown below is briefly described in order to indicate the ratio of each constituent unit, P-MA8 is not a block copolymer in which each constituent unit forms an independent block.

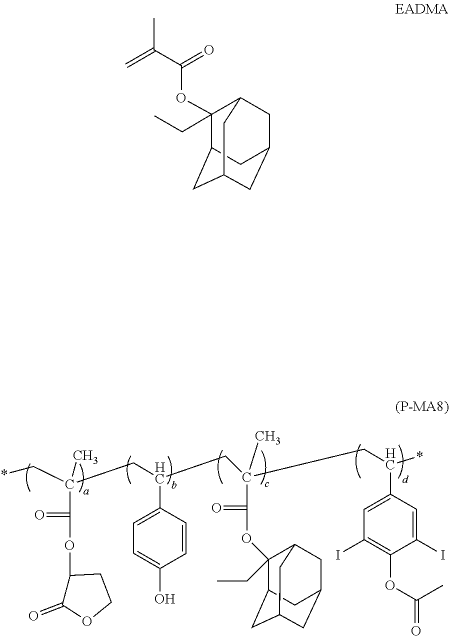

Resin Synthetic Examples D2 to A10 were conducted in the same manner as Resin Synthetic Example D1, except that, among monomers used in Resin Synthetic Example D1, P-MA8 was changed to the following kind and amount.

The Mw and the dispersibility of the obtained resin, and the monomer composition ratio a: b: c: d in the resin were as shown in the following Table.

TABLE 9

| | | | Molecular | | Composition |
|---|---|---|---|---|---|
| Synthetic | | Weight | weight | | ratio |
| Example | Monomer | (g) | Mw | Dispersity | a:b:c:d |
| D1 | MA8 | 3 | 11000 | 1.93 | 10:20:50:20 |
| D2 | MA9 | 3.4 | 10000 | 1.88 | 10:20:50:20 |
| D3 | MA10 | 4.3 | 13000 | 1.98 | 10:20:50:20 |
| D4 | MA12 | 2.1 | 12000 | 1.85 | 10:20:50:20 |
| D5 | MA14 | 2.5 | 13000 | 1.91 | 10:20:50:20 |
| D6 | MA16 | 2.5 | 11000 | 1.94 | 10:20:50:20 |
| D7 | MA18 | 3 | 12000 | 1.99 | 10:20:50:20 |
| D8 | MA20 | 2.5 | 10000 | 1.87 | 10:20:50:20 |
| D9 | MA27 | 3.4 | 9200 | 1.82 | 10:20:50:20 |
| D10 | MA29 | 2.5 | 9500 | 1.83 | 10:20:50:20 |

The above Synthetic Examples D1 to D10 were subjected to the same purification treatment as Synthetic Example C1P to synthesize DIP to D10P. Evaluations of the amount of impurities of the obtained polymers were conducted in the same manner.

TABLE 10

| | | Polymer impurity content (ppm) | | | | | |
|---|---|---|---|---|---|---|---|
| | | | | | | | Phosphorus- |
| Synthetic | | | | | | | containing |
| Example | Polymer | Mn | Al | Si | Li | Maleic acid | compound |
| D1P | E1P | 0.0001 | 0.0001 | 0.001 | 0.0001 | 0.1 | 0.1 |
| D2P | E2P | 0.0001 | 0.0001 | 0.001 | 0.0001 | 0.1 | 0.1 |
| D3P | E3P | 0.0001 | 0.0001 | 0.001 | 0.0001 | 0.1 | 0.1 |
| D4P | E4P | 0.0001 | 0.0001 | 0.001 | 0.0001 | 0.1 | 0.1 |
| D5P | E5P | 0.0001 | 0.0001 | 0.001 | 0.0001 | 0.1 | 0.1 |
| D6P | E6P | 0.0001 | 0.0001 | 0.001 | 0.0001 | 0.1 | 0.1 |
| D7P | E7P | 0.0001 | 0.0001 | 0.001 | 0.0001 | 0.1 | 0.1 |
| D8P | E8P | 0.0001 | 0.0001 | 0.001 | 0.0001 | 0.1 | 0.1 |
| D9P | E9P | 0.0001 | 0.0001 | 0.001 | 0.0001 | 0.1 | 0.1 |
| D10P | E10P | 0.0001 | 0.0001 | 0.001 | 0.0001 | 0.1 | 0.1 |

Furthermore, evaluations of the EUV sensitivity (aqueous TMAH solution development), the change of the sensitivity due to aging, the EB pattern (aqueous TMAH solution development), the etching defect, and the change of the etching defect due to aging were carried out in the same manner as C1P.

TABLE 11

| | | Evaluation | | | | |
|---|---|---|---|---|---|---|
| | | EUV sensitivity | Change of | EB pattern | | Change of |
| | | (aqueous TMAH | sensitivity | (aqueous | | etching defect |
| | | solution | due to | TMAH solution | Etching | due to |
| | Polymer | development) | aging | development) | defect | aging |
| D1P | E1P | 20 | A | A | A | A |
| D2P | E2P | 19 | A | A | A | A |
| D3P | E3P | 18 | A | A | A | A |
| D4P | E4P | 21 | A | A | A | A |
| D5P | E5P | 21 | A | A | A | A |
| D6P | E6P | 21 | A | A | A | A |
| D7P | E7P | 19 | A | A | A | A |
| D8P | E8P | 21 | A | A | A | A |
| D9P | E9P | 19 | A | A | A | A |
| D10P | E10P | 21 | A | A | A | A |

The results of Examples and Comparative Examples above show that the composition according to the present embodiment can provide a composition for film formation excellent in the sensitivity to an exposure light source and can improve the aging stability of defects.

### INDUSTRIAL APPLICABILITY

The present invention can provide a composition, a composition for film formation, a pattern formation method, and a compound, by which the sensitivity to an exposure light source is excellent and defects that may be caused on a film or a pattern after exposure due to aging are suppressed. The composition, the composition for film formation, the pattern formation method, and the compound can be utilized for photoresists used in photolithography in the production of semiconductor elements and liquid crystal display elements.

1. A composition comprising a compound (A) represented by the following formula (1) and a compound (B) represented by the following formula (2): 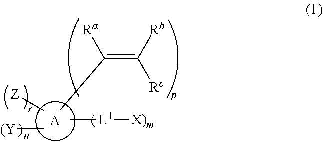
wherein
each X is independently I, F, Cl, Br, or an organic group having 1 to 30 carbon atoms and having 1 or more and 5 or less substituents selected from the group consisting of I, F, Cl, and Br;
each L¹ is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of L¹ optionally has a substituent;
each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, I, F, Cl, Br, or an organic group having 1 to 8 carbon atoms and optionally having a substituent;
A is an organic group having 6 to 30 carbon atoms;
each Z is independently an alkoxy group, an ester group, an acetal group, a carboxyalkoxy group, or a carbonate ester group, and the alkoxy group, the ester group, the acetal group, the carboxyalkoxy group, or the carbonate ester group of Z optionally has a substituent; and
p is an integer of 1 or more, m is an integer of 1 or more, n is an integer of 0 or more, and r is an integer of 0 or more; and 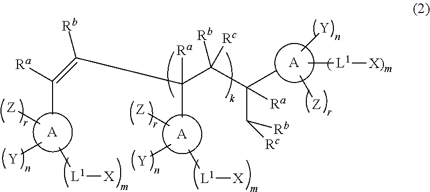
wherein
X, L¹, Y, R^{a}, R^{b}, R^{c}, A, Z, p, m, n, and r are the same as those described in the formula (1), and k represents an integer of 0 or more and 2 or less.

2. The composition according to claim 1, wherein the formula (1) is represented by the following formula (Ia): 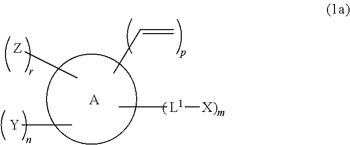
wherein
X, L¹, Y, A, Z, p, m, n, and r are as defined in the formula (1).

3. The composition according to claim 1, wherein the formula (1) is represented by the following formula (Ib): 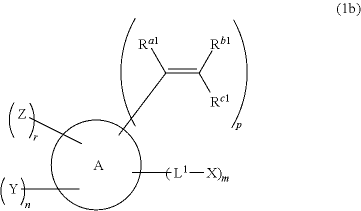
wherein
X, L¹, Y, A, Z, p, m, n, and r are as defined in the formula (1);
each of R^{a1}, R^{b1}, and R^{e1} is independently H, I, F, Cl, Br, or an organic group having 1 to 8 carbon atoms and optionally having a substituent; and
at least one of R^{a1}, R^{b1}, and R^{e1} is I, F, Cl, Br, or an organic group having 1 to 8 carbon atoms and optionally having a substituent.

4. The composition according to claim 1, wherein n+r in the formula (1) is an integer of 1 or more.

5. The composition according to claim 1, wherein each Y in the formula (1) is independently a group represented by the following formula (Y-1): 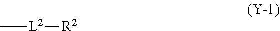
wherein
L² is a group which is cleaved by an action of an acid or a base; and
R² is a linear, branched, or cyclic aliphatic group having 1 to 30 carbon atoms, an aromatic group having 6 to 30 carbon atoms, a linear, branched, or cyclic aliphatic group containing a heteroatom and having 1 to 30 carbon atoms, or an aromatic group containing a heteroatom and having 1 to 30 carbon atoms, and the aliphatic group, the aromatic group, the aliphatic group containing a heteroatom, and the aromatic group containing a heteroatom of R² optionally further have a substituent.

6. The composition according to claim 1, wherein A in the formula (1) is an aromatic ring.

7. The composition according to claim 1, wherein A in the formula (1) is an alicyclic structure.

8. The composition according to claim 1, wherein A in the formula (1) is a heterocyclic structure.

9. The composition according to claim 1, wherein n in the formula (1) is 2 or more.

10. The composition according to claim 1, wherein the compound represented by the formula (1) comprises a functional group for improving solubility in an alkaline developing solution by the action of an acid or a base.

11. The composition according to claim 1, wherein X in the formula (1) is I, and L¹ is a single bond.

12. The composition according to claim 1, wherein X in the formula (1) is an aromatic group into which one or more F, Cl, Br, or I are introduced.

13. The composition according to claim 1, wherein X in the formula (1) is an alicyclic group into which one or more F, Cl, Br, or I are introduced.

14. The composition according to claim 1, wherein A in the formula (2) is an aromatic ring.

15. The composition according to claim 14, wherein A in the formula (2) is a benzene ring or a naphthalene ring.

16. The composition according to claim 1, wherein X in the formula (2) is iodine or fluorine.

17. The composition according to claim 1, wherein L¹ in the formula (2) is a single bond.

18. The composition according to claim 1, wherein Y in the formula (2) is a hydroxy group, an alkoxy group, a carbonate ester group, or an acetal group.

19. The composition according to claim 1, wherein a mass ratio of a content of the compound represented by the formula (2) based on a content of the compound represented by the formula (1) is 1 ppm or more and 5% by mass or less.

20. The composition according to claim 1, wherein the composition comprises a compound represented by the formula (2a), and a content of the compound represented by the formula (2a) is 1% by mass or less based on the compound of the formula (1): 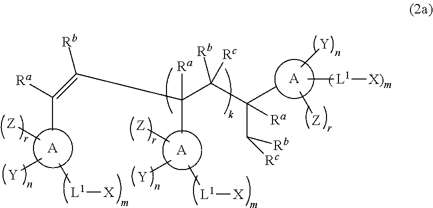
wherein
X, L¹, Y, R^{a}, R^{b}, Re, A, Z, p, m, n, and r are the same as those described in the formula (1), and k represents an integer of 3 or more.

21. The composition according to claim 20, wherein peroxide is 10 ppm by mass or less based on the compound of the formula (1).

22. The composition according to claim 20, wherein impurities containing one or more elements selected from the group consisting of Mn, Al, Si, and Li are 1 ppm by mass or less, in terms of element, based on the compound of the formula (1).

23. The composition according to claim 20, wherein a phosphorus-containing compound is 10 ppm by mass or less based on the compound of the formula (1).

24. The composition according to claim 20, wherein maleic acid is 10 ppm by mass or less based on the compound of the formula (1).

25. The composition according to claim 1, wherein in the formula (1) and the formula (2), all r are 0, and at least one n is 1 or more.

26. A resin composition comprising:
a polymer comprising at least a constitutional unit represented by the following formula (4) and having 5 or more constitutional units;
a compound (B) represented by the following formula (2) in a content of 1% by mass or less based on the polymer; and
a compound (A) represented by the following formula (1): 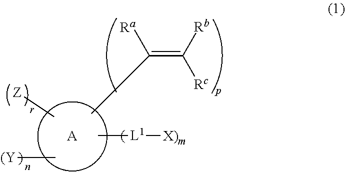
wherein
each X is independently I, F, Cl, Br, or an organic group having 1 to 30 carbon atoms and having 1 or more and 5 or less substituents selected from the group consisting of I, F, Cl, and Br;
each L¹ is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of L¹ optionally has a substituent;
each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, I, F, Cl, Br, or an organic group having 1 to 8 carbon atoms and optionally having a substituent;
A is an organic group having 6 to 30 carbon atoms;
each Z is independently an alkoxy group, an ester group, an acetal group, a carboxyalkoxy group, or a carbonate ester group, and the alkoxy group, the ester group, the acetal group, the carboxyalkoxy group, or the carbonate ester group of Z optionally has a substituent; and
p is an integer of 1 or more, m is an integer of 1 or more, n is an integer of 0 or more, and r is an integer of 0 or more; 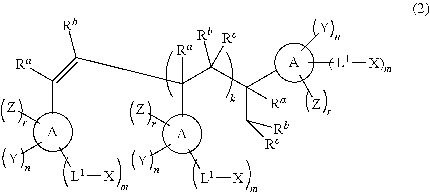
wherein
X, L¹, Y, R^{a}, R^{b}, Re, A, Z, p, m, n, and r are the same as those described in the formula (1), and k represents an integer of 0 or more and 2 or less; and 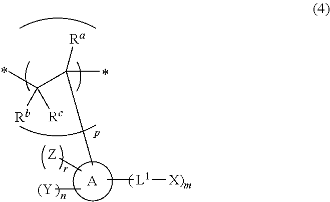
wherein X, L¹, Y, R^{a}, R^{b}, R^{c}, A, Z, p, m, n, and r are as defined in the formula (1); and
* is a site for binding with an adjacent constitutional unit.

27. The resin composition according to claim 26, wherein the polymer further comprises a constitutional unit represented by the following formula (C6): 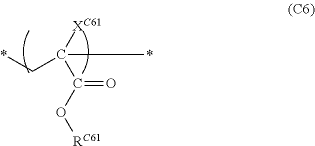
wherein
X^{C61} is a hydroxyl group or a halogen group;
each R^{C61} is independently an alkyl group having 1 to 20 carbon atoms; and
* is a site for binding with an adjacent constitutional unit.

28. The resin composition according to claim 26, wherein in the formula (1), the formula (2), and the formula (4), all r are 0, and at least one n is 1 or more.

29. A composition for film formation comprising the composition according to claim 1.

30. The composition for film formation according to claim 29, further comprising an acid generating agent, a base generating agent, or a base compound.

31. A resist pattern formation method comprising:
a step of forming a resist film on a substrate by using a composition for film formation containing the composition according to claim 1;
a step of exposing a pattern on the resist film; and
a step of subjecting the resist film to a development treatment after exposure.

32. A compound represented by the following formula (2): 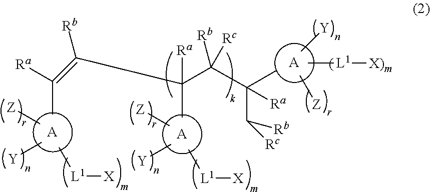
wherein
each X is independently I, F, Cl, Br, or an organic group having 1 to 30 carbon atoms and having 1 or more and 5 or less substituents selected from the group consisting of I, F, Cl, and Br;
each L¹ is independently a single bond, an ether group, an ester group, a thioether group, an amino group, a thioester group, an acetal group, a phosphine group, a phosphone group, a urethane group, a urea group, an amide group, an imide group, or a phosphate group, and the ether group, the ester group, the thioether group, the amino group, the thioester group, the acetal group, the phosphine group, the phosphone group, the urethane group, the urea group, the amide group, the imide group, or the phosphate group of L¹ optionally has a substituent;
each Y is independently a hydroxyl group, an alkoxy group, an ester group, an acetal group, a carboxyalkoxy group, a carbonate ester group, a nitro group, an amino group, a carboxyl group, a thiol group, an ether group, a thioether group, a phosphine group, a phosphone group, a urethane group, a urea group, an amide group, an imide group, or a phosphate group, and the alkoxy group, the ester group, the carbonate ester group, the amino group, the ether group, the thioether group, the phosphine group, the phosphone group, the urethane group, the urea group, the amide group, the imide group, and the phosphate group of Y optionally have a substituent;
each of R^{a}, R^{b}, and R^{c} is independently H, I, F, Cl, Br, or an organic group having 1 to 8 carbon atoms and optionally having a substituent;
A is an organic group having 6 to 30 carbon atoms;
each Z is independently an alkoxy group, an ester group, an acetal group, a carboxyalkoxy group, or a carbonate ester group, and the alkoxy group, the ester group, the acetal group, the carboxyalkoxy group, or the carbonate ester group of Z optionally has a substituent;
p is an integer of 1 or more, m is an integer of 1 or more, n is an integer of 0 or more, and r is an integer of 0 or more; and
k represents an integer of 0 or more and 2 or less.

33. The compound according to claim 32, wherein in the formula (2), all r are 0, and at least one n is 1 or more.

34. A composition for film formation comprising the resin composition according to claim 26.

35. A resist pattern formation method comprising:
a step of forming a resist film on a substrate by using a composition for film formation containing the resist composition according to claim 26;
a step of exposing a pattern on the resist film; and
a step of subjecting the resist film to a development treatment after exposure.
